(19) United States
(12) Patent Application Publication
(10) Pub. No.: US 2025/0252998 A1
(43) Pub. Date: Aug. 7, 2025

(54) THREE-DIMENSIONAL MEMORY DEVICE CONTAINING A DIELECTRIC SUPPORT ASSEMBLY WITH A DIELECTRIC CONNECTION PLATE AND METHOD OF MAKING THEREOF

(71) Applicant: SANDISK TECHNOLOGIES LLC, ADDISON, TX (US)

(72) Inventors: Koichi MATSUNO, Fremont, CA (US); Ruogu Matthew ZHU, San Jose, CA (US); Johann ALSMEIER, San Jose, CA (US)

(21) Appl. No.: 18/433,073

(22) Filed: Feb. 5, 2024

(51) Int. Cl. G11C 16/04; H01L 23/522; H01L 23/528; H10B 41/10; H10B 41/27; H10B 41/35; H10B 43/10; H10B 43/27; H10B 43/35

(52) U.S. Cl. CPC G11C 16/0483; H01L 23/5226; H01L 23/5283; H10B 41/10; H10B 41/27; H10B 41/35; H10B 43/10; H10B 43/27; H10B 43/35

(57) ABSTRACT

A memory device includes an alternating stack of insulating layers and electrically conductive layers including stepped surfaces, a dielectric material portion overlying the stepped surfaces of the alternating stack, a memory opening vertically extending through the alternating stack, a memory opening fill structure located in the memory opening and including a vertical stack of memory elements and a vertical semiconductor channel, and a dielectric support assembly. The dielectric support assembly includes a plurality of dielectric pillar structures and a dielectric connection plate. The plurality of dielectric pillar structures vertically extend through the stepped surfaces, the dielectric material portion, and an underlying portion of the alternating stack. The dielectric connection plate overlies the stepped surfaces and contacts and laterally surrounds each of the plurality of dielectric pillar structures.

### FIELD

The present disclosure relates generally to the field of semiconductor devices, and particularly to a three-dimensional memory device including a dielectric support assembly with a dielectric connection plate and method of making thereof.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: an alternating stack of insulating layers and electrically conductive layers, wherein the alternating stack comprises stepped surfaces located in a contact region; a dielectric material portion overlying the stepped surfaces of the alternating stack; a memory opening vertically extending through the alternating stack; a memory opening fill structure located in the memory opening and comprising a vertical stack of memory elements and a vertical semiconductor channel; and a dielectric support assembly comprising a plurality of dielectric pillar structures and a dielectric connection plate, wherein the plurality of dielectric pillar structures vertically extend through the stepped surfaces, the dielectric material portion, and an underlying portion of the alternating stack, and the dielectric connection plate overlies the stepped surfaces and contacts and laterally surrounds each of the plurality of dielectric pillar structures.

According to another aspect of the present disclosure, a method of forming a memory device is provided. The method comprises: forming an alternating stack of insulating layers and sacrificial material layers over a substrate; forming stepped surfaces by patterning the alternating stack; forming an etch-stop material layer over the stepped surfaces; forming a dielectric material portion over a portion of the etch-stop material layer that overlies the stepped surfaces; forming a memory opening through the alternating stack; forming a memory opening fill structure in the memory opening, wherein the memory opening fill structure comprises a vertical stack of memory elements and a vertical semiconductor channel; forming support openings through the dielectric material portion, the etch-stop material layer, and a portion of the alternating stack that underlies the dielectric material portion; isotropically etching the etch-stop material layer around a subset of the support openings by performing an isotropic etch process to form a continuous cavity which comprises volumes of the subset of the support openings and further comprises a laterally-extending cavity that laterally surrounds the volumes of the subset of the support openings; forming a dielectric support assembly in the continuous cavity, wherein the dielectric support assembly comprises a plurality of dielectric pillar structures located in the volumes of the subset of the support openings and further comprises a dielectric connection plate which fills the laterally-extending cavity and laterally surrounds each of the plurality of dielectric pillar structures; and replacing the sacrificial material layers with electrically conductive layers.

### BRIEF DESCRIPTION OF THE DRAWINGS

FIG. 1 is a vertical cross-sectional view of a first exemplary structure after formation of a dielectric isolation layer, a first alternating stack of first insulating layers and first sacrificial material layers, and first stepped surfaces according to an embodiment of the present disclosure.

FIG. 2 is a vertical cross-sectional view of the first exemplary structure after formation of a first insulating liner and a first etch-stop material layer over the first stepped surfaces according to an embodiment of the present disclosure.

FIG. 3 is a vertical cross-sectional view of the first exemplary structure after formation of a first stepped dielectric material portion according to an embodiment of the present disclosure.

FIG. 4A is a vertical cross-sectional view of the first exemplary structure after formation of an inter-tier dielectric layer and first-tier memory openings according to an embodiment of the present disclosure.

FIG. 4B is a top-down view of the first exemplary structure of FIG. 4A. The hinged vertical plane A-A′ is the cut plane of the vertical cross-sectional view of FIG. 4A.

FIG. 4C is a vertical cross-sectional view of the first exemplary structure along the vertical plane C-C′ of FIG. 4B.

FIG. 5A is a vertical cross-sectional view of the first exemplary structure after formation of first-tier support openings and first-tier contact openings according to an embodiment of the present disclosure.

FIG. 5B is a top-down view of the first exemplary structure of FIG. 5A. The hinged vertical plane A-A′ is the plane of the vertical cross-sectional view of FIG. 5A.

FIG. 6 is a vertical cross-sectional view of the first exemplary structure after formation of first-tier sacrificial memory opening fill structures, first-tier sacrificial support opening fill structures, and first-tier sacrificial contact opening fill structures according to an embodiment of the present disclosure.

FIG. 7 is a vertical cross-sectional view of the first exemplary structure after formation of a second alternating stack of second insulating layers and second sacrificial material layers and second stepped surfaces according to an embodiment of the present disclosure.

FIG. 8 is a vertical cross-sectional view of the first exemplary structure after formation of a second insulating liner and a second etch-stop material layer over the second stepped surfaces according to an embodiment of the present disclosure.

FIG. 9 is a vertical cross-sectional view of the first exemplary structure after formation of a second stepped dielectric material portion and an insulating cap layer according to an embodiment of the present disclosure.

FIG. 10A is a vertical cross-sectional view of the first exemplary structure after formation of second-tier memory openings, second-tier support openings, and second-tier contact openings according to an embodiment of the present disclosure.

FIG. 10B is a top-down view of the first exemplary structure of FIG. 10A. The hinged vertical plane A-A′ is the cut plane of the vertical cross-sectional view of FIG. 10A.

FIG. 11A is a vertical cross-sectional view of the first exemplary structure after formation of second-tier sacrificial memory opening fill structures, second-tier sacrificial support opening fill structures, and second-tier sacrificial contact opening fill structures according to an embodiment of the present disclosure.

FIG. 11B is a top-down view of the first exemplary structure of FIG. 11A. The hinged vertical plane A-A′ is the cut plane of the vertical cross-sectional view of FIG. 11A.

FIG. 11C is a vertical cross-sectional view of the first exemplary structure along the vertical plane C-C′ of FIG. 11B.

FIG. 12 is a vertical cross-sectional view of the first exemplary structure after formation of multi-tier memory openings according to an embodiment of the present disclosure.

FIG. 13 is a vertical cross-sectional view of the first exemplary structure after formation of memory opening fill structures according to an embodiment of the present disclosure.

FIG. 14 is a vertical cross-sectional view of the first exemplary structure after formation of a first contact-level dielectric layer and first connection openings according to an embodiment of the present disclosure.

FIG. 15A is a vertical cross-sectional view of the first exemplary structure after formation of contact via cavities according to an embodiment of the present disclosure.

FIG. 15B is a top-down view of the first exemplary structure of FIG. 15A. The hinged vertical plane A-A′ is the plane of the vertical cross-sectional view of FIG. 15A.

FIG. 16 is a vertical cross-sectional view of the first exemplary structure after formation of first-stage in-process finned contact via cavities according to an embodiment of the present disclosure.

FIG. 17 is a vertical cross-sectional view of the first exemplary structure after conformally depositing a conformal dielectric material layer according to an embodiment of the present disclosure.

FIG. 18 is a vertical cross-sectional view of the first exemplary structure after formation of second-stage in-process finned contact via cavities and vertical stacks of annular insulating plates and according to an embodiment of the present disclosure.

FIG. 19 is a vertical cross-sectional view of the first exemplary structure after laterally expanding the second-stage in-process finned contact via cavities to form third-stage in-process finned contact via cavities according to an embodiment of the present disclosure.

FIG. 20 is a vertical cross-sectional view of the first exemplary structure after formation of sacrificial finned cavity fill material structures according to an embodiment of the present disclosure.

FIG. 21A is a vertical cross-sectional view of the first exemplary structure after formation of a second contact-level dielectric layer and second connection openings according to an embodiment of the present disclosure.

FIG. 21B is a top-down view of the first exemplary structure of FIG. 21A. The hinged vertical plane A-A′ is the cut plane of the vertical cross-sectional view of FIG. 21A.

FIG. 21C is a vertical cross-sectional view of the first exemplary structure along the vertical plane C-C′ of FIG. 21B.

FIGS. 22A-22D are sequential vertical cross-sectional views of a region of the first exemplary structure during formation of annular insulating fins around support openings according to an embodiment of the present disclosure.

FIG. 23A is a vertical cross-sectional view of a region of the first exemplary structure after formation of a laterally-extending cavity that laterally surrounds volumes of a set of support openings according to an embodiment of the present disclosure.

FIG. 23B is a horizontal cross-sectional view of the region of the first exemplary structure along the horizontal plane B-B′ of FIG. 23A.

FIG. 24A is a vertical cross-sectional view of the first exemplary structure after formation of dielectric pillar structures and a dielectric support assembly according to an embodiment of the present disclosure.

FIG. 24B is a top-down view of the first exemplary structure of FIG. 24A. The hinged vertical plane A-A′ is the cut plane of the vertical cross-sectional view of FIG. 24A.

FIG. 24C is a vertical cross-sectional view of a region of the first exemplary structure along the cut plane C-C′ of FIG. 24B.

FIG. 24D is a horizontal cross-sectional view of the region of the first exemplary structure along the horizontal plane D-D′ of FIG. 24C.

FIG. 24E is a vertical cross-sectional view of the region of the first exemplary structure along the vertical plane E-E′ of FIG. 24B.

FIG. 25A is a vertical cross-sectional view of the first exemplary structure after formation of lateral isolation trenches according to an embodiment of the present disclosure.

FIG. 25B is a top-down view of the first exemplary structure of FIG. 25A. The hinged vertical plane A-A′ is the plane of the vertical cross-sectional view of FIG. 25A.

FIG. 25C is a vertical cross-sectional view of a region of the first exemplary structure along the cut plane C-C′ of FIG. 25B.

FIG. 26A is a vertical cross-sectional view of the first exemplary structure after formation of laterally-extending cavities according to an embodiment of the present disclosure.

FIG. 26B is a top-down view of the first exemplary structure of FIG. 26A. The hinged vertical plane A-A′ is the plane of the vertical cross-sectional view of FIG. 26A.

FIG. 26C is a vertical cross-sectional view of a region of the first exemplary structure along the cut plane C-C′ of FIG. 26B.

FIG. 27A is a vertical cross-sectional view of the first exemplary structure after formation of electrically conductive layers according to an embodiment of the present disclosure.

FIG. 27B is a top-down view of the first exemplary structure of FIG. 27A. The hinged vertical plane A-A′ is the cut plane of the vertical cross-sectional view of FIG. 27A.

FIG. 27C is a vertical cross-sectional view of a region of the first exemplary structure along the cut plane C-C′ of FIG. 27B.

FIG. 27D is a horizontal cross-sectional view of the region of the first exemplary structure along the horizontal plane D-D′ of FIG. 27C.

FIG. 28 is a vertical cross-sectional view of the first exemplary structure after formation of source regions, insulating spacers, and source contact via structures according to an embodiment of the present disclosure.

FIG. 29A is a vertical cross-sectional view of the first exemplary structure after formation of third connection openings according to an embodiment of the present disclosure.

FIG. 29B is a vertical cross-sectional view of a region of the first exemplary structure of FIG. 29A.

FIG. 30A is a vertical cross-sectional view of the first exemplary structure after removal of the sacrificial finned cavity fill material structures according to an embodiment of the present disclosure.

FIG. 30B is a vertical cross-sectional view of a region of the first exemplary structure of FIG. 30A.

FIG. 31A is a vertical cross-sectional view of the first exemplary structure after formation of contact via structures according to an embodiment of the present disclosure.

FIG. 31B is a top-down view of the first exemplary structure of FIG. 31A. The hinged vertical plane A-A′ is the plane of the vertical cross-sectional view of FIG. 31A.

FIG. 31C is a vertical cross-sectional view of a region of the first exemplary structure along the vertical plane C-C′ of FIG. 31B.

FIG. 31D is a vertical cross-sectional view of a region of the first exemplary structure along the vertical plane D-D′ of FIG. 31B.

FIG. 32 is a vertical cross-sectional view of a region of a second exemplary structure formation of annular insulating fins around support openings according to an embodiment of the present disclosure.

FIG. 33A is a vertical cross-sectional view of a region of the second exemplary structure after formation of a laterally-extending cavity that laterally surrounds volumes of a set of support openings according to an embodiment of the present disclosure.

FIG. 33B is a horizontal cross-sectional view of the region of the second exemplary structure along the horizontal plane B-B′ of FIG. 33A.

FIG. 34A is a vertical cross-sectional view of the second exemplary structure after formation of a dielectric support assembly according to an embodiment of the present disclosure.

FIG. 34B is a top-down view of the second exemplary structure of FIG. 34A. The hinged vertical plane A-A′ is the cut plane of the vertical cross-sectional view of FIG. 34A.

FIG. 34C is a vertical cross-sectional view of a region of the second exemplary structure along the cut plane C-C′ of FIG. 34B.

FIG. 34D is a horizontal cross-sectional view of the region of the second exemplary structure along the horizontal plane D-D′ of FIG. 34C.

FIG. 35A is a vertical cross-sectional view of the second exemplary structure after formation of lateral isolation trenches according to an embodiment of the present disclosure.

FIG. 35B is a top-down view of the second exemplary structure of FIG. 35A. The hinged vertical plane A-A′ is the plane of the vertical cross-sectional view of FIG. 35A.

FIG. 35C is a vertical cross-sectional view of a region of the second exemplary structure along the cut plane C-C′ of FIG. 35B. The vertical plane B-B′ is the cut plane of the vertical cross-sectional view of FIG. 35B.

FIG. 36 is a vertical cross-sectional view of the second exemplary structure after replacement of sacrificial material layers with electrically conductive layers and formation of source regions, insulating spacers, and source contact via structures according to an embodiment of the present disclosure.

FIG. 37A is a vertical cross-sectional view of the second exemplary structure after replacement of the sacrificial finned cavity fill material structures with contact via structures according to an embodiment of the present disclosure.

FIG. 37B is a top-down view of the second exemplary structure of FIG. 37A. The hinged vertical plane A-A′ is the plane of the vertical cross-sectional view of FIG. 37A.

FIG. 37C is a vertical cross-sectional view of a region of the second exemplary structure along the vertical plane C-C′ of FIG. 37B.

FIG. 37D is a vertical cross-sectional view of a region of the second exemplary structure along the vertical plane D-D′ of FIG. 37B.

FIG. 37E is a horizontal cross-sectional view of a region of the second exemplary structure along the vertical plane E-E′ of FIG. 37D.

### DETAILED DESCRIPTION

As discussed above, the present disclosure is directed to a three-dimensional memory device including a dielectric support assembly containing dielectric support pillar structures and a dielectric connection plate, and method of making thereof including replacement of a staircase contact etch-stop layer, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

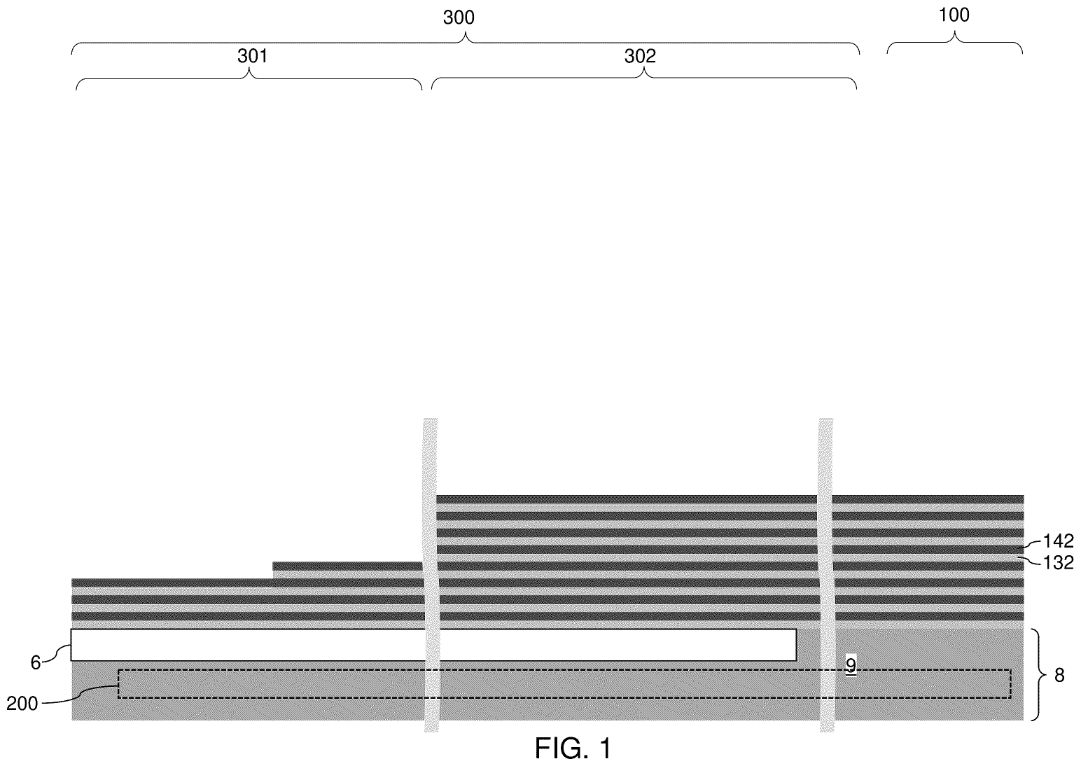

Referring to FIG. 1, a first exemplary structure according to a first embodiment of the present disclosure is illustrated, which includes a substrate 8 containing a semiconductor material layer 9 at least at an upper portion thereof. The semiconductor material layer 9 may comprise a single crystalline semiconductor material layer or a polycrystalline semiconductor material layer. The substrate 8 may or may not comprise additional layers (such as dielectric material layers embedding metal interconnect structures) and/or semiconductor devices (such as a peripheral circuit for controlling operation of a three-dimensional memory array to be subsequently formed) underneath the semiconductor material layer. In one embodiment, the substrate 8 may comprise a commercially available semiconductor wafer, such as a single crystalline silicon wafer. The semiconductor material layer 9 may comprise an upper portion of the silicon wafer, a doped well in the silicon wafer, an epitaxial silicon layer on the silicon wafer, etc.

The first exemplary structure comprises a memory array region 100 and a contact region 300. The memory array region 100 is a region in which a three-dimensional memory array is to be subsequently formed. The contact region 300 is a region in which layer contact via structures contacting electrically conductive lines that function as word lines of the three-dimensional memory array are to be subsequently formed. The contact region 300 may comprise a first contact region 301 in which first contact via structures providing electrical connections to first electrically conductive layers are subsequently formed, and a second contact region 302 in which second contact via structures providing electrical connections to second electrically conductive layers are subsequently formed. The memory array region 100 can be provided adjacent to the contact region 300.

An optional dielectric isolation layer 6 can be formed in an upper portion of the substrate 8, such as when the substrate 8 or the semiconductor material layer 9 comprise heavily doped semiconductor material, such as heavily doped silicon. The dielectric isolation layer 6 may comprise a silicon oxide layer which is located in the contact region 300 and may optionally extend into the memory array region 100. Alternatively, the dielectric isolation layer 6 may be omitted if the substrate 8 and the semiconductor material layer comprise an intrinsic or low doped semiconductor material, which has a relatively high resistivity.

A first alternating stack of first insulating layers 132 and first sacrificial material layers 142 can be formed over the substrate 8. The first insulating layers 132 comprise an insulating material such as undoped silicate glass or a doped silicate glass, and the first sacrificial material layers 142 comprise a sacrificial material such as silicon nitride or a silicon-germanium alloy. The first alternating stack (132, 142) may comprise multiple repetitions of a unit layer stack including a first insulating layer 132 and a first sacrificial material layer 142. The total number of repetitions of the unit layer stack within the first alternating stack (132, 142) may be, for example, in a range from 8 to 1,024, such as from 32 to 256, although lesser and greater number of repetitions may also be employed. Each of the first insulating layers 132 may have a thickness in a range from 20 nm to 100 nm, such as from 30 nm to 60 nm, although lesser and greater thicknesses may also be employed. Each of the first sacrificial material layers 142 may have a thickness in a range from 20 nm to 100 nm, such as from 30 nm to 60 nm, although lesser and greater thicknesses may also be employed.

First stepped surfaces are formed in the first contact region 301. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A first stepped cavity is formed within the volume from which portions of the first alternating stack (132, 142) are removed through formation of the first stepped surfaces. A “stepped cavity” refers to a cavity having stepped surfaces.

The first stepped cavity can have various first stepped surfaces such that the horizontal cross-sectional shape of the first stepped cavity changes in steps as a function of the vertical distance from the top surface of the substrate 8. In one embodiment, the first stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each first sacrificial material layer 142 other than a topmost first sacrificial material layer 142 within the first alternating stack (132, 142) laterally extends farther than any overlying first sacrificial material layer 142 within the first alternating stack (132, 142) in the terrace region. The first stepped surfaces of the first alternating stack (132, 142) continuously extend from the bottommost layer within the first alternating stack (132, 142) to the topmost layer within the first alternating stack (132, 142). Generally, the first stepped surfaces continuously extends from a bottommost layer within the first alternating stack (132, 142) at least to a topmost layer within the first alternating stack (132, 142).

Generally, the first stepped surfaces comprise first horizontally-extending surface segments and first vertically-extending surface segments that are adjoined to each other. The first horizontally-extending surface segments are arranged along a first horizontal direction. A first tapered surface can be formed on the first alternating stack (132, 142). The first tapered surface may laterally extend along the first horizontal direction (e.g., word line direction) hd1, may be inclined along the second horizontal direction (e.g., bit line direction) hd2 which is perpendicular to the first horizontal direction hd1, may have a top edge located within a horizontal plane, and may have a stepped bottom edge that is adjoined to a stepped edge of the first stepped surfaces.

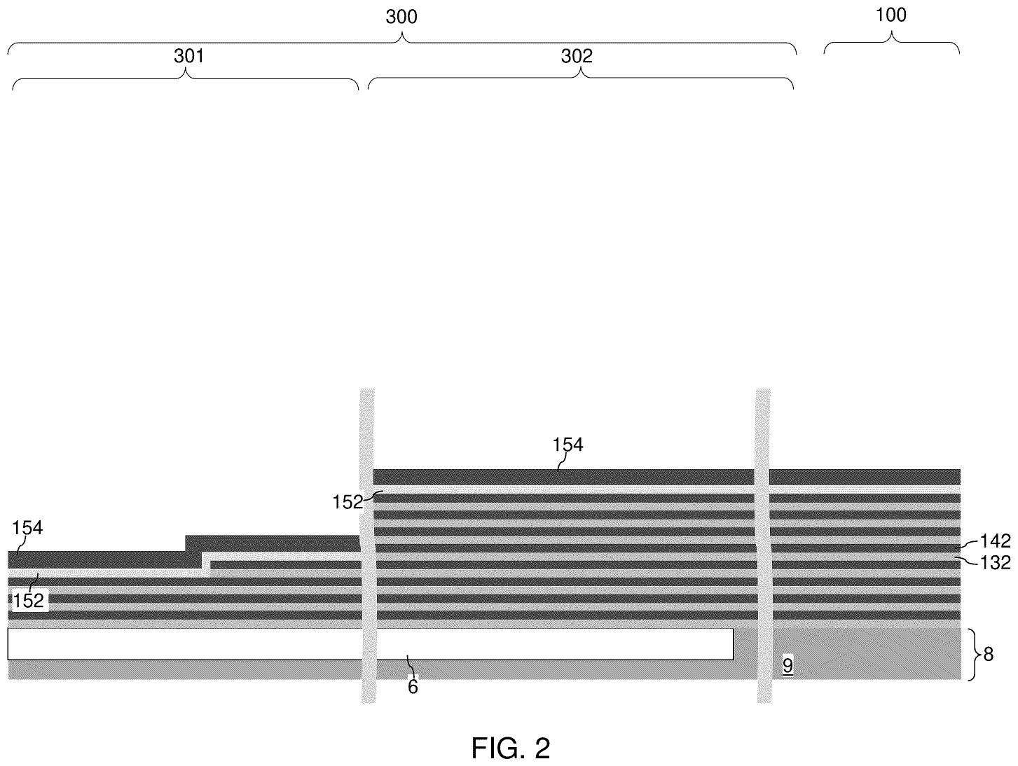

Referring to FIG. 2, a first insulating liner 152 and a first etch-stop material layer 154 can be sequentially deposited over the first stepped surfaces. The first insulating liner 152 may be formed by a first conformal deposition process, and may comprise an insulating material such as undoped silicate glass (i.e., silicon oxide) or a doped silicate glass. The thickness of the first insulating liner 152 may be in a range from 10 nm to 50 nm, such as from 15 nm to 30 nm, although lesser and greater thicknesses may also be employed. The first etch-stop material layer 154 may be formed by a second conformal deposition process, and may comprise a sacrificial material that can be subsequently removed selective to the material of the first insulating liner 152. In one embodiment, the first etch-stop material layer 154 may comprise silicon nitride. The thickness of the first etch-stop material layer 154 is greater than the thickness of the first sacrificial material layers 142, and may be in a range from 40 nm to 150 nm, such as from 60 nm to 100 nm, although lesser and greater thicknesses may also be employed.

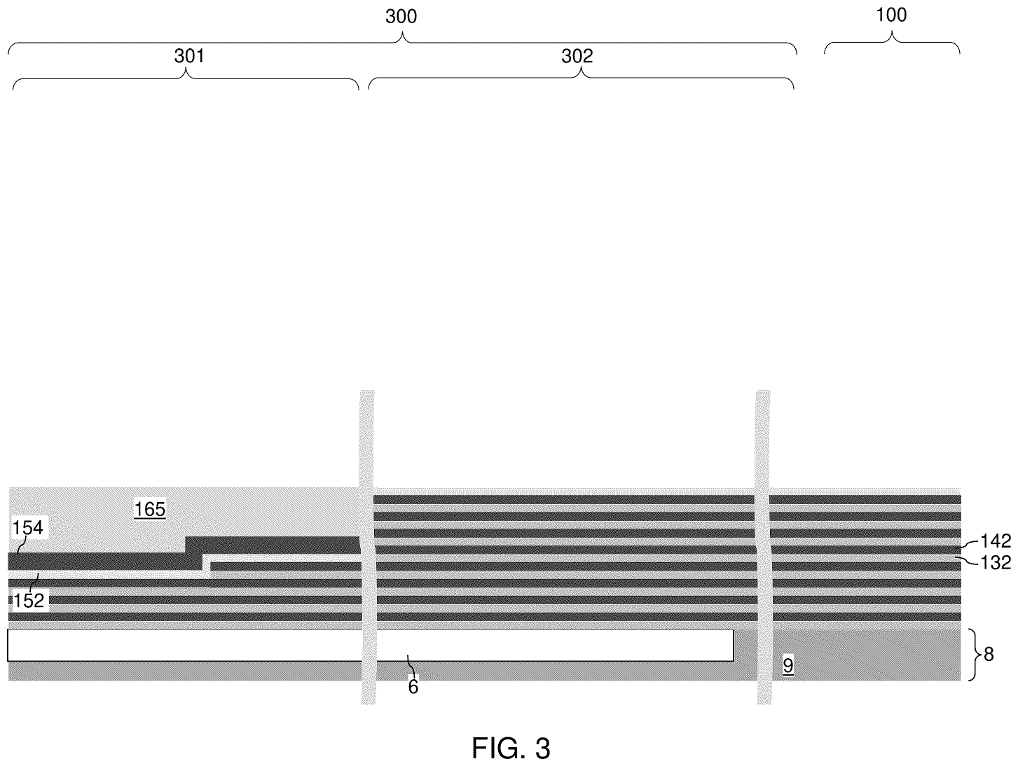

Referring to FIG. 3, a dielectric fill material such as silicon oxide can be deposited in the first stepped cavity. Excess portions of the deposited dielectric fill material can be removed from above the horizontal plane including the top surface of the first etch-stop material layer 154, for example, by chemical mechanical planarization (CMP). A recess etch process can be performed to vertically recess a remaining portion of the dielectric fill material by a vertical recess distance that is the same as the thickness of the first etch-stop material layer 154. Subsequently, an isotropic etch process can be performed to remove a horizontally-extending portion of the first etch-stop material layer 154 selective to the material of the first insulating liner 152. A remaining portion of the dielectric fill material that fills the first stepped cavity constitutes a first stepped dielectric material portion 165. The first stepped dielectric material portion 165 can be retro-stepped.

As used herein, a “retro-stepped” element refers to an element that has first stepped surfaces and a horizontal cross-sectional area that increases monotonically as a function of a vertical distance from a top surface of a substrate on which the element is present. If silicon oxide is employed for the first stepped dielectric material portion 165, the silicon oxide of the first stepped dielectric material portion 165 may, or may not, be doped with dopants such as B, P, and/or F. In one embodiment, the first stepped dielectric material portion 165 overlies and contacts the first stepped surfaces, and has a top surface that is coplanar with the top surface of the horizontally-extending portion of the first insulating liner 152 that overlies the first alternating stack (132, 142) in the memory array region 100.

As discussed above, the first alternating stack (132, 142) comprises a tapered surface laterally extending along the first horizontal direction hd1, tapered along the second horizontal direction hd2, having a top edge located within a horizontal plane, and having a stepped bottom edge that is adjoined to a stepped edge of the first stepped surfaces. The first etch-stop material layer 154 comprises a tapered portion which is tapered along the second horizontal direction hd2, overlying the tapered surface and having a top surface within a horizontal plane including a top surface of the first stepped dielectric material portion 165.

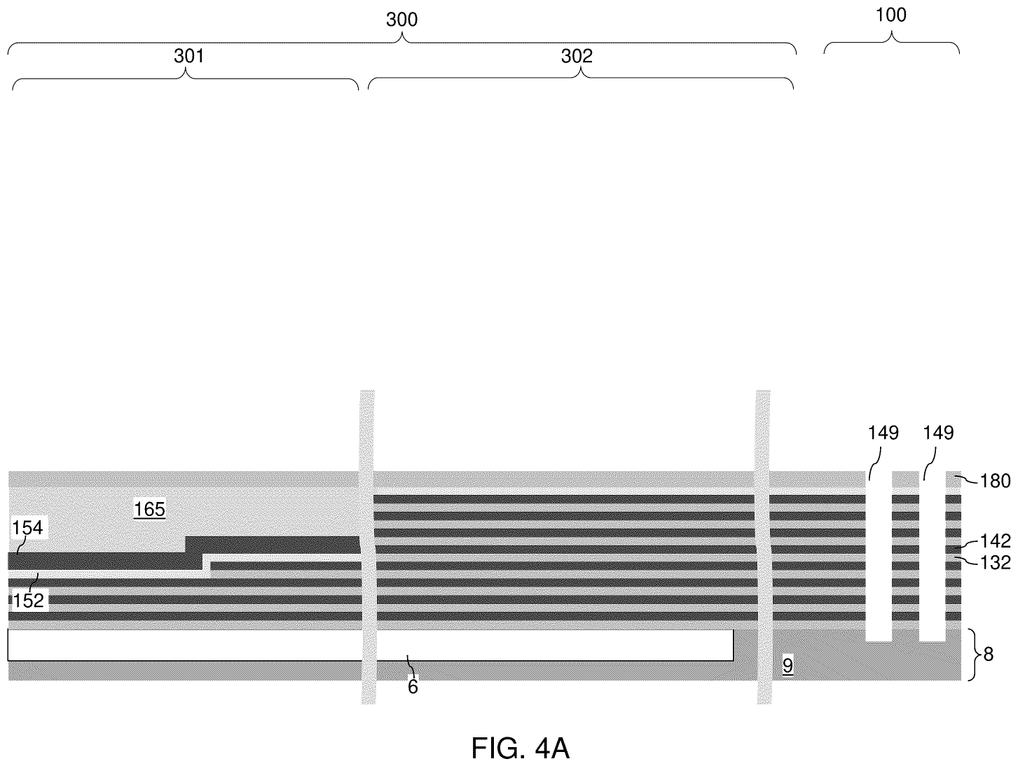

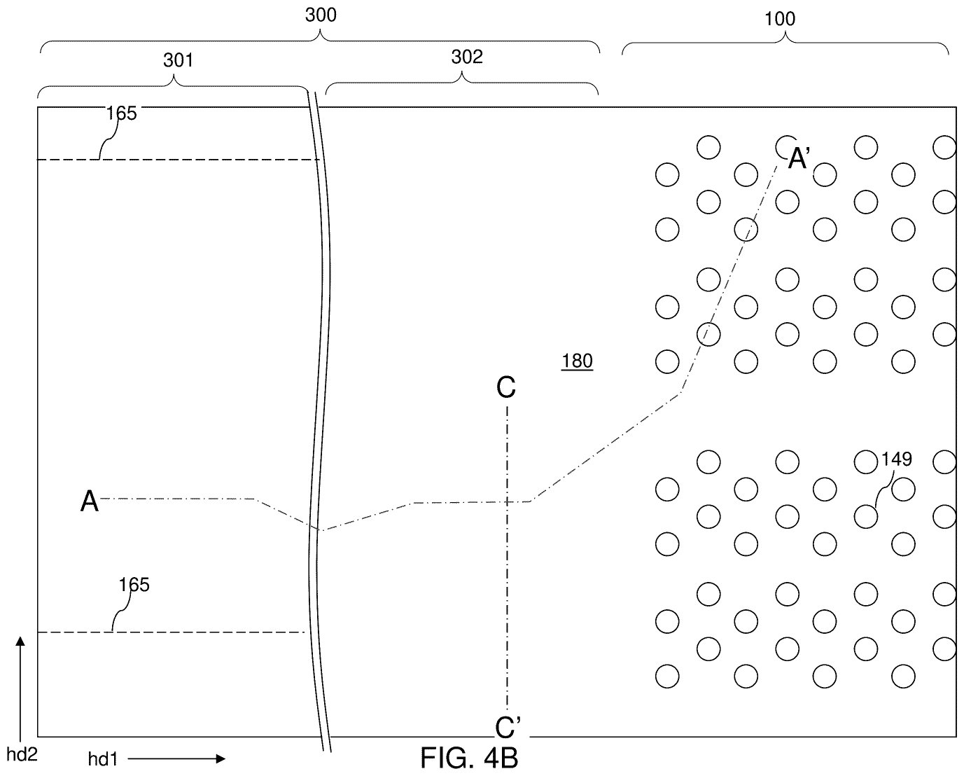

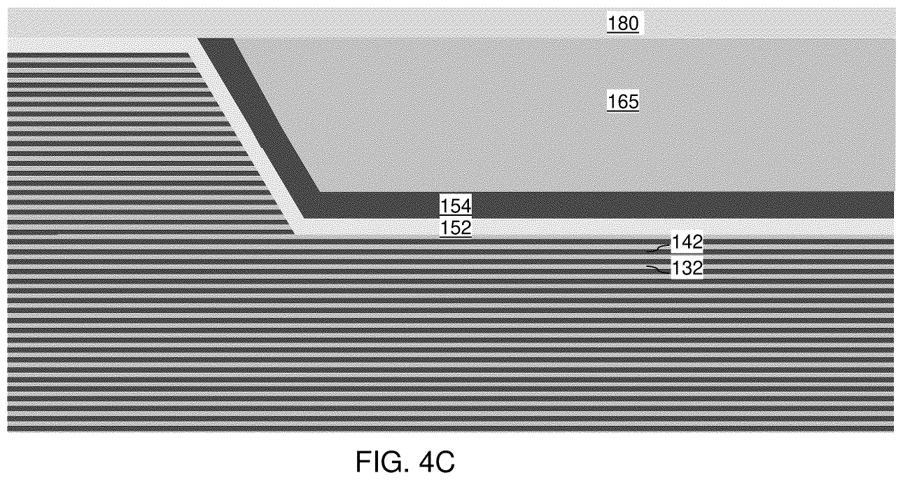

Referring to FIGS. 4A-4C, a dielectric material layer can be formed over the first insulating liner 152 and the first stepped dielectric material portion 165. The dielectric material layer is herein referred to as an inter-tier dielectric layer 180. The inter-tier dielectric layer 180 comprises a dielectric material such as silicon oxide, and may have a thickness in a range from 50 nm to 200 nm, such as 80 nm to 160 nm, although lesser and greater thicknesses may also be employed.

A first photoresist layer (not shown) can be applied over the inter-tier dielectric layer 180, and can be lithographically patterned to form an array of openings in the memory array region 100. An anisotropic etch process can be performed to transfer the pattern of the openings in the first photoresist layer through the inter-tier dielectric layer 180, the first insulating liner 152, and the first alternating stack (132, 142) and optionally into an upper portion of the semiconductor material layer 9. First-tier memory openings 149 can be formed through the inter-tier dielectric layer 180, the first insulating liner 152, and the first alternating stack (132, 142). The depth of overetch of the first-tier memory openings 149 into the semiconductor material layer 9 may be in a range from 0 nm to 50 nm, such as from 5 nm to 30 nm, although greater overetch depths may also be employed. The first photoresist layer can be subsequently removed, for example, by ashing.

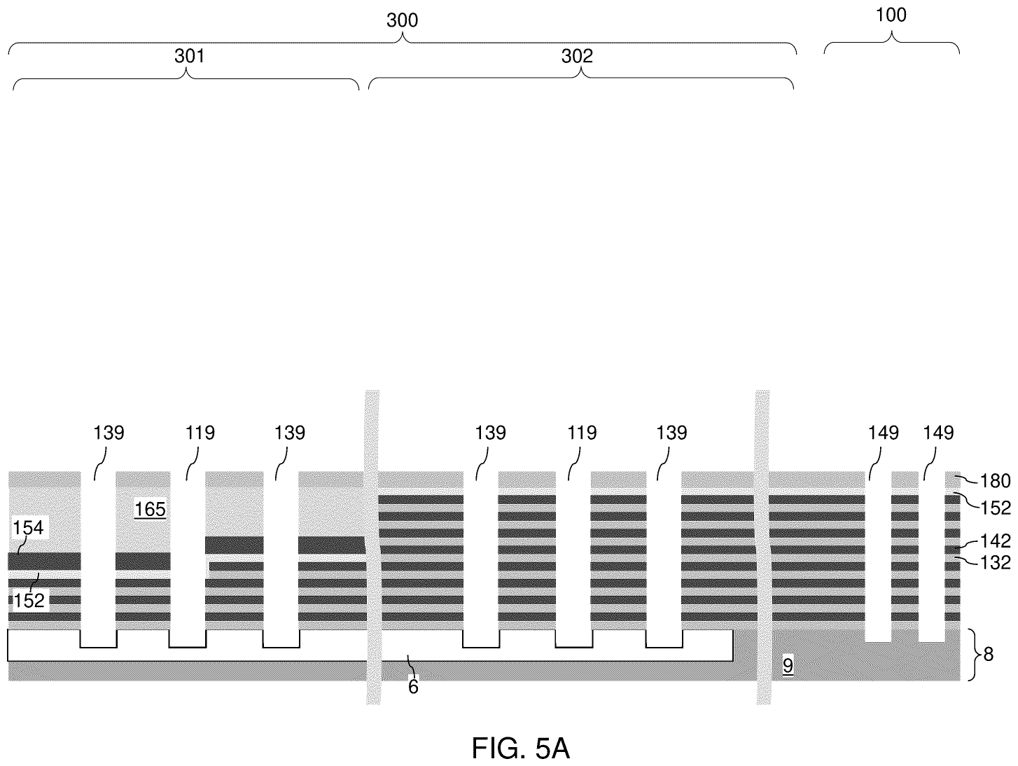

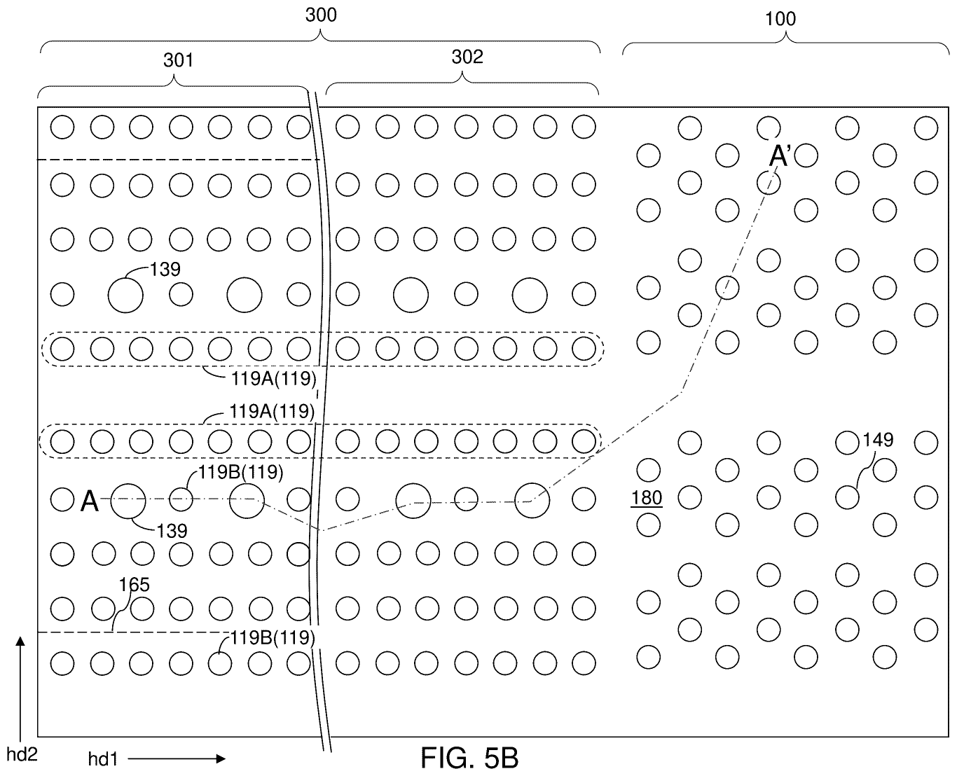

Referring to FIGS. 5A and 5B, a second photoresist layer (not shown) can be applied over the inter-tier dielectric layer 180, and can be lithographically patterned to form openings in the contact region 300. An anisotropic etch process can be performed to transfer the pattern of the openings in the second photoresist layer through the inter-tier dielectric layer 180, the first etch-stop material layer 154, the first insulating liner 152, the first stepped dielectric material portion 165, and portions of the first alternating stack (132, 142) that underlie the first stepped dielectric material portion 165, and optionally into an upper portion of the dielectric isolation layer 6 (if present) or the semiconductor material layer 9 (if layer 6 is omitted). First-tier contact openings 139 can be formed in areas in which layer contact via structures are to be subsequently formed. The layer contact via structures are contact via structures that will contact subsequently formed electrically conductive layers. First-tier support openings 119 can be formed in areas that laterally surround the first-tier contact openings 139. Dielectric pillar structures are subsequently formed in the volumes of the first-tier support openings 119, and are employed as structural support structures during replacement of the first sacrificial material layers 142 with first electrically conductive layers. The second photoresist layer can be subsequently removed, for example, by ashing. The first-tier memory openings 149 may be arranged in rows that extend along a first horizontal direction hd1, which may be a word line direction. Rows of the first-tier memory openings 149 may be laterally spaced apart from each other along a second horizontal direction hd2, which may be perpendicular to the first horizontal direction hd1 and may be a bit line direction. The first-tier contact openings 139 may be arranged in rows that laterally extend along the first horizontal direction hd1.

The first-tier support openings 119 comprise first-type first-tier support openings 119A that are formed in rows adjacent to a gap region that laterally extends along a first horizontal direction hd1 between neighboring clusters of first-tier support openings 119. The first-tier support openings 119 also comprise second-type first-tier support openings 119B that are formed outside of the areas of the first-type first-tier support openings 119A. A subset of the second-type first-tier support openings 119B may be interlaced with the first-tier contact openings 139.

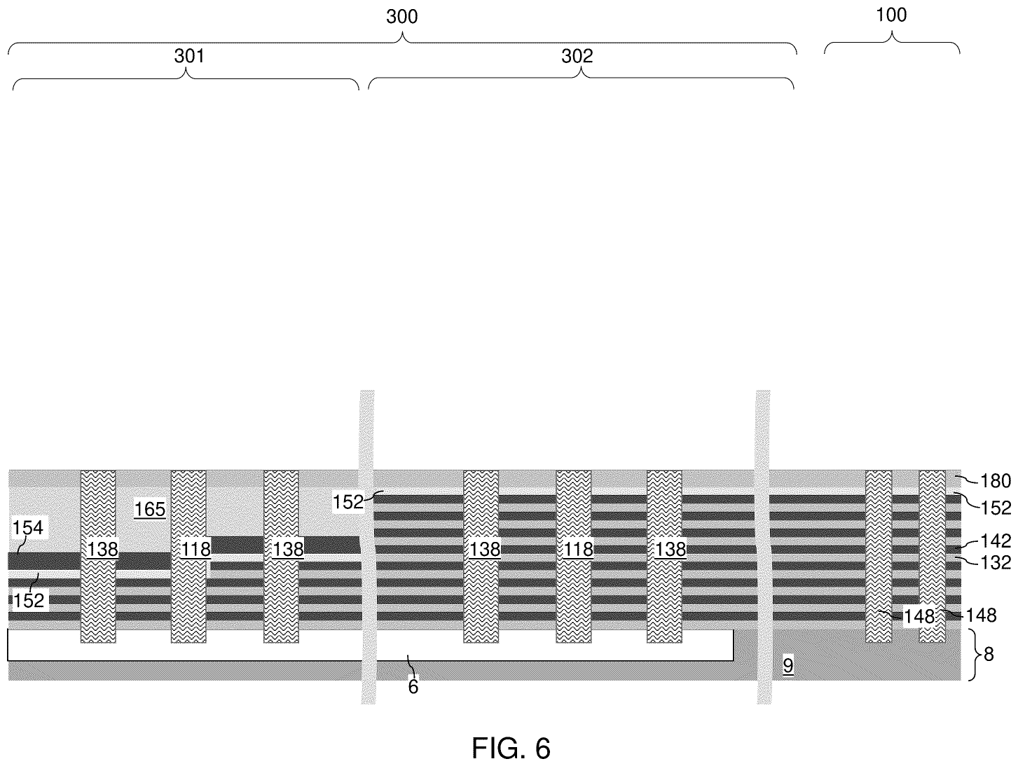

Referring to FIG. 6, an optional etch stop liner (not shown) and a first sacrificial fill material can be deposited in the first-tier memory openings 149, the first-tier support openings 119, and the first-tier contact openings 139. The optional etch stop liner (if present) comprises a thin silicon oxide layer having a thickness in a range from 1 nm to 6 nm. The first sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material.

A planarization process can be performed to remove portions of the first sacrificial fill material from above the horizontal plane including the top surface of the inter-tier dielectric layer 180. In one embodiment, each remaining portion of the first sacrificial fill material has a top surface within a horizontal plane including a top surface of the inter-tier dielectric layer 180. Remaining portions of the first sacrificial fill material that fill the first-tier memory openings 149 constitute first-tier sacrificial memory opening fill structures 148. Remaining portions of the first sacrificial fill material that fill the first-tier support openings 119 constitute first-tier sacrificial support opening fill structures 118. Remaining portions of the first sacrificial fill material that fill the first-tier contact openings 139 constitute first-tier sacrificial contact opening fill structures 138.

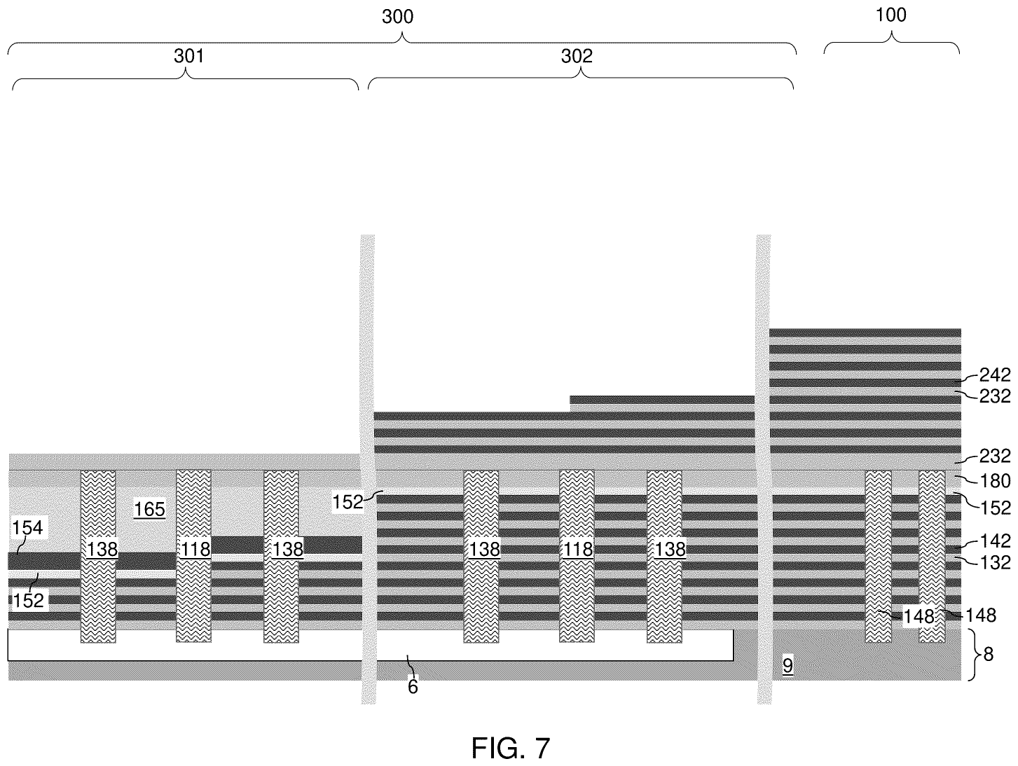

Referring to FIG. 7, a second alternating stack of second insulating layers 232 and second sacrificial material layers 242 can be formed over the first alternating stack (132, 142). The second insulating layers 232 comprise an insulating material, such as undoped silicate glass (i.e., silicon oxide) or a doped silicate glass, and the second sacrificial material layers 242 comprise a sacrificial material, such as silicon nitride. The second alternating stack (232, 242) may comprise multiple repetitions of a unit layer stack including a second insulating layer 232 and a second sacrificial material layer 242. The total number of repetitions of the unit layer stack within the second alternating stack (232, 242) may be, for example, in a range from 8 to 1,024, such as from 32 to 256, although lesser and greater number of repetitions may also be employed. Each of the second insulating layers 232 may have a thickness in a range from 20 nm to 100 nm, such as from 30 nm to 60 nm, although lesser and greater thicknesses may also be employed. Each of the second sacrificial material layers 242 may have a thickness in a range from 20 nm to 100 nm, such as from 30 nm to 60 nm, although lesser and greater thicknesses may also be employed. While two alternating stacks are provided in this embodiment, in other embodiment only one alternating stack or more than two alternating stacks (e.g., three alternating stacks) may be used.

Second stepped surfaces are formed in the second contact region 302. A second stepped cavity is formed within the volume from which portions of the second alternating stack (232, 242) are removed through formation of the second stepped surfaces. The second stepped cavity can have various second stepped surfaces such that the horizontal cross-sectional shape of the second stepped cavity changes in steps as a function of the vertical distance from the top surface of the substrate 8. In one embodiment, the second stepped cavity can be formed by repetitively performing a set of processing steps. The set of processing steps can include, for example, an etch process of a second type that vertically increases the depth of a cavity by one or more levels, and an etch process of a second type that laterally expands the area to be vertically etched in a subsequent etch process of the second type.

Each second sacrificial material layer 242 other than a topmost second sacrificial material layer 242 within the second alternating stack (232, 242) laterally extends farther than any overlying second sacrificial material layer 242 within the second alternating stack (232, 242) in the terrace region. The second stepped surfaces of the second alternating stack (232, 242) continuously extend from the bottommost layer within the second alternating stack (232, 242) to the topmost layer within the second alternating stack (232, 242). Generally, the second stepped surfaces continuously extends from a bottommost layer within the second alternating stack (232, 242) at least to a topmost layer within the second alternating stack (232, 242).

Generally, the second stepped surfaces comprise second horizontally-extending surface segments and second vertically-extending surface segments that are adjoined to each other. The second horizontally-extending surface segments are arranged along the first horizontal direction hd1. A second tapered surface can be formed on the second alternating stack (232, 242). The second tapered surface may laterally extend along the first horizontal direction hd1, may be inclined along the second horizontal direction hd2, may have a top edge located within a horizontal plane, and may have a stepped bottom edge that is adjoined to a stepped edge of the second stepped surfaces.

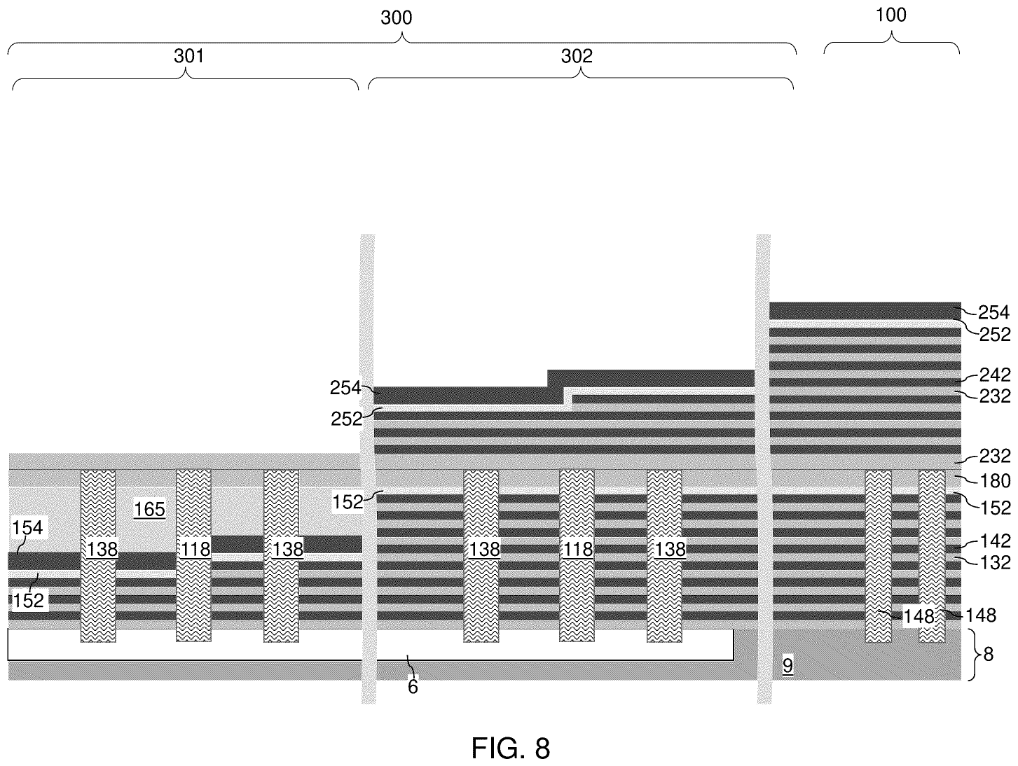

Referring to FIG. 8, a second insulating liner 252 and a second etch-stop material layer 254 can be sequentially deposited over the second stepped surfaces. The second insulating liner 252 may be formed by a conformal deposition process, and may comprise an insulating material such as undoped silicate glass or a doped silicate glass. The thickness of the second insulating liner 252 may be the same as that of the first insulating liner 152. The second etch-stop material layer 254 may be formed by a conformal deposition process, and may comprise a sacrificial material that can be subsequently removed selective to the material of the second insulating liner 252. In one embodiment, the second etch-stop material layer 254 may comprise silicon nitride. The thickness of the second etch-stop material layer 254 is greater than the thickness of the second sacrificial material layers 242, and may be the same as that of the first etch-stop material layer 154.

A photoresist layer (not shown) can be applied over the second etch-stop material layer 254, and can be lithographically patterned such that the photoresist layer covers the memory array region 100 and the second contact region 302, and does not cover the first contact region 301. A first etch process can be performed to remove unmasked portions of the second etch-stop material layer 254 in the first contact region 301. A second etch process can be performed to remove unmasked portions of the second insulating liner 252 in the first contact region 301. The photoresist layer can be subsequently removed, for example, by ashing.

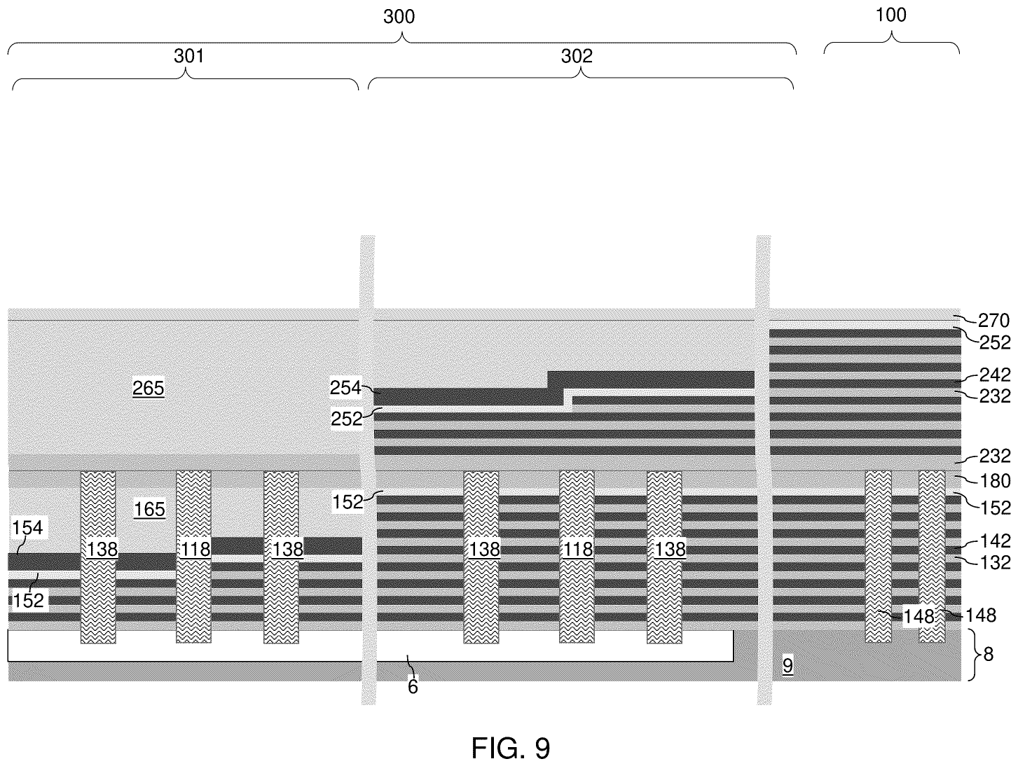

Referring to FIG. 9, a dielectric fill material, such as silicon oxide, can be deposited in the second stepped cavity. Excess portions of the deposited dielectric fill material can be removed from above the horizontal plane including the top surface of the second etch-stop material layer 254, for example, by chemical mechanical planarization (CMP). A recess etch process can be performed to vertically recess a remaining portion of the dielectric fill material by a vertical recess distance that is the same as the thickness of the second etch-stop material layer 254. Subsequently, an isotropic etch process can be performed to remove a horizontally-extending portion of the second etch-stop material layer 254 selective to the material of the second insulating liner 252. A remaining portion of the dielectric fill material that fills the second stepped cavity constitutes a second stepped dielectric material portion 265.

If silicon oxide is employed for the second stepped dielectric material portion 265, the silicon oxide of the second stepped dielectric material portion 265 may, or may not, be doped with dopants such as B, P, and/or F. In one embodiment, the second stepped dielectric material portion 265 overlies and contacts the second stepped surfaces, and has a top surface that is coplanar with the top surface of the horizontally-extending portion of the second insulating liner 252 that overlies the second alternating stack (232, 242) in the memory array region 100.

As discussed above, the second alternating stack (232, 242) comprises a tapered surface laterally extending along the first horizontal direction hd1, inclined along the second horizontal direction hd2, having a top edge located within a horizontal plane, and having a stepped bottom edge that is adjoined to a stepped edge of the second stepped surfaces. The second etch-stop material layer 254 comprises a tapered portion inclined along the second horizontal direction hd2, overlying the tapered surface and having a top surface within a horizontal plane including a top surface of the second stepped dielectric material portion 265.

An insulating cap layer 270 can be formed over the second insulating liner 252 and the second stepped dielectric material portion 265. The insulating cap layer 270 comprises a dielectric material, such as silicon oxide, and may have a thickness in a range from 50 nm to 200 nm, such as 80 nm to 260 nm, although lesser and greater thicknesses may also be employed.

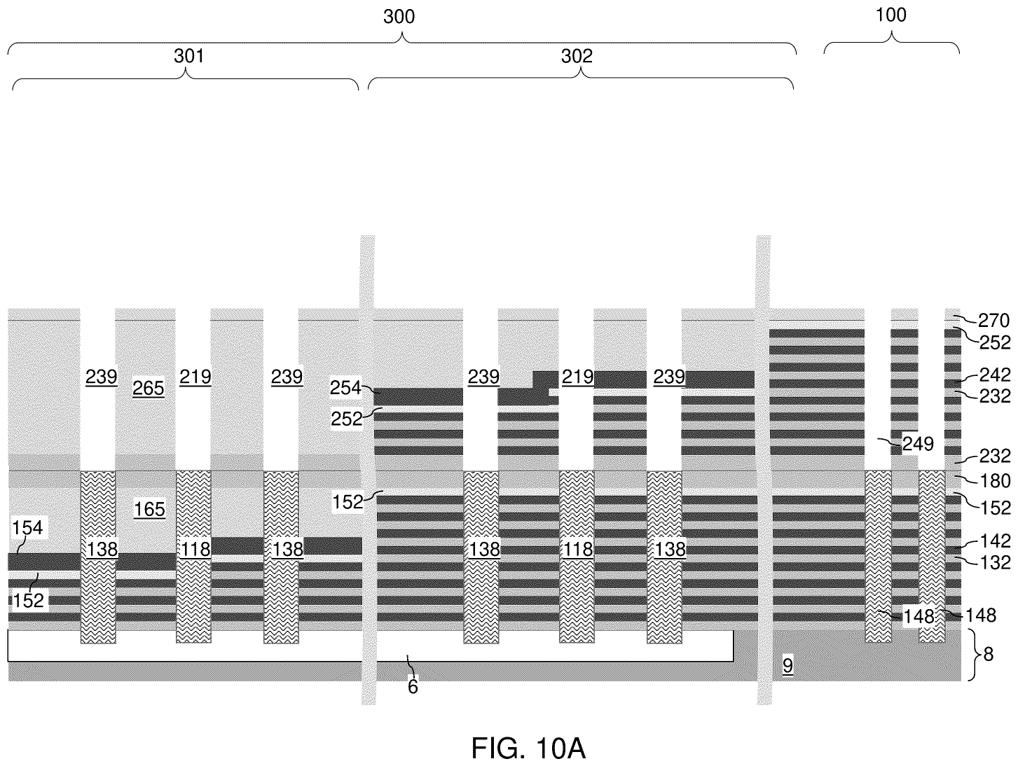

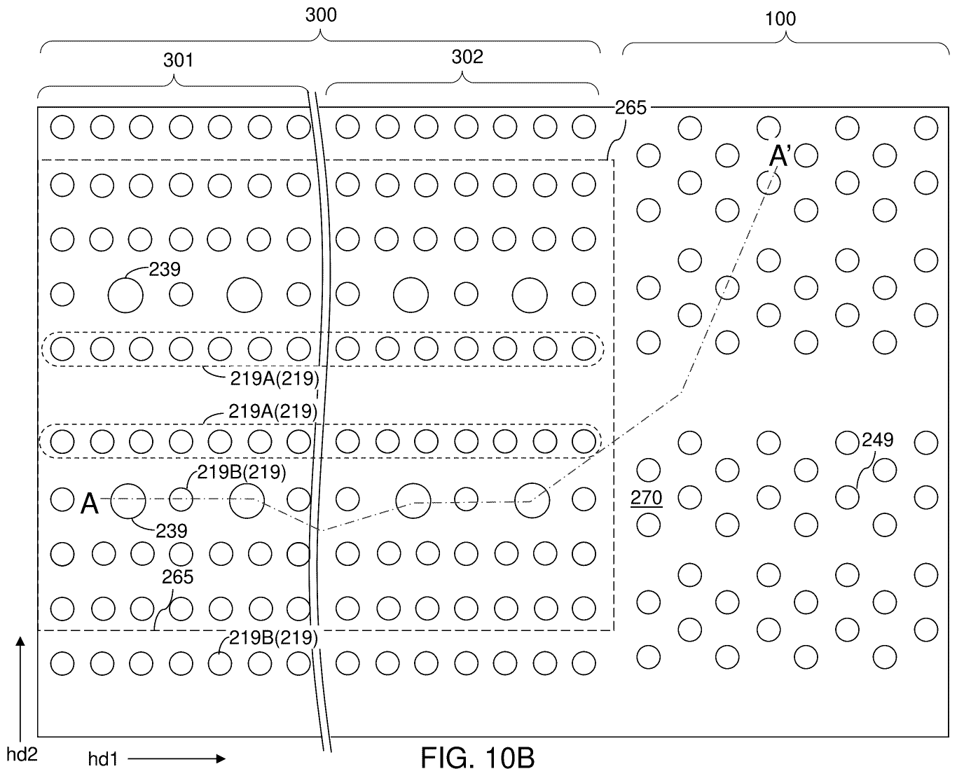

Referring to FIGS. 10A and 10B, a photoresist layer (not shown) can be applied over the insulating cap layer 270, and can be lithographically patterned to form openings over areas of the first-tier sacrificial memory opening fill structures 148, the first-tier sacrificial contact opening fill structures 138, and the first-tier sacrificial support opening fill structures 118. An anisotropic etch process can be performed to transfer the pattern of the openings in the photoresist layer through the insulating cap layer 270, the second stepped dielectric material portion 265, the second etch-stop material layer 254, the second insulating liner 252, and portions of the second alternating stack (232, 242) that underlie the second stepped dielectric material portion 265. Second-tier memory openings 249 can be formed over the first-tier sacrificial memory opening fill structures 148; second-tier contact openings 239 can be formed over the first-tier sacrificial contact opening fill structures 138; and second-tier support openings 219 can be formed over the first-tier sacrificial support opening fill structures 118.

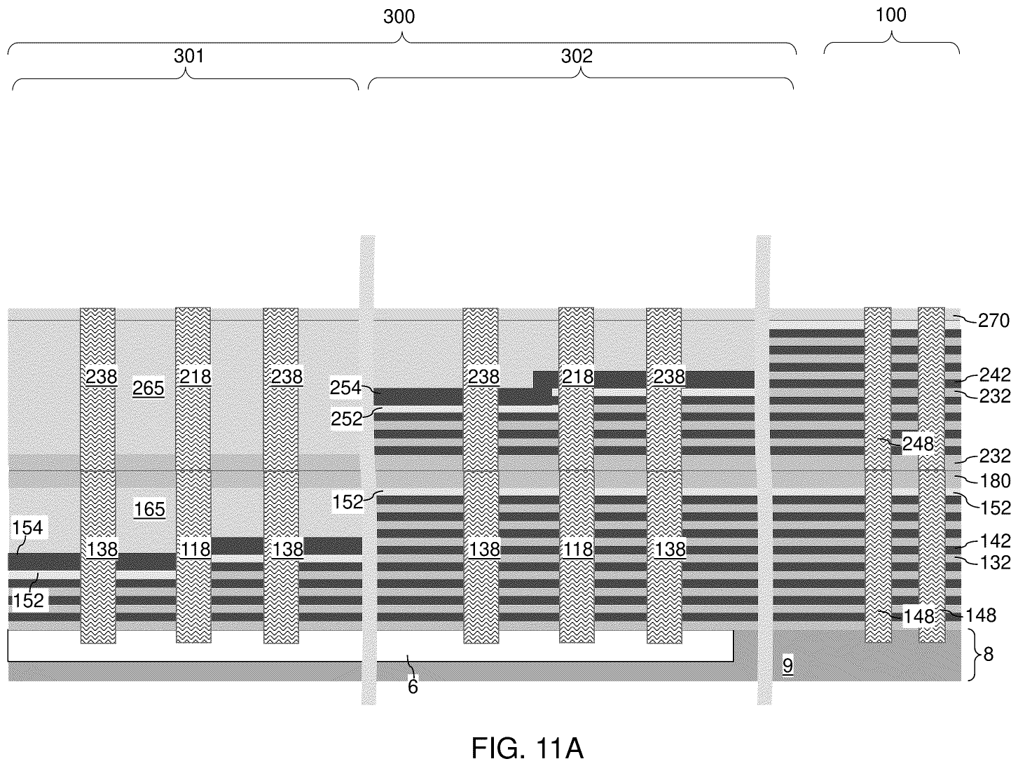

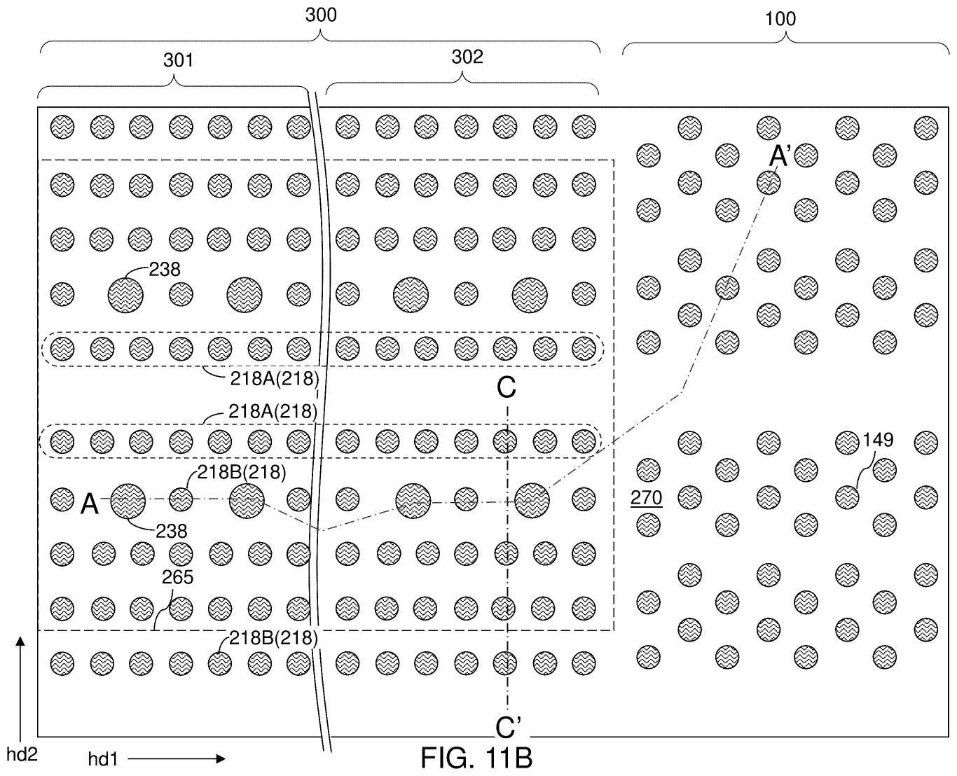

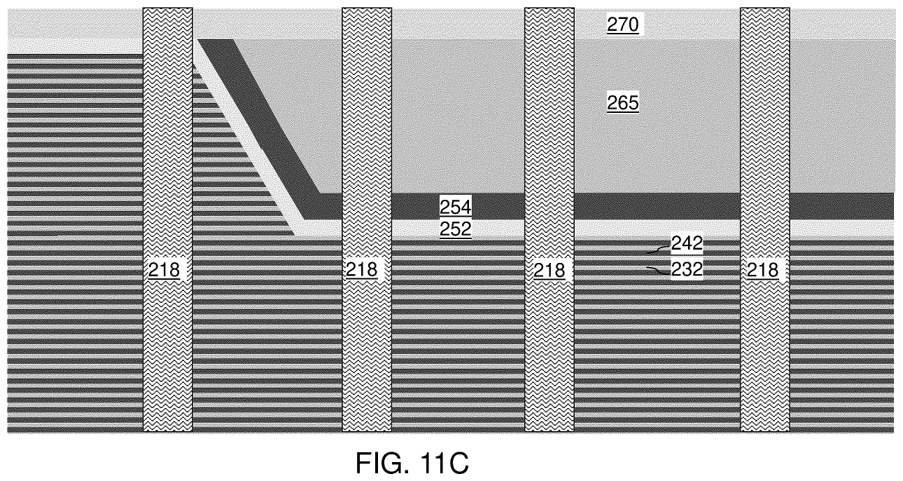

Referring to FIGS. 11A-11C, an optional etch stop liner (not shown) and a second sacrificial fill material can be deposited in the second-tier memory openings 249, the second-tier support openings 229, and the second-tier contact openings 239. The optional etch stop liner (if present) comprises a thin silicon oxide layer having a thickness in a range from 2 nm to 6 nm. The second sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material.

A planarization process can be performed to remove portions of the second sacrificial fill material from above the horizontal plane including the top surface of the insulating cap layer 270. In one embodiment, each remaining portion of the second sacrificial fill material has a top surface within a horizontal plane including a top surface of the insulating cap layer 270. Remaining portions of the second sacrificial fill material that fill the second-tier memory openings 249 constitute second-tier sacrificial memory opening fill structures 248. Remaining portions of the second sacrificial fill material that fill the second-tier support openings 229 constitute second-tier sacrificial support opening fill structures 218. Remaining portions of the second sacrificial fill material that fill the second-tier contact openings 239 constitute second-tier sacrificial contact opening fill structures 238.

The second-tier sacrificial support opening fill structures 218 comprise first-type second-tier sacrificial support opening fill structures 218A that are formed in rows adjacent to a gap region that laterally extends along a first horizontal direction hd1 between neighboring clusters of second-tier sacrificial support opening fill structures 218 (e.g., between memory block regions). The second-tier sacrificial support opening fill structures 218 also comprise second-type second-tier sacrificial support opening fill structures 218B that are formed outside of the areas of the first-type second-tier sacrificial support opening fill structures 218A. A subset of the second-type second-tier sacrificial support opening fill structures 218B may be interlaced with the second-tier sacrificial contact opening fill structures 238.

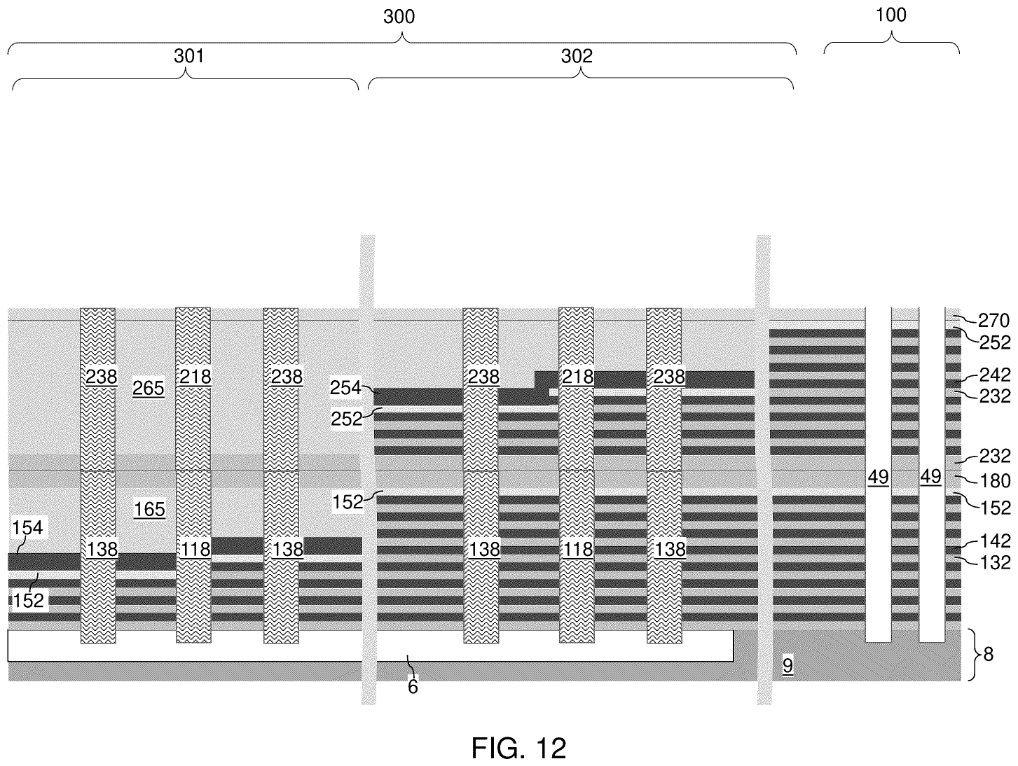

Referring to FIG. 12, a photoresist layer (not shown) may be applied over the insulating cap layer 270, and can be lithographically patterned to cover the contact region 300 without covering the memory array region 100. The second-tier sacrificial memory opening fill structures 248 and the first-tier sacrificial memory opening fill structures 148 can be subsequently removed selective to the materials of the insulating cap layer 270, the alternating stacks {(132, 142), (232, 242)}, the inter-tier dielectric layer 180, the etch-stop material layers (154, 254), and the insulating liners (152, 252). Multi-tier memory openings 49, which are also referred to as memory openings 49, are formed in the volumes from which the second-tier sacrificial memory opening fill structures 248 and the first-tier sacrificial memory opening fill structures 148 are removed. The photoresist layer can be subsequently removed, for example, by ashing.

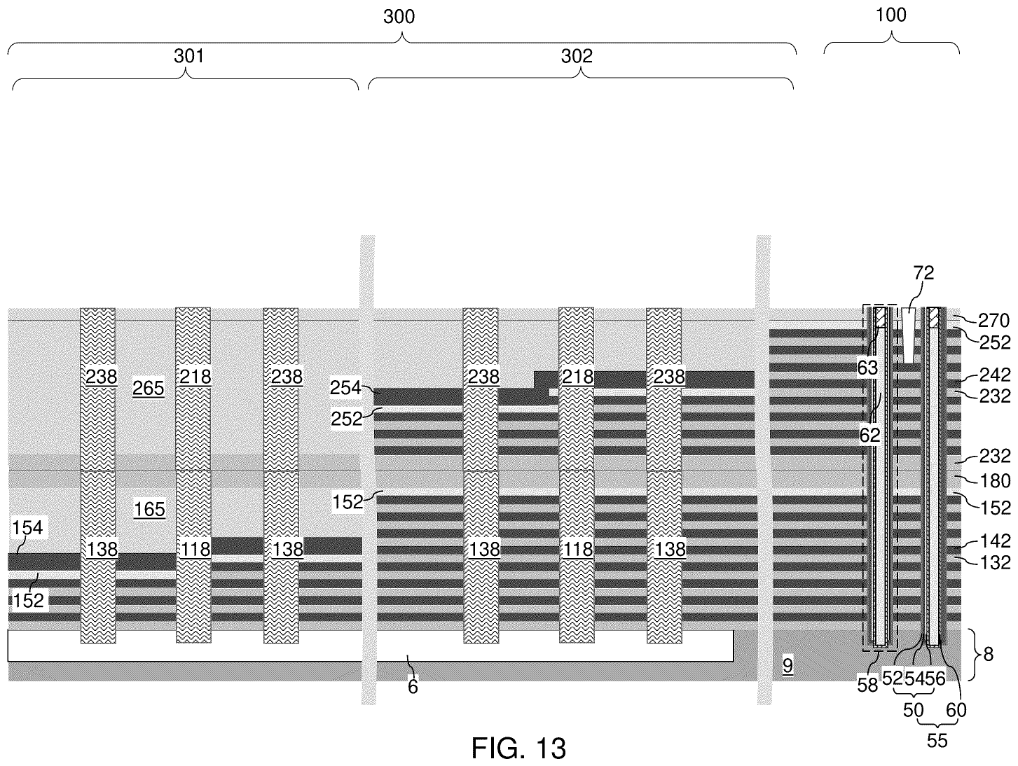

Referring to FIG. 13, a sequence of processing steps can be performed to form a memory opening fill structure 58 within each inter-tier memory opening 49. For example, a memory film 50 can be formed within each of the memory openings 49. The memory films 50 may include any memory material that can store information by charge trapping, a change in electrical resistivity, a change in the direction of ferroelectric polarization (e.g., in a ferroelectric material), or any other material that can store information therein. For example, each memory film 50 may comprise a layer stack including a blocking dielectric layer 52, a charge storage material layer 54, and a tunneling dielectric layer 56. In one embodiment, the memory films 50 can be formed by depositing material layers and/or material portions and by removing excess portions of the material layers and/or the material portions from outside and the bottoms of the memory openings 49, for example, by performing an anisotropic etch process (e.g., a sidewall spacer etch process). In one embodiment, the blocking dielectric layer 52 may comprise a silicon oxide or an aluminum oxide layer. The charge storage material layer 54 may comprise a silicon nitride layer. The tunneling dielectric layer 56 may comprise a silicon oxide layer or an “ONO” stack of silicon oxide/silicon nitride/silicon oxide layers.

A vertical semiconductor channel 60 can be formed in each of the memory openings 49 by conformal deposition of a semiconductor channel material (e.g., amorphous silicon or polysilicon) having a doping of a first conductivity type. The semiconductor channel material may have a doping of a same conductivity type as the horizontal semiconductor channels (not expressly shown) located in the substrate 9. A dielectric fill material can be deposited in the remaining volumes of the memory openings 49, and can be vertically recessed to form a dielectric core 62. A semiconductor material (e.g., amorphous silicon or polysilicon) having a doping of a second conductivity type can be deposited over each dielectric core 62 at a top end of each vertical semiconductor channel 60 to form a drain region 63 within each of the memory openings 49. The second conductivity type is opposite of the first conductivity type. Each contiguous combination of a memory film 50 and a vertical semiconductor channel 60 constitutes a memory stack structure 55. Each memory stack structure 55 comprises a respective vertical stack of memory elements. For example, each vertical stack of memory elements may comprise portions of the charge storage material layer 54 located at the levels of the sacrificial material layers (142, 242) which are subsequently replaced with electrically conductive layers.

Generally, the memory opening fill structures 58 are formed in the memory openings 49. Each of the memory opening fill structures 58 comprises a respective vertical semiconductor channel 60, a respective vertical stack of memory elements (e.g., portions of a memory film 50), a drain region 63 and an optional dielectric core 62. In one embodiment, drain-select-level dielectric isolation structures 72 can be formed through the insulating cap layer 270, the second insulating liner 252, and an uppermost set of second sacrificial material layers 242 which will be replaced with drain side select gate electrodes at a subsequent step.

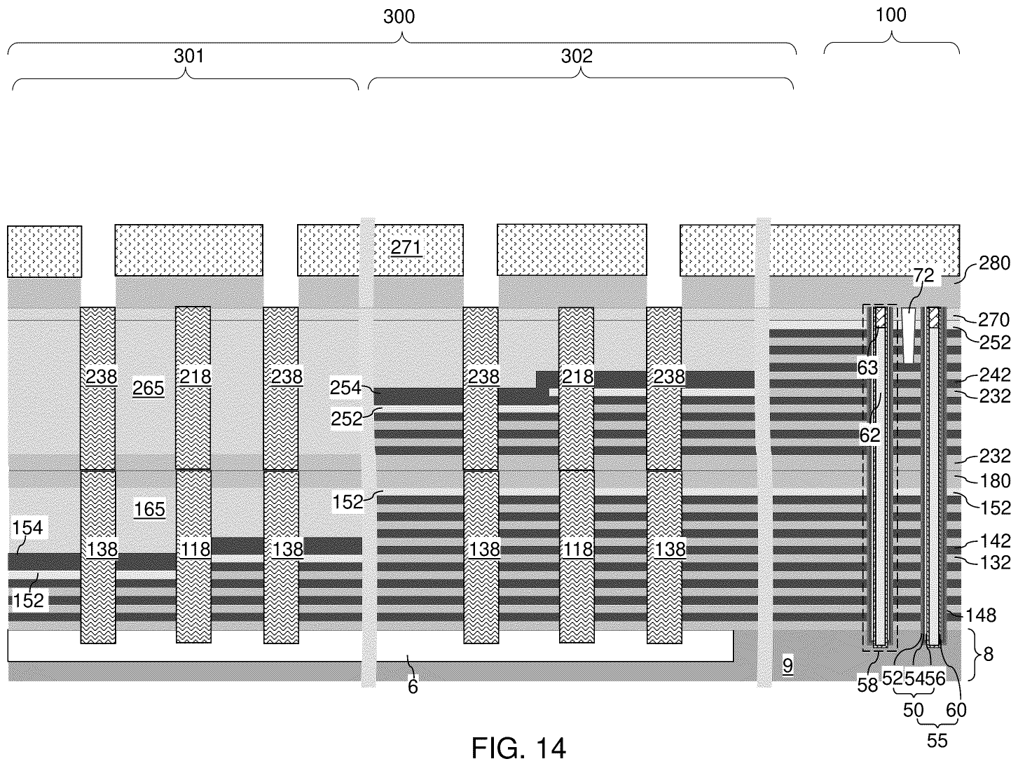

Referring to FIG. 14, a first contact-level dielectric layer 280 can be formed over the insulating cap layer 270. The first contact-level dielectric layer 280 comprises a dielectric material such as silicon oxide, and may have a thickness in a range from 100 m to 400 nm, although lesser and greater thicknesses may also be employed. A photoresist layer 271 can be applied over the first contact-level dielectric layer 280, and can be lithographically patterned to form openings over the areas of the second-tier sacrificial contact opening fill structures 238. An anisotropic etch process can be performed to form openings through the first contact-level dielectric layer 280 over the second-tier sacrificial contact opening fill structures 238.

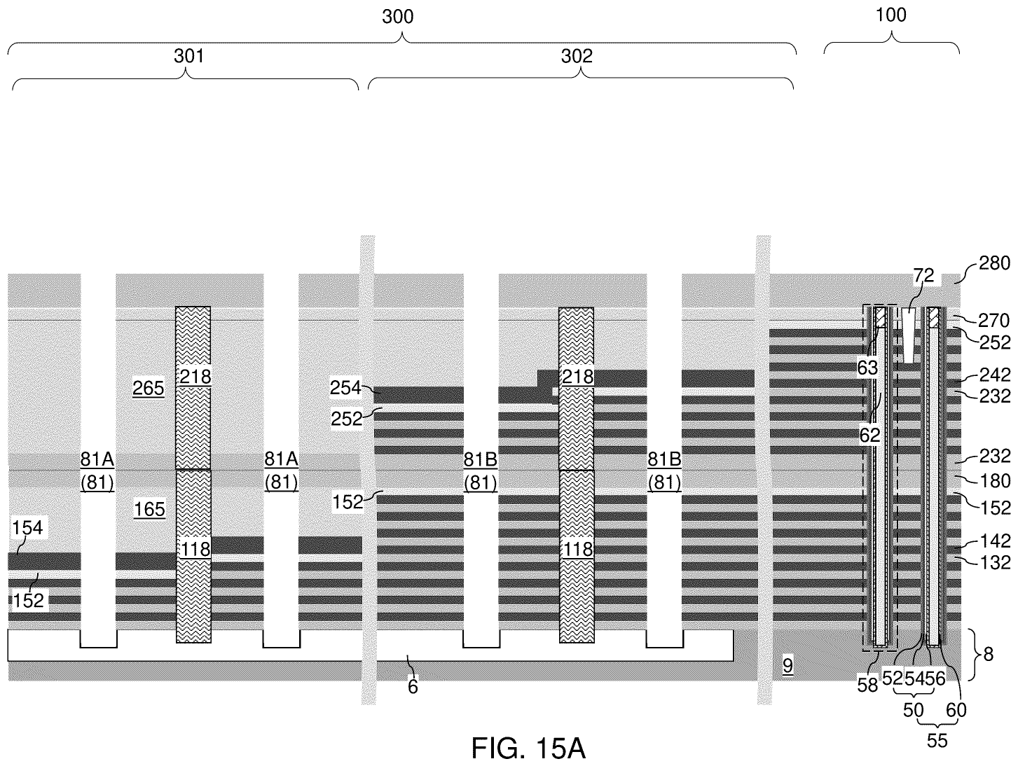

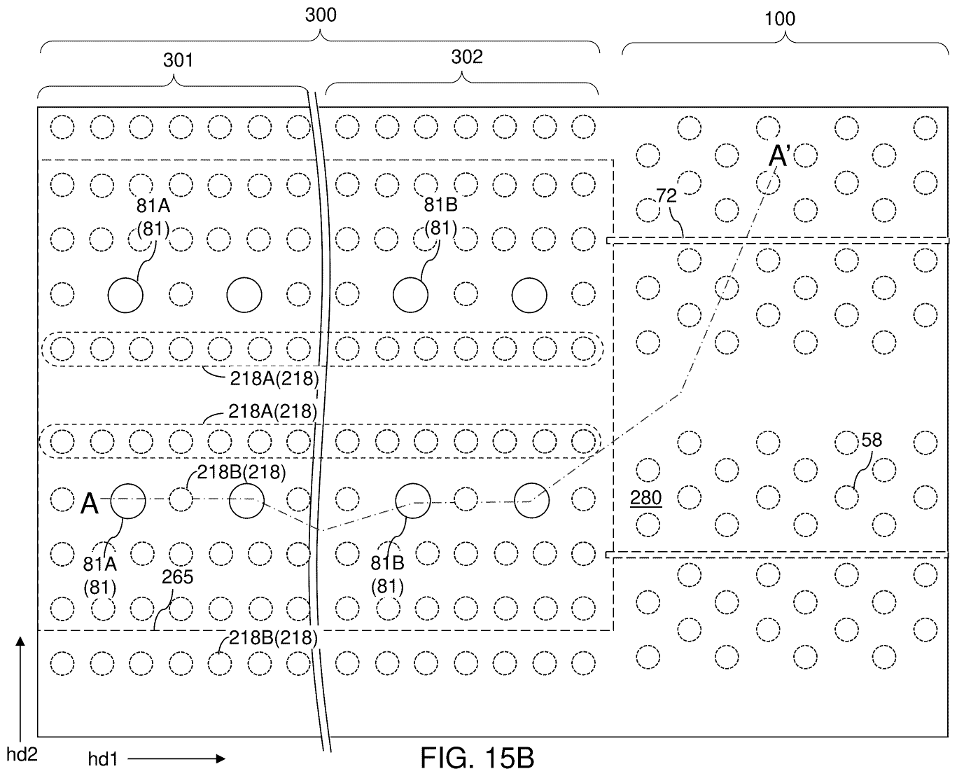

Referring to FIGS. 15A and 15B, the second-tier sacrificial contact opening fill structures 238 and the first-tier sacrificial contact opening fill structures 138 can be subsequently removed selective to the materials of the first contact-level dielectric layer 280, the insulating cap layer 270, the stepped dielectric material portions (165, 265), the alternating stacks {(132, 142), (232, 242)}, the inter-tier dielectric layer 180, the etch-stop material layers (154, 254), and the insulating liners (152, 252). The photoresist layer 271 may be removed during or after removal of the second-tier sacrificial contact opening fill structures 238 and the first-tier sacrificial contact opening fill structures 138. Contact via cavities 81 are formed in the volumes from which the second-tier sacrificial contact opening fill structures 238 and the first-tier sacrificial contact opening fill structures 138 are removed. The contact via cavities 81 comprise first contact via cavities 81A that are formed in the first contact region 301 and extending through the second stepped dielectric material portion 265, the first stepped dielectric material portion 165, and the first alternating stack (132, 142); and second contact via cavities 81B that are formed in the second contact region 302 and extending through the second stepped dielectric material portion 265, the first alternating stack (132, 142) and the second alternating stack (232, 242).

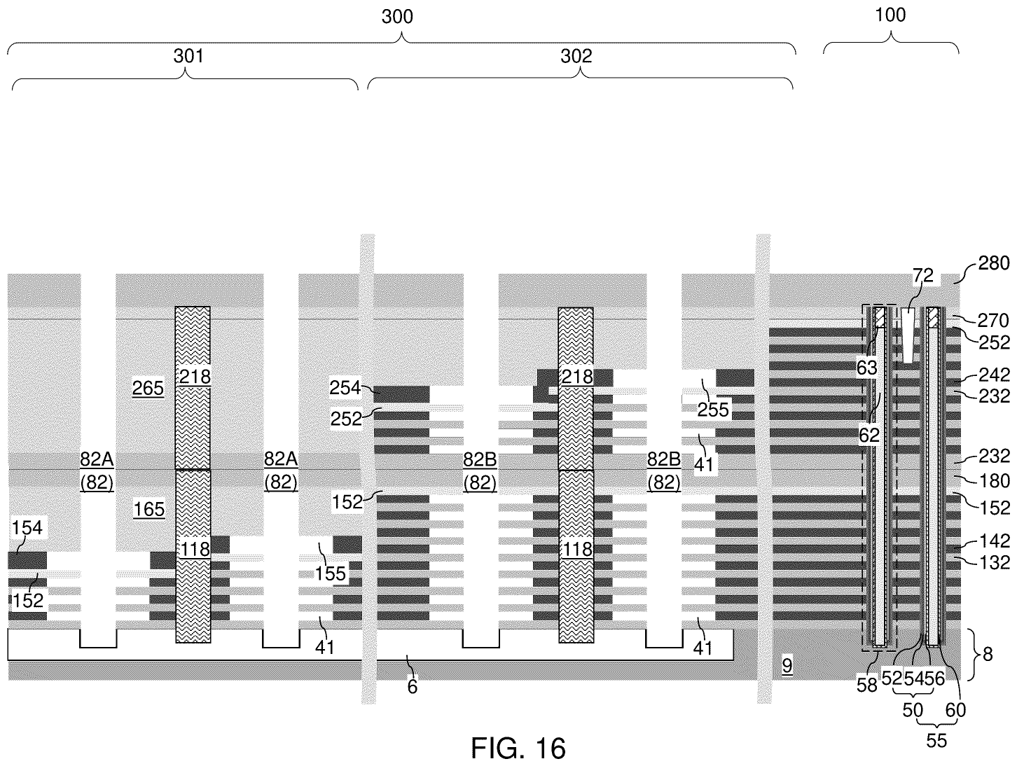

Referring to FIG. 16, a first isotropic etch process can be performed to isotropically recess the material of the sacrificial material layers (142, 242), the first etch-stop material layer 154, and the second etch-stop material layer 254 selective to the materials of the first contact-level dielectric layer 280, the insulating cap layer 270, the insulating layers (132, 232), the inter-tier dielectric layer 180, the insulating liners (152, 252), and the dielectric isolation layer 6 (if present). For example, if the sacrificial material layers (142, 242), the first etch-stop material layer 154, and the second etch-stop material layer 254 comprise silicon nitride, a wet etch process employing hot phosphoric acid can be performed to laterally recess the sacrificial material layers (142, 242).

Generally, sidewalls of the sacrificial material layers (142, 242), the first etch-stop material layer 154, and the second etch-stop material layer 254 may be laterally recessed relative to sidewalls of the insulating layers (132, 232) and the stepped dielectric material portions (165, 265) around the contact via cavities 81. Lateral recesses 41 are formed in volumes from which the materials of the sacrificial material layers (142, 242) are removed. The lateral recesses 41 may have a width of 50 nm to 250 nm, such as 100 nm to 150 nm, and may be set to obtain a desired electric field between word lines and layer contact via structures to be formed in subsequent steps, as will be described below. A first annular cavity 155 can be formed in each volume from which an annular portion of the first etch-stop material layer 154 is removed around a respective one of the first contact via cavities 81A. A second annular cavity 255 can be formed in each volume from which an annular portion of the second etch-stop material layer 254 is removed around a respective one of the second contact via cavities 81B.

Generally, the first isotropic etch process etches proximal portions of the first etch-stop material layer 154 and the first sacrificial material layers 142 from around each first contact via cavity 81A to form a respective finned cavity, which is herein referred to as a first first-stage in-process finned contact via cavity 82A. Further, the first isotropic etch process etches proximal portions of the second etch-stop material layer 154, the first sacrificial material layers 142, and the second sacrificial material layers 242 from around each second contact via cavity 81B to form a respective finned cavity, which is herein referred to as a second first-stage in-process finned contact via cavity 82B. The first first-stage in-process finned contact via cavities 82A and the second first-stage in-process finned contact via cavities 82A comprise first-stage in-process finned contact via cavities 82.

Each first first-stage in-process finned contact via cavity 82A comprises a cylindrical cavity including the volume of a respective first contact via cavity 82A, a first annular cavity 155, and at least one lateral recess 41 formed by removal of an annular portion of a respective first sacrificial material layer 142. Each second first-stage in-process finned contact via cavity 82B comprises a cylindrical cavity including the volume of a respective second contact via cavity 82B, a second annular cavity 255, and lateral recesses 41 formed by removal of annular portions of first sacrificial material layers 142 and at least one second sacrificial material layer 242.

Physically exposed, recessed surfaces of the sacrificial material layers (142, 242), the first etch-stop material layer 154, and the second etch-stop material layer 254 after the first isotropic etch process comprises sidewall segments that are laterally offset by a uniform lateral offset distance from sidewalls of the insulating layers (132, 232) and the stepped dielectric material portions (165, 265) around the cylindrical cavity of a respective first-stage in-process finned contact via cavity 82. The uniform lateral offset distance can be the same as the etch distance of the first isotropic etch process.

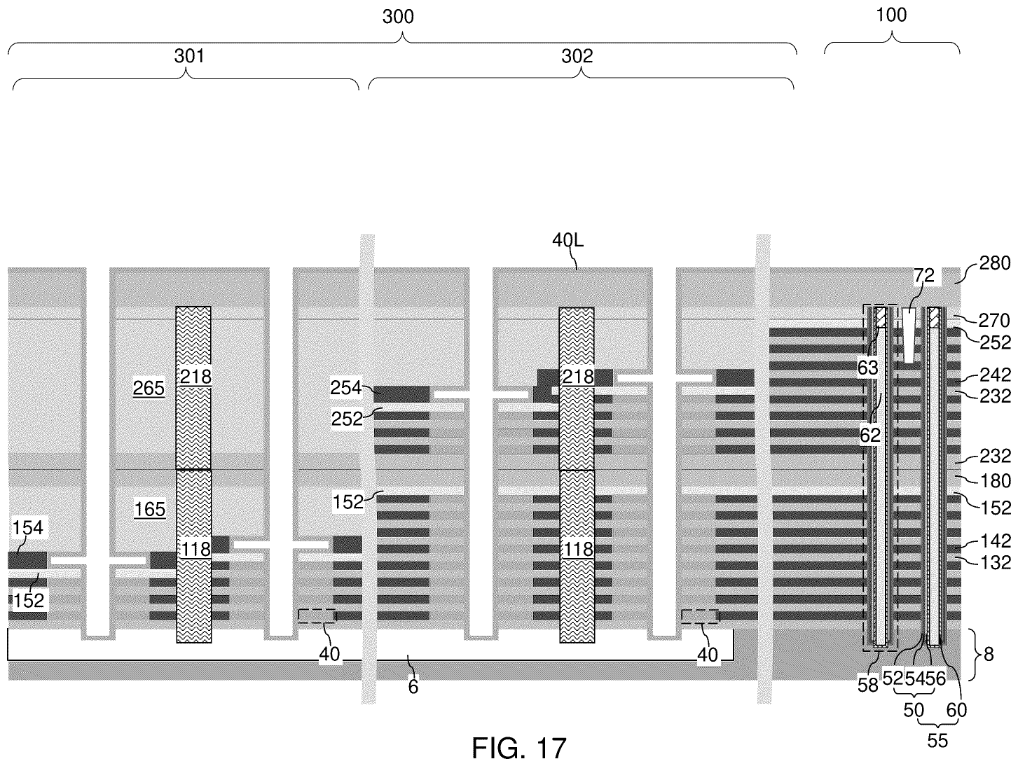

Referring to FIG. 17, a conformal dielectric material layer 40L can be deposited in the first-stage in-process finned contact via cavities 82 by a conformal deposition process such as a low-pressure chemical vapor deposition process or an atomic layer deposition process. The conformal dielectric material layer 40L can be conformally deposited to completely fill volumes of the lateral recesses 41 without completely filling the volumes of the first annular cavities 155 or the second annular cavities 255. The conformal dielectric material layer 40L comprises a material that is different from the materials of the sacrificial material layers (142, 242). For example, the conformal dielectric material layer 40L comprises silicon oxide.

As discussed above the first etch-stop material layer 154 and the second etch-stop material layer 254 have thicknesses that are greater than the thicknesses of the sacrificial material layers (142, 242). Thus, the first annular cavities 155 or the second annular cavities 255 have greater heights than the heights of the lateral recesses 41. The thickness of the conformal dielectric material layer 40L can be greater than one half of the height of the lateral recesses 41, and can be less than one half of the height of the first annular cavities 155 or the second annular cavities 255. Thus, the volumes of the first annular cavities 155 or the second annular cavities 255 can be partially filled with the conformal dielectric material layer 40L, while unfilled volumes are still present within each of the first annular cavities 155 or the second annular cavities 255.

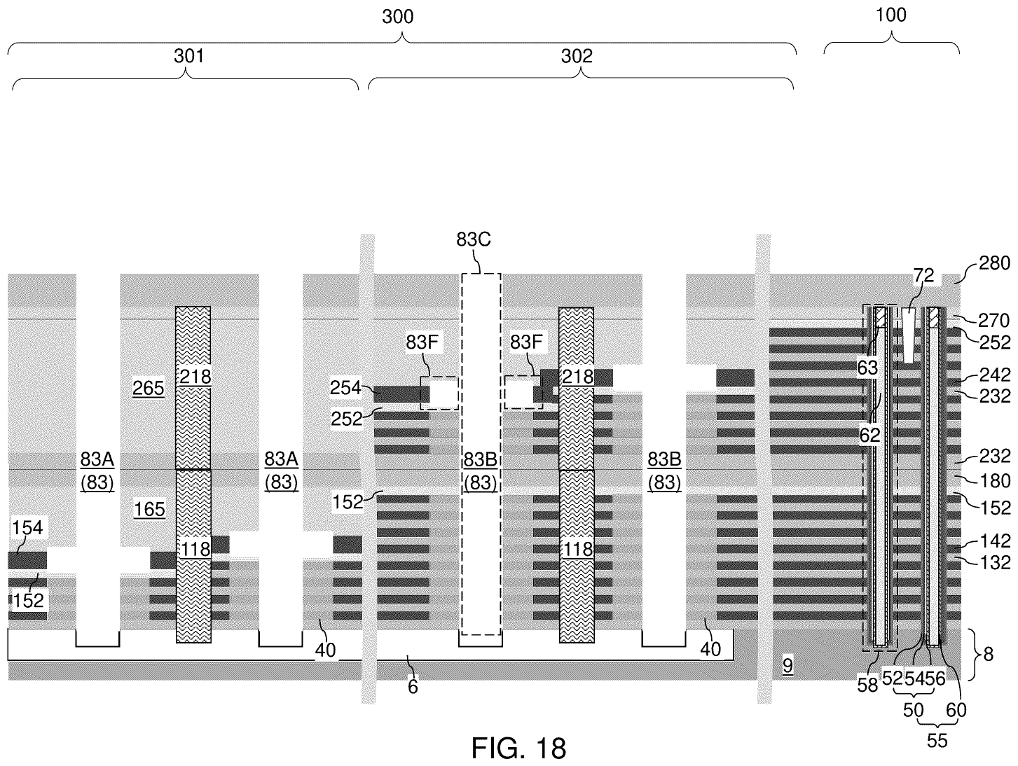

Referring to FIG. 18, an isotropic recess etch process can be performed to isotropically recess the conformal dielectric material layer 40L. For example, if the conformal dielectric material layer 40L comprises silicon oxide, a wet etch process employing dilute hydrofluoric acid can be performed to isotropically recess the conformal dielectric material layer 40L around cavities through the alternating stacks {(132, 142), (232, 242)}. The duration of the isotropic etch process can be selected such that the isotropic recess etch process completely removes the material of the conformal dielectric material layer 40L from inside each of the first annular cavities 155 and the second annular cavities 255. Remaining portions of the conformal dielectric material layer 40L that fill the lateral recesses 41 (i.e., the volumes from which portions of the sacrificial material layers (142, 242) are removed) constitute annular insulating plates 40, which are insulating fins.

The remaining volumes of the first-stage in-process finned contact via cavities 82 are herein referred to as second-stage in-process finned contact via cavities 83. The second stage in-process finned contact via cavities 83 may comprise first second-stage in-process finned contact via cavities 83A that extend through the first stepped dielectric material portion 165 and a portion of the first alternating stack (132, 142), and second second-stage in-process finned contact via cavities 83B that extend through the second stepped dielectric material portion 265 and a portion of the second alternating stack (232, 242). Each second-stage in-process finned contact via cavity 83 comprises a cylindrical cavity portion 83C having a cylindrical shape and vertically extending form the top surface of the first contact-level dielectric layer 280 to the dielectric isolation layer 6 (if present, or alternatively to the substrate 8), and an annular cavity portion 83F that is adjoined to and laterally surrounds the cylindrical cavity portion 83C. Each annular cavity portion 83F can be bounded by an annular bottom surface of a stepped dielectric material portion (165, 265), a cylindrical sidewall of a etch-stop material layer (154, 254), and an annular top surface segment of an insulating liner (152, 252).

At least one annular insulating plate 40 can be present around each second stage in-process finned contact via cavity 83. A plurality of first second-stage in-process finned contact via cavities 83A and each of the second second-stage in-process finned contact via cavities 83B can be laterally surrounded by a respective vertical stack of annular insulating plates 40. A first second-stage in-process finned contact via cavity 83A may comprise a first cylindrical surface vertically extending through the first stepped dielectric material portion 165 and the second stepped dielectric material portion 265 and having a bottom periphery that is adjoined to an inner periphery of the annular top surface of an annular cavity portion 83F, and a second cylindrical surface vertically extending through a subset of layers within the first alternating stack (132, 142) and having a top periphery that is adjoined to an annular bottom surface the annular cavity portion 83F. A second second-stage in-process finned contact via cavity 83B may comprise a first cylindrical surface vertically extending through the second stepped dielectric material portion 265 and having a bottom periphery that is adjoined to an inner periphery of the annular top surface of an annular cavity portion 83F, and a second cylindrical surface vertically extending through a subset of layers within the second alternating stack (232, 242) and each layer within the first alternating stack (132, 142) and having a top periphery that is adjoined to an annular bottom surface the annular cavity portion 83F. Generally, each second-stage in-process finned contact via cavity 83 comprises an entirety of a volume of a respective contact via cavity 81 and a volume formed by removal of a portion of a etch-stop material layer (154, 254) during the first isotropic etch process.

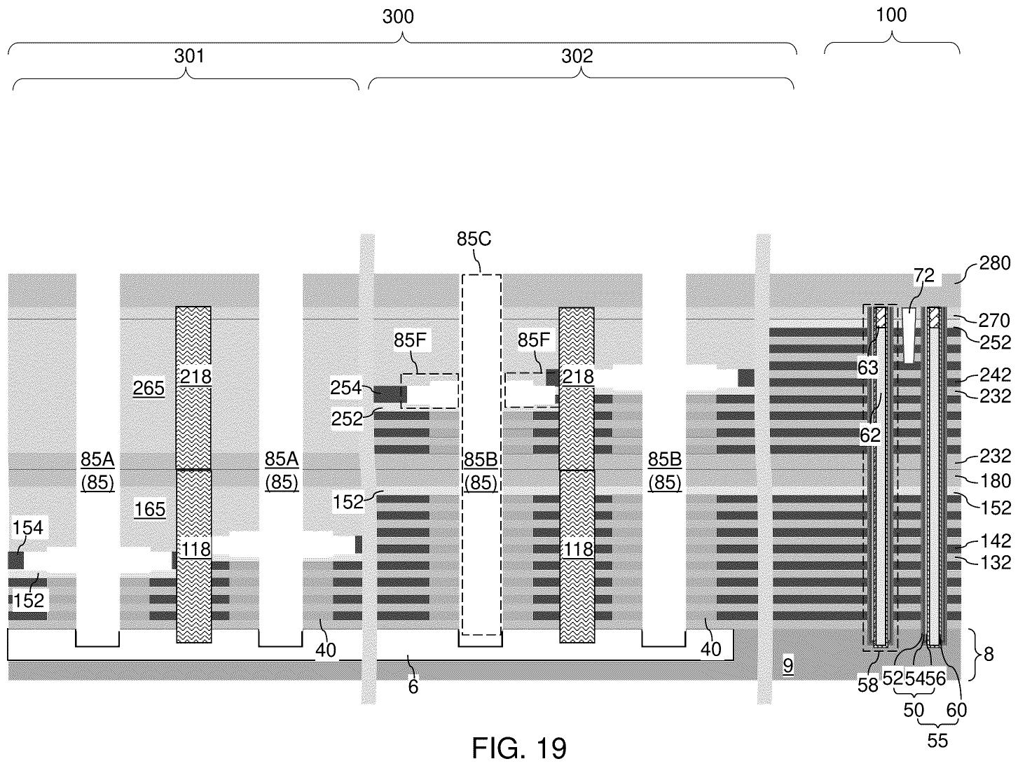

Referring to FIG. 19, a second isotropic etch process can be performed to isotropically recess the materials of the etch-stop material layers (154, 254) selective to the materials of the first contact-level dielectric layer 280, the dielectric spacer layers (272, 274), the insulating cap layer 270, the insulating layers (132, 232), the inter-tier dielectric layer 180, the dielectric isolation layer 6 (if present), and the annular insulating plates 40. For example, if the etch-stop material layers (154, 254) comprise silicon nitride, a wet etch process employing hot phosphoric acid can be performed to isotropically recess the etch-stop material layers (154, 254). The volume of each annular cavity portion 83F can be laterally expanded by the second isotropic etch process. The second-stage in-process finned contact via cavities 83, as expanded by the second isotropic etch process, are herein referred to as third-stage in-process finned contact via cavities 85.

Generally, the third-stage in-process finned contact via cavities 85 can be formed by laterally recessing sidewalls of the etch-stop material layers (154, 254) around the second-stage in-process finned contact via cavities 83 by performing the second isotropic etch process. The lateral recess distance of the second isotropic etch process may be in a range from 20 nm to 300 nm, such as from 40 nm to 150 nm, although lesser and greater lateral etch distances may also be employed. The third-stage in-process finned contact via cavities 85 comprise first third-stage in-process finned contact via cavities 85A that are formed in the first contact region 301, and second third-stage in-process finned contact via cavities 85B that are formed in the second contact region 302. Each of the third-stage in-process finned contact via cavities 85 comprises a cylindrical cavity portion 85C and an annular cavity portion 85F. In one embodiment, each annular cavity portion 85F may have a stepped top surface that includes a first annular top surface segment which is an annular bottom surface segment of a stepped dielectric material portion (165, 265), a cylindrical surface segment that is adjoined to an outer periphery of the first annular top surface segment, and a second annular top surface segment which is another annular bottom surface segment of the stepped dielectric material portion (165, 265).

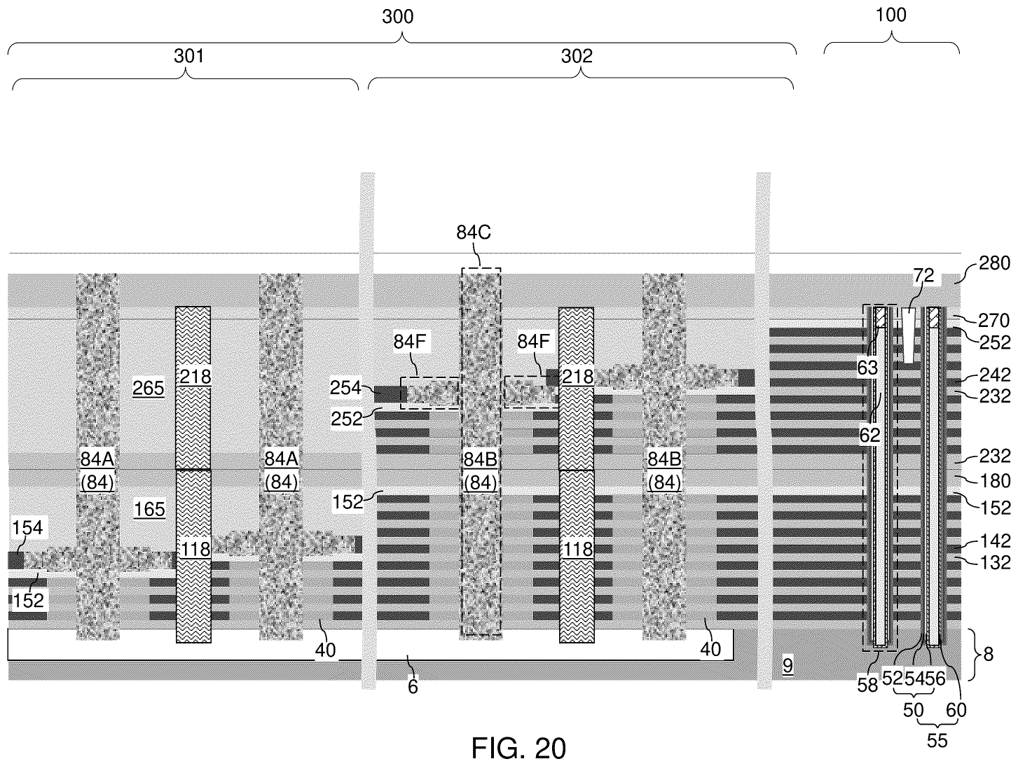

Referring to FIG. 20, a sacrificial fill material can be deposited in the third-stage in-process finned contact via cavities 85. The sacrificial fill material may comprise a semiconductor material (such as amorphous silicon or polysilicon), a carbon-based material (such as amorphous carbon or diamond-like carbon), a dielectric fill material (such as borosilicate glass or organosilicate glass), or a polymer material. Optionally, a thin etch stop liner (not illustrated) may be deposited prior to filling of the third-stage in-process finned contact via cavities 85 with the sacrificial fill material. The thin etch stop liner may comprise silicon oxide or a dielectric metal oxide, and may have a thickness in a range from 2 nm to 6 nm, although lesser and greater thicknesses may also be employed.

Portions of the sacrificial fill material overlying the horizontal plane including the top surface of the first contact-level dielectric layer 280 can be removed by a planarization process, which may comprise a recess etch process or a chemical mechanical polishing process. Each remaining portion of the sacrificial fill material that fills a respective one of the third-stage in-process finned contact via cavities 85 constitutes a sacrificial finned cavity fill material structure 84. Each sacrificial finned cavity fill material structure 84 comprises a respective cylindrical fill material portion 84C and at least one fin-shaped fill material portion 84F. Each fin-shaped fill material portion 84F has a respective annular shape.

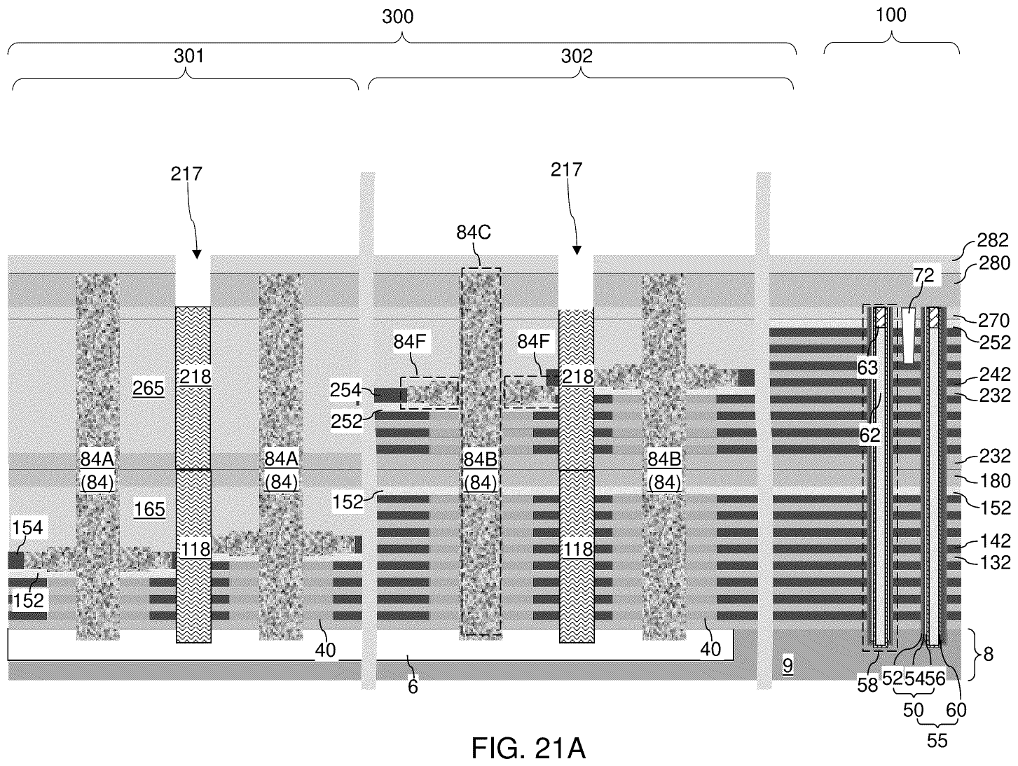

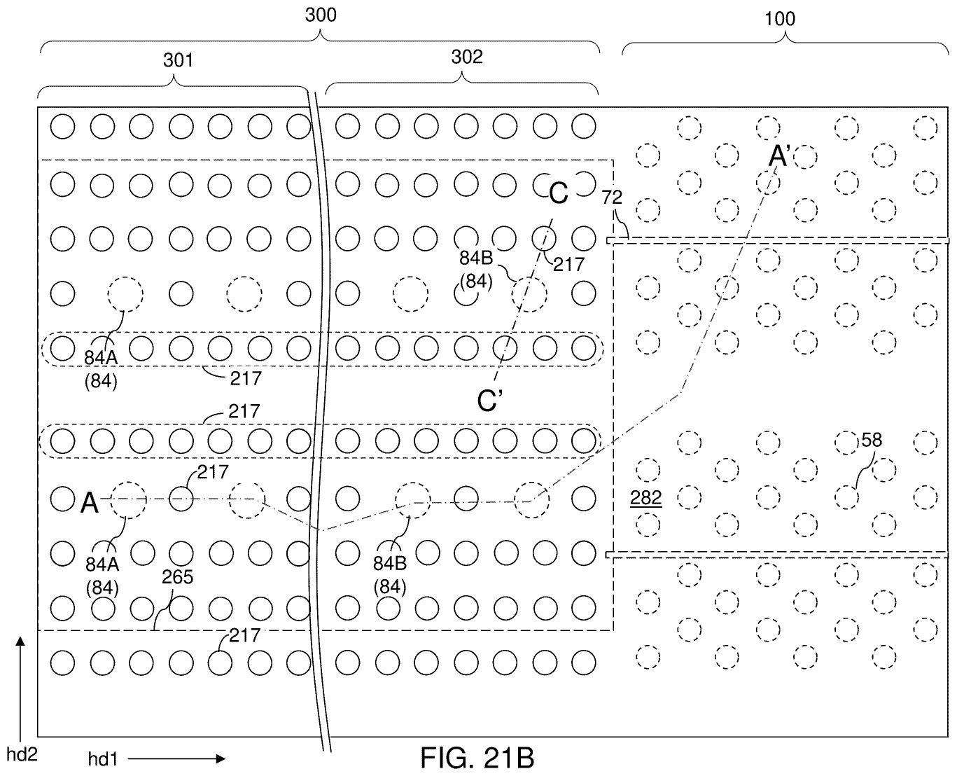

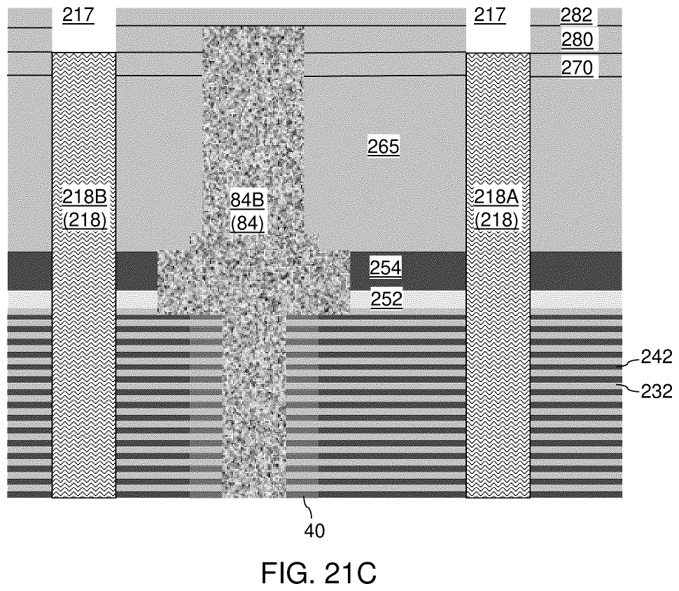

Referring to FIGS. 21A-21C, a second contact-level dielectric layer 282 can be formed over the first contact-level dielectric layer 280. The second contact-level dielectric layer 282 comprises a dielectric material, such as undoped silicate glass or a doped silicate glass, and may have a thickness in a range from 10 nm to 200 nm, such as from 20 nm to 100 nm, although lesser and greater thicknesses may also be employed.

A photoresist layer (not shown) can be applied over the second contact-level dielectric layer 282, and can be lithographically patterned to form openings over areas of the second-tier sacrificial support opening fill structures 218. An anisotropic etch process can be performed through the contact-level dielectric layers (280, 282) to form connection openings 217 over each of the second-tier sacrificial support opening fill structures 218. The photoresist layer can be subsequently removed, for example, by ashing.

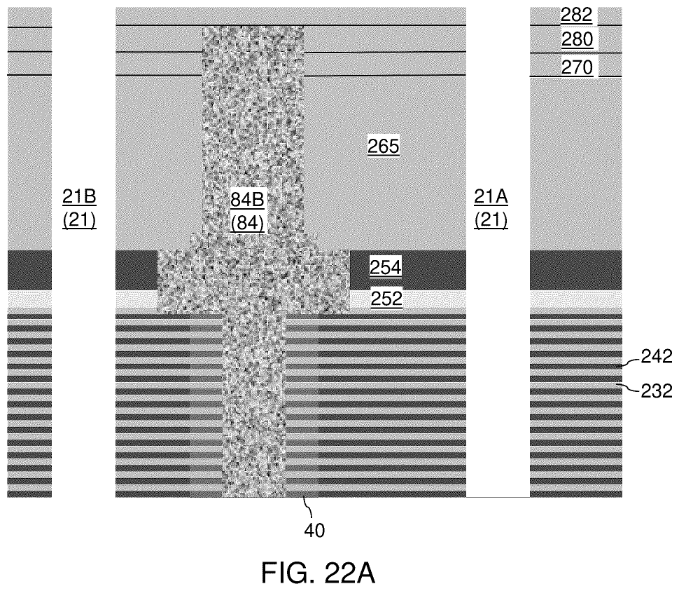

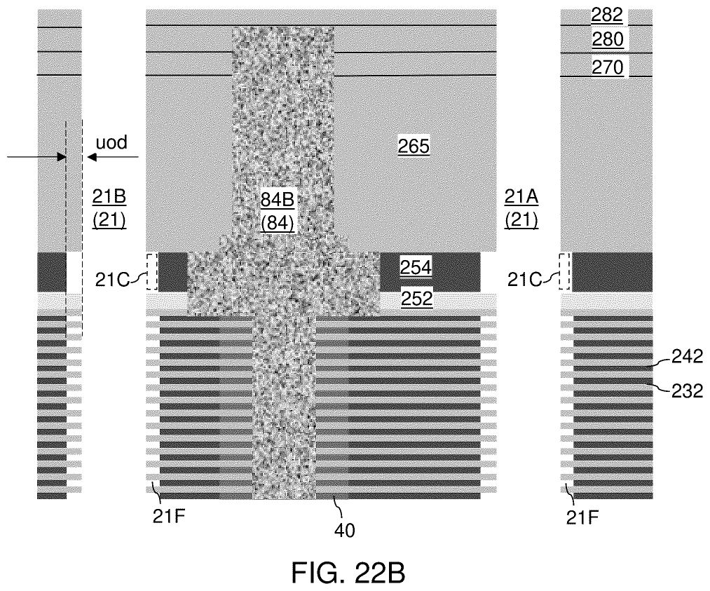

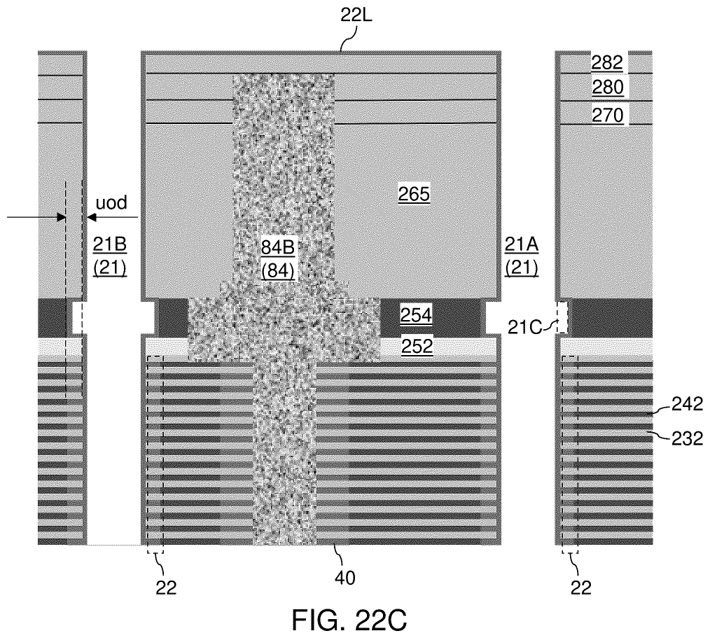

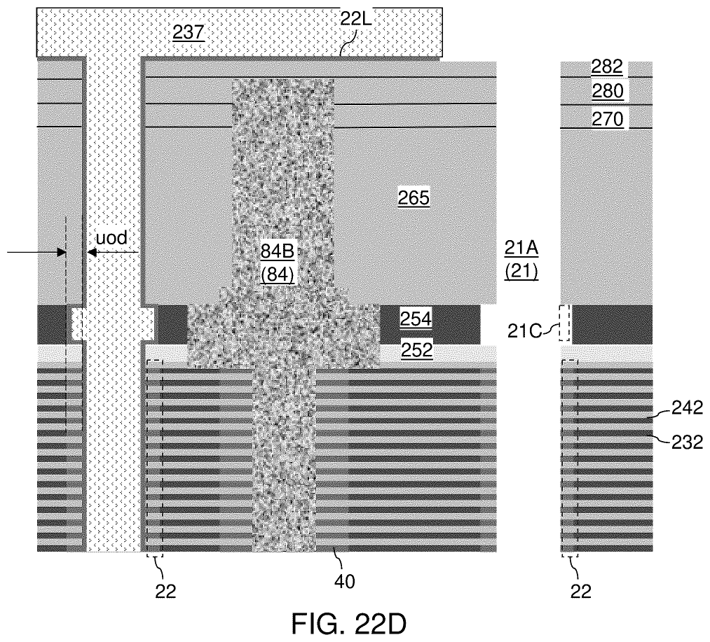

FIGS. 22A-22D are sequential vertical cross-sectional views of a region of the first exemplary structure during formation of annular insulating fins 22 around support openings 21 according to an embodiment of the present disclosure.

Referring to FIG. 22A, the second-tier sacrificial support opening fill structures 218 and the first-tier sacrificial support opening fill structures 118 can be subsequently removed selective to the materials of the contact-level dielectric layers (280, 282), the insulating cap layer 270, the alternating stacks {(132, 142), (232, 242)}, the inter-tier dielectric layer 180, the etch-stop material layers (154, 254), and the insulating liners (152, 252). Multi-tier support openings 21, which are also referred to as support openings 21, are formed in the volumes from which the second-tier sacrificial support opening fill structures 218 and the first-tier sacrificial support opening fill structures 118 are removed.

The support openings 21 comprise first-type support openings 21A that are formed in the volumes from which the first-type second-tier sacrificial support opening fill structures 218A and first-type first-tier sacrificial support opening fill structures (which are formed in the first-type first-tier support openings 119A) are removed. The support openings 21 also comprise second-type support openings 21B that are formed in the volumes from which the second-type second-tier sacrificial support opening fill structures 218B and second-type first-tier sacrificial support opening fill structures (which are formed in the second-type first-tier support openings 119B) are removed.

Referring to FIG. 22B, an isotropic etch process can be performed to isotropically recess the material of the sacrificial material layers (142, 242), the first etch-stop material layer 154, and the second etch-stop material layer 254 selective to the materials of the first contact-level dielectric layer 280, the insulating cap layer 270, the insulating layers (132, 232), the inter-tier dielectric layer 180, the insulating liners (152, 252), and the dielectric isolation layer 6 (if present). For example, if the sacrificial material layers (142, 242), the first etch-stop material layer 154, and the second etch-stop material layer 254 comprise silicon nitride, a wet etch process employing hot phosphoric acid can be performed to laterally recess the sacrificial material layers (142, 242).

Sidewalls of the sacrificial material layers (142, 242), the first etch-stop material layer 154, and the second etch-stop material layer 254 may be laterally recessed relative to sidewalls of the insulating layers (132, 232) and the stepped dielectric material portions (165, 265) around the support openings by a uniform offset distance “uod”, which is the lateral recess distance of the isotropic etch process. The uniform offset distance uod may have a width of 50 nm to 250 nm, such as 100 nm to 150 nm, although lesser and greater dimensions may also be employed. Fin cavities 21F are formed in volumes from which the materials of the sacrificial material layers (142, 242) are removed around the support openings 21. A cylindrical annular cavity 21C can be formed in each volume from which a respective cylindrical annular portion of the first etch-stop material layer 154 or the second etch-stop material layer 254 is removed around a respective one of the support cavities 21.

Referring to FIG. 22C, a conformal insulating layer 22L can be deposited in peripheral regions of the support openings 21 by a conformal deposition process, such as a low-pressure chemical vapor deposition process or an atomic layer deposition process. The conformal insulating layer 22L can be conformally deposited to completely fill volumes of the fin cavities 21F without completely filling the volumes of the cylindrical annular cavities 21C. The conformal insulating layer 22L comprises a material that is different from the materials of the sacrificial material layers (142, 242). For example, the conformal insulating layer 22L comprises silicon oxide.

As discussed above, the first etch-stop material layer 154 and the second etch-stop material layer 254 have thicknesses that are greater than the thicknesses of the sacrificial material layers (142, 242). Thus, the cylindrical annular cavities 21C have greater heights than the heights of the fin cavities 21F. The thickness of the conformal insulating layer 22L can be greater than one half of the height of the fin cavities 21F, and can be less than one half of the height of the cylindrical annular cavities 21C.

Referring to FIG. 22D, a photoresist layer 237 can be applied over the first exemplary structure, and can be lithographically patterned to cover each of the second-type support openings 21B without covering the first-type support openings 21A. An isotropic recess etch process can be performed to isotropically recess unmasked portions of the conformal insulating layer 22L. For example, if the conformal insulating layer 22L comprises silicon oxide, a wet etch process employing dilute hydrofluoric acid can be performed to isotropically recess the conformal insulating layer 22L within the first-type support openings 21A. The duration of the isotropic etch process can be selected such that the isotropic recess etch process completely removes the material of the conformal insulating layer 22L from inside each of the cylindrical annular cavities 21C of the first-type support openings 21A. Remaining portions of the conformal insulating layer 22L that fill the fin cavities 21F (i.e., the volumes from which portions of the sacrificial material layers (142, 242) are removed) constitute insulating fins 22. The photoresist layer 237 can be subsequently removed, for example, by ashing.

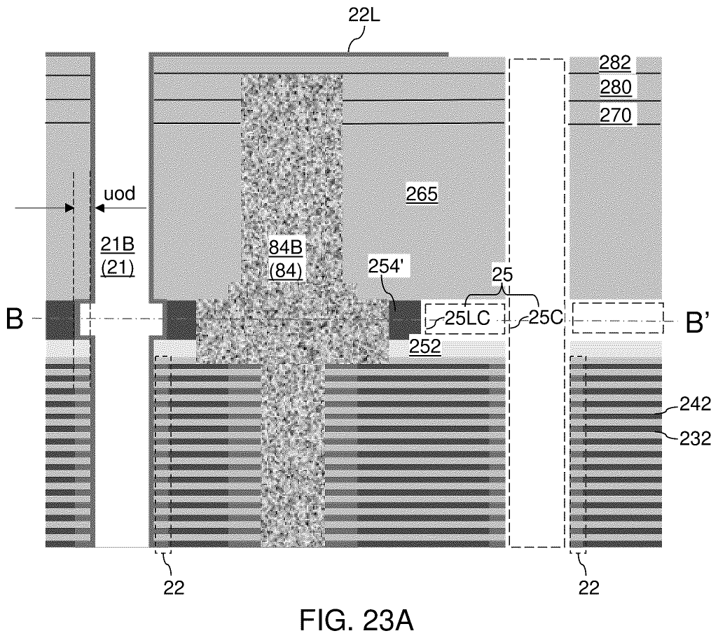

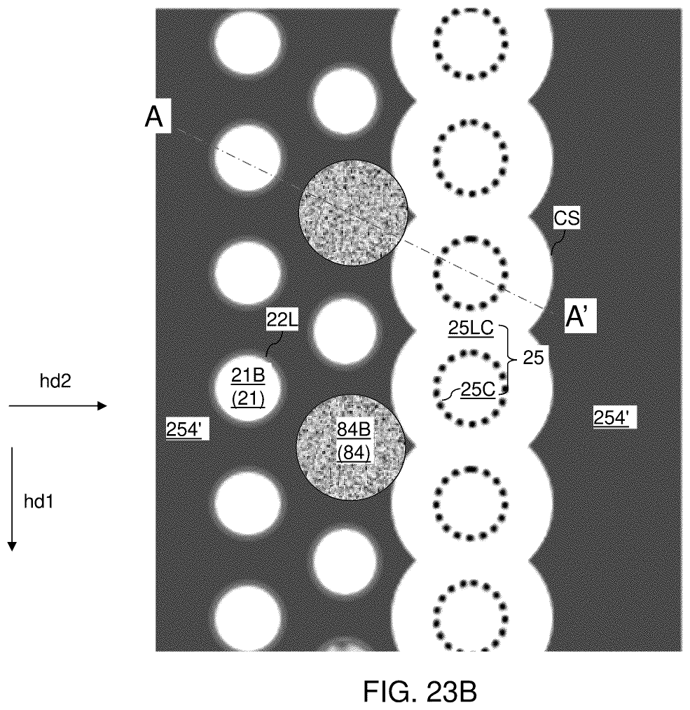

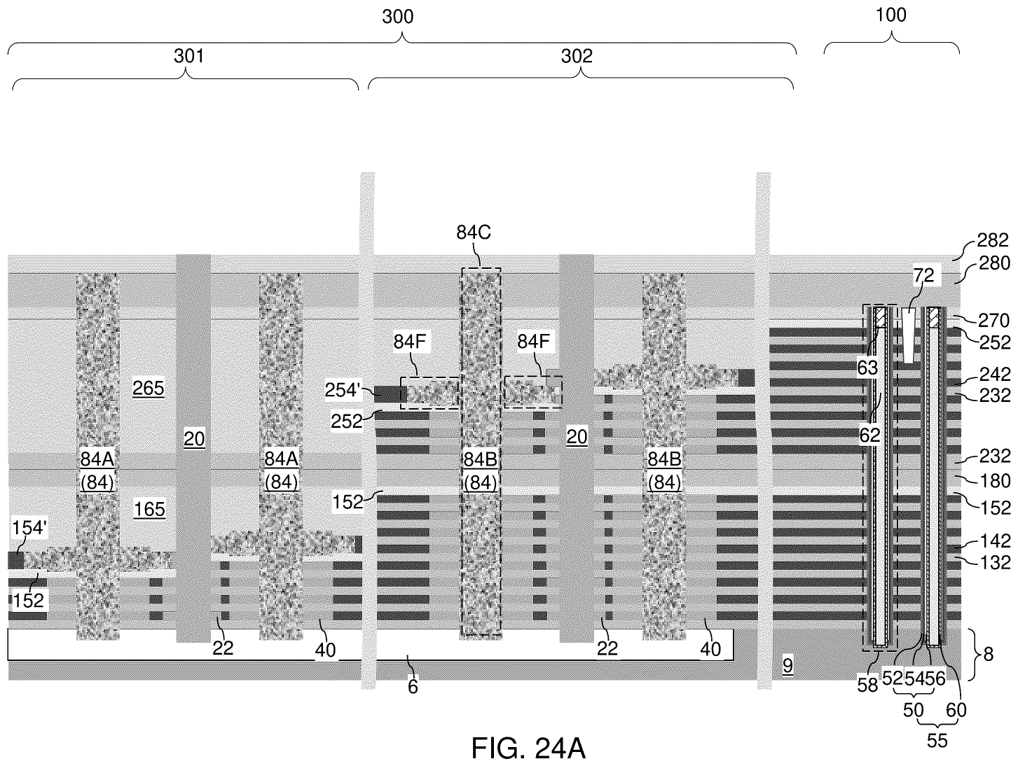

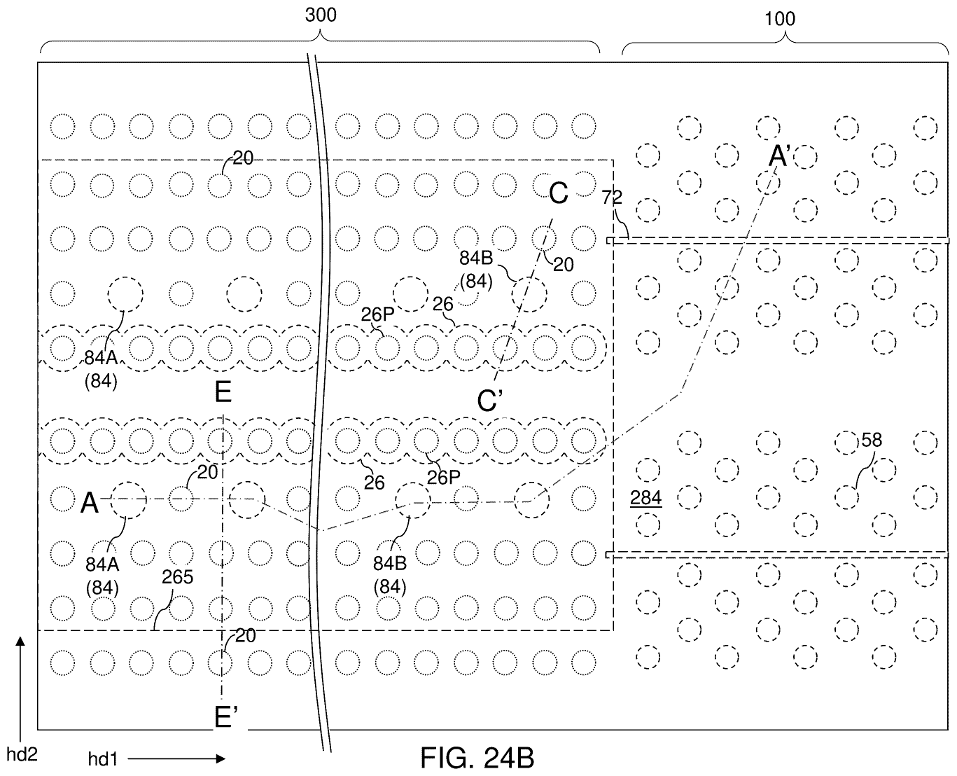

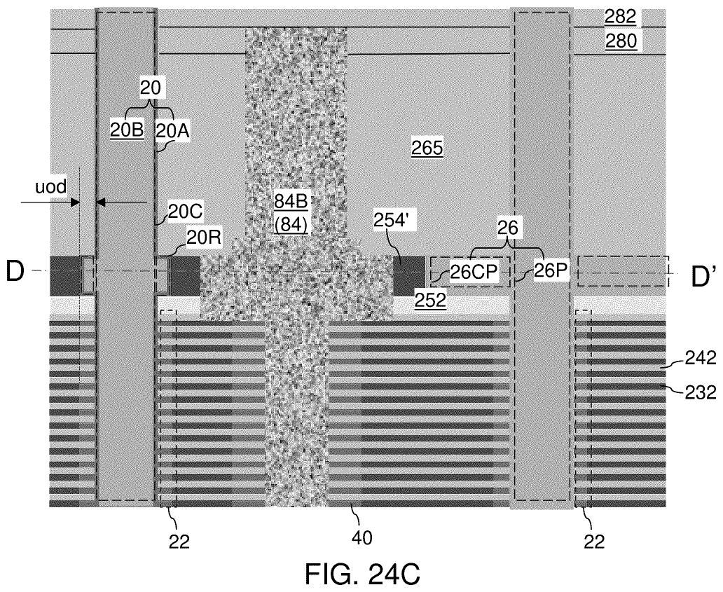

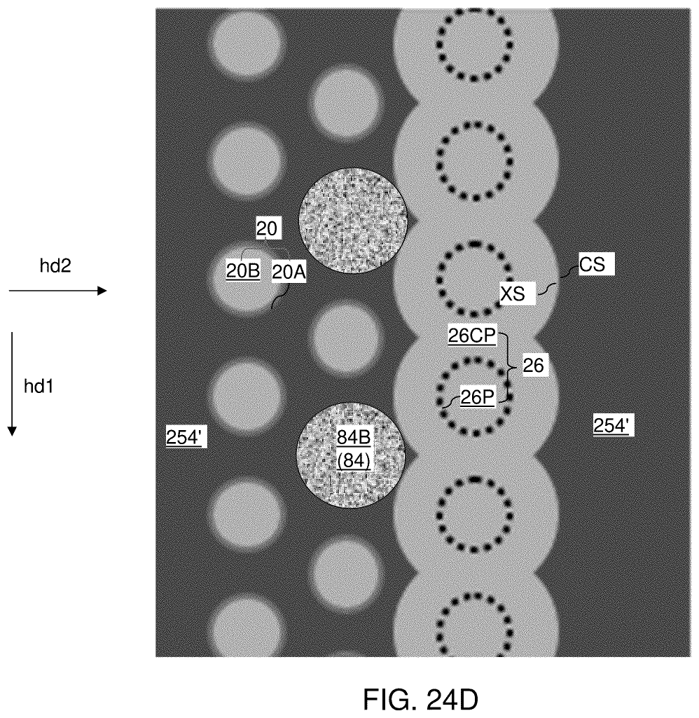

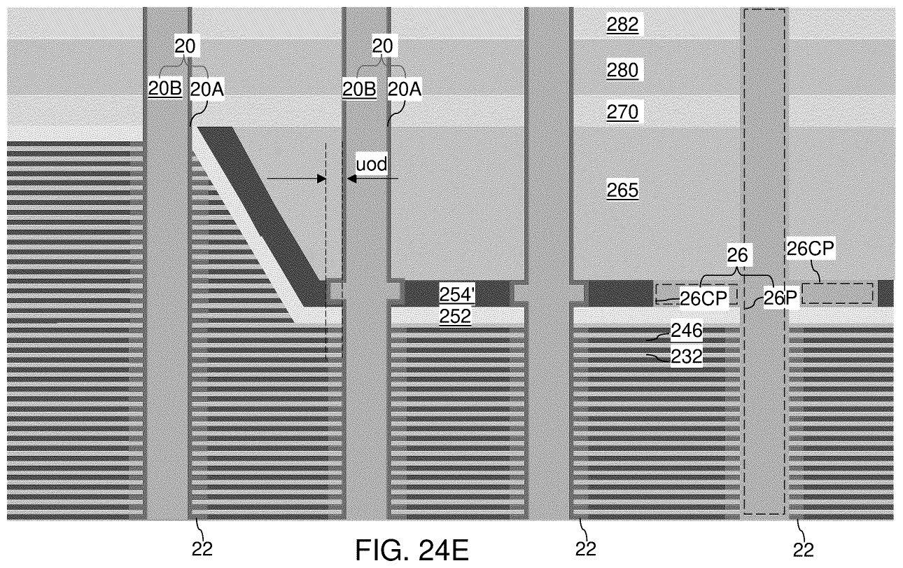

Referring to FIGS. 23A and 23B, a selective isotropic etch process can be performed to laterally recess the etch-stop material layers (154, 254) around the first-type support openings 21A selective to the contact-level dielectric layers (280, 282), the insulating cap layer 270, the stepped dielectric material portions (165, 265), the insulating liners (152, 252), the insulating fins 22, and the sacrificial finned cavity fill material structure 84. The insulating fins 22 prevent the lateral recessing of the sacrificial material layers (142, 242). For example, if the etch-stop material layers (154, 254) comprise silicon nitride, the selective isotropic etch process may comprise a wet etch process employing hot phosphoric acid. The duration of the selective isotropic etch process can be selected such that laterally-expanded cavities around each row of first-type support openings 21A merge to form a continuous cavity 25 including a laterally-extending cavity 25LC that is interconnected to a row of cylindrical cavities 25C. As shown in FIG. 23B, the continuous cavity 25 comprises a continuous laterally-extending cavity 25LC that surrounds a plurality of the cylindrical cavities 25C. The volumes of the cylindrical cavities 25C include volumes of a row of first-type support openings 21A. The volume of the laterally-extending cavity 25LC includes a volume of a removed portion of an etch-stop material layer (154, 254). Each remaining portion of an etch-stop material layer (154, 254) constitutes a dielectric material plate (154′, 254′). Specifically, a remaining portion of the first etch-stop material layer 154 comprises a first dielectric material plate 154′ (as shown in FIG. 24A), and a remaining portion of the second etch-stop material layer 254 comprises a second dielectric material plate 254′.

Generally, the etch-stop material layers (154, 254) can be isotropically etched around a subset of the support openings 21, such as the first-type support openings 21A, by performing an isotropic etch process. A continuous cavity 25 can be formed, which comprises volumes (i.e., 25C) of the subset of the support openings 21A and further comprises a laterally-extending cavity 25LC that laterally surrounds the volumes of the subset of the support openings 21A. In one embodiment, each etch-stop material layer (154, 254) comprises a dielectric material, such as silicon nitride. Each remaining portion of an etch-stop material layer (154, 254) comprises a dielectric material plate (154′, 254′) overlying stepped surfaces of an alternating stack {(132, 142) or (232, 242)} and comprising vertically-straight and horizontally-concave surface segments CS that are exposed to a continuous cavity 25, as shown in FIG. 23B. As used herein, a vertically-straight surface segment refers to a surface segment having a straight profile in a vertical cross-sectional view. As used herein, a horizontally-concave surface segment refers to a surface segment having a concave profile in a horizontal cross-sectional view. As used herein, a horizontally-convex surface segment refers to a surface segment having a convex profile in a horizontal cross-sectional view.

Referring to FIGS. 24A-24E, a dielectric fill material, such as an undoped silicate glass (i.e., silicon oxide) or a doped silicate glass, can be conformally deposited in the continuous cavities 25 and in the unfilled volumes of the second-type support openings 21B. A planarization process, such as a recess etch process and/or a chemical mechanical polishing process, can be performed to remove portions of the deposited dielectric fill material from above the horizontal plane including the top surface of the second contact-level dielectric layer 282.

Each remaining portion of the dielectric fill material that fills a continuous cavity 25 constitutes a dielectric support assembly 26. Each dielectric support assembly 26 comprises a plurality of dielectric pillar structures 26P located in the volumes of a subset of the support openings 21 (such as a row of first-tier support openings 21A) and further comprises a dielectric connection plate 26CP which fills a laterally-extending cavity 25LC and laterally surrounds and is adjoined to each of the plurality of dielectric pillar structures 26P. In other words, the dielectric connection plate 26CP comprises a continuous dielectric plate which surrounds a plurality of dielectric pillar structures 26P which protrude above and below the horizontal surfaces of the dielectric connection plate 26CP. In one embodiment, the dielectric connection plate 26CP extends over multiple stepped surfaces of the alternating stacks {(132, 142), (232, 242)}. In one embodiment shown in FIG. 24D, the dielectric connection plate 26CP comprises vertically-straight and horizontally-convex surface segments XS that are adjoined to each other at vertically-extending edges. A dielectric material plate (154′, 254′) overlies the stepped surfaces of the alternating stack {(132, 142), (232, 242)}, and comprises vertically-straight and horizontally-concave surface segments CS contacting the vertically-straight and horizontally-convex surface segments CX of the dielectric connection plate 26CP.

In one embodiment, the dielectric connection plate 26CP comprises horizontally-extending dielectric connection plate portions that overlie horizontally-extending surface segments of stepped surfaces of an alternating stack {(132, 142) or (232, 242)} and vertically-extending dielectric connection plate portions that overlie vertically-extending surface segments of the stepped surfaces of the alternating stack {(132, 142) or (232, 242)}. In one embodiment, a vertical thickness of the horizontally-extending dielectric connection plate portions is the same as a lateral thickness of the vertically-extending dielectric connection plate portions.

In one embodiment, dielectric pillar structures 20 can be formed in the second-type support openings 21B. In one embodiment shown in FIG. 24C, a subset of the dielectric pillar structures 20 that vertically extends through a respective dielectric material plate (154′, 254′) may comprise a cylindrical portion 20C having a cylindrical shape and may further comprise a rim portion 20R that protrudes outward from the cylindrical portion 20C and contacting the dielectric material plate (154′, 254′). In one embodiment, a cylindrical surface of the dielectric material plate (154′, 254′) is laterally offset from a cylindrical surface of the cylindrical portion 20C by a uniform offset distance uod, which is the same as the width of the rim portion 20R. In one embodiment, each dielectric pillar structure 20 may comprise an insulating liner 22A (which is a remaining portion of the conformal insulating liner 22L) and an insulating fill material portion 20B which is a portion of the deposited dielectric fill material.

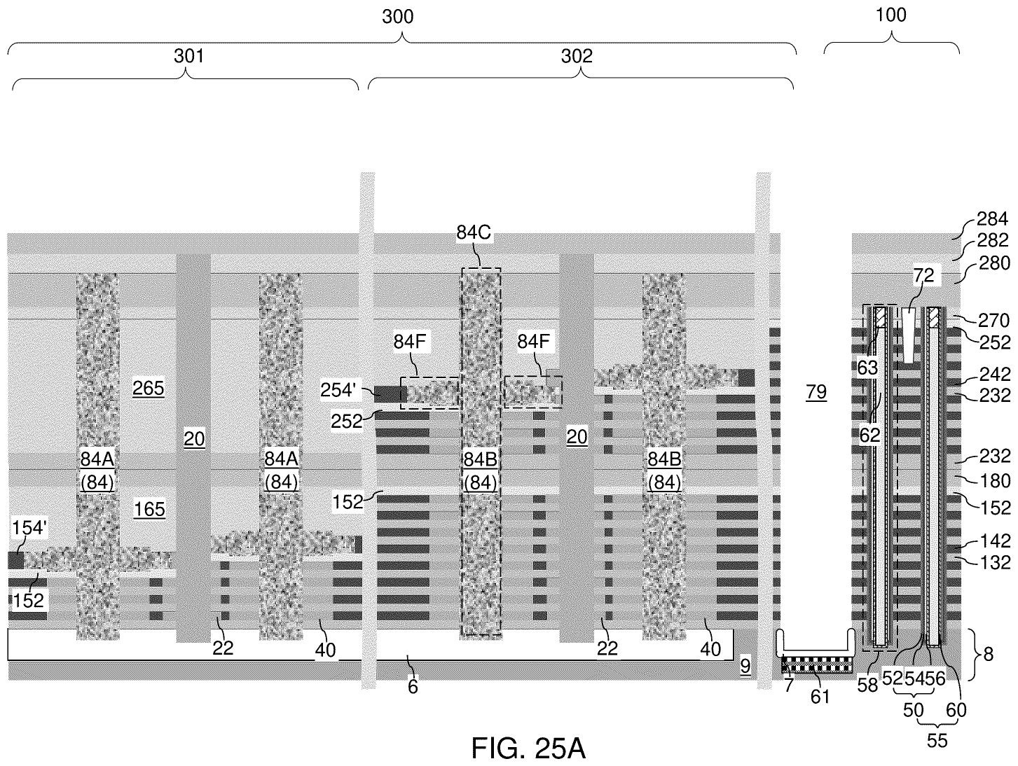

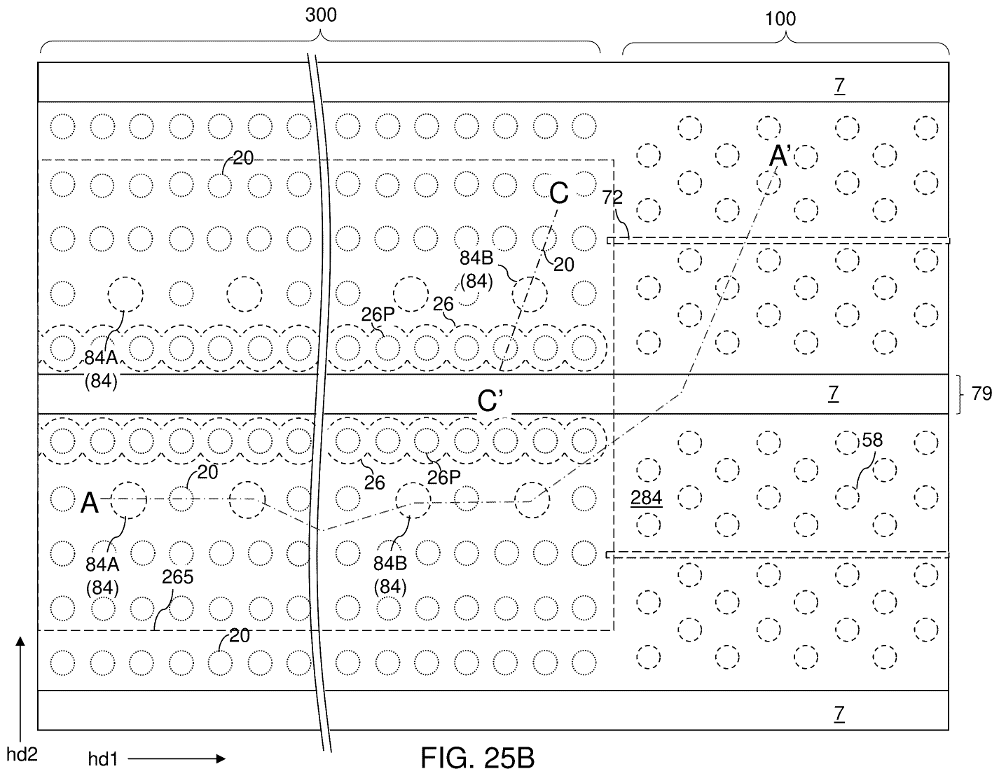

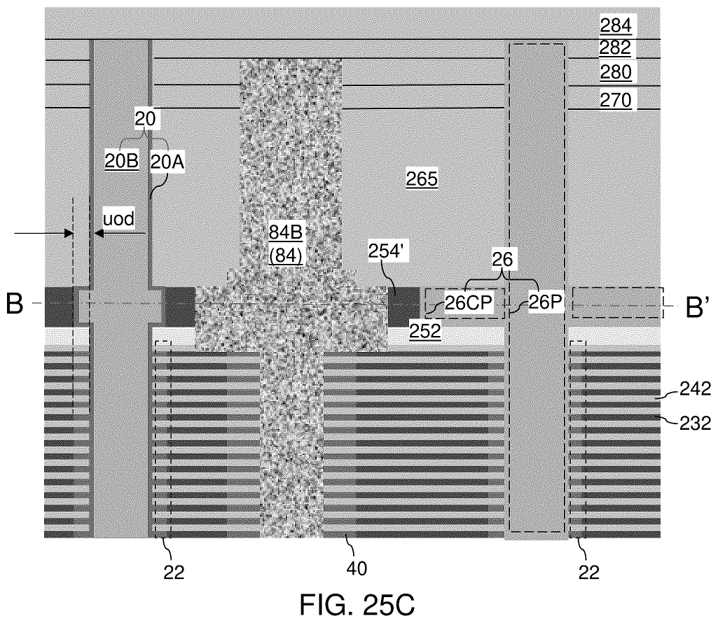

Referring to FIGS. 25A-25C, a third contact-level dielectric layer 284 can be formed over the second contact-level dielectric layer 282. The third contact-level dielectric layer 284 comprises a dielectric material such as undoped silicate glass or a doped silicate glass. The thickness of the third contact-level dielectric layer 284 may be in a range from 100 nm to 400 nm, although lesser and greater thicknesses may also be employed.

A photoresist layer (not shown) can be applied over the third contact-level dielectric layer 284, and can be lithographically patterned to form openings within areas extending across the memory array region 100 and the contact region 300. The openings in the photoresist layer can laterally extend along the first horizontal direction hd1 between each neighboring cluster of memory opening fill structures 58. Lateral isolation trenches 79 can be formed by transferring the pattern in the photoresist layer through the contact-level dielectric layers (284, 282, 280), the second alternating stack (232, 242), and the first alternating stack (132, 142), the stepped dielectric material portions (165, 265), and into the substrate 8. Portions of the contact-level dielectric layers (284, 282, 280), the second alternating stack (232, 242), and the first alternating stack (132, 142), the stepped dielectric material portions (165, 265) that underlie the openings in the photoresist layer can be removed to form the lateral isolation trenches 79. In one embodiment, the lateral isolation trenches 79 can be formed between clusters (e.g., blocks) of memory opening fill structures 58. The clusters of the memory opening fill structures 58 can be laterally spaced apart along the second horizontal direction hd2 by the lateral isolation trenches 79. In one embodiment, the lateral isolation trenches 79 form sidewalls of memory blocks. Each dielectric material plate (154′, 254′) can be cut by a respective lateral isolation trench 79.

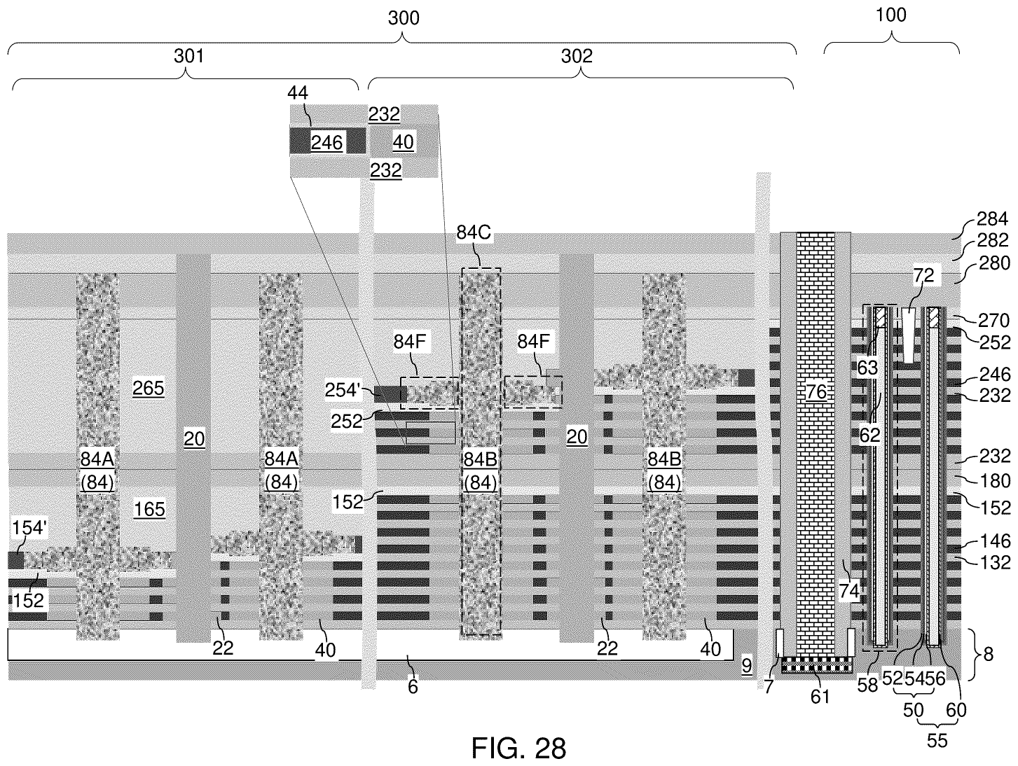

An optional ion implantation process can be performed to implant dopants of a second conductivity type (which is the opposite of the first conductivity type) into the portion of the semiconductor material layer 9 that underlies the lateral isolation trenches 79. An optional source region 61 can be formed underneath each lateral isolation trench 79. The source regions 61 may comprise dopants of the second conductivity type at an atomic concentration in a range from 5.0×10¹⁸/cm³ to 2.0×10²¹/cm³. An activation anneal may be performed to activate all electrical dopants in the vertical semiconductor channels 60, the drain regions 63, and the source regions 61. Alternatively, formation of the source regions 61 may be omitted at this time and instead a top source contact is formed over the bottom tips of the vertical semiconductor channels after removal of the substrate 8. In another alternative embodiment, the source regions 61 may be formed at the step shown in FIG. 28 and described below.

An optional semiconductor oxide barrier liner 7 may be formed at the bottom of each lateral isolation trench 79 by converting physically exposed surface portions of the semiconductor material layer (e.g., silicon layer) 9 into a dielectric semiconductor oxide material, such as silicon oxide. The thickness of the semiconductor oxide barrier liner 7 may be in a range from 6 nm to 20 nm, although lesser and greater thicknesses may also be employed.

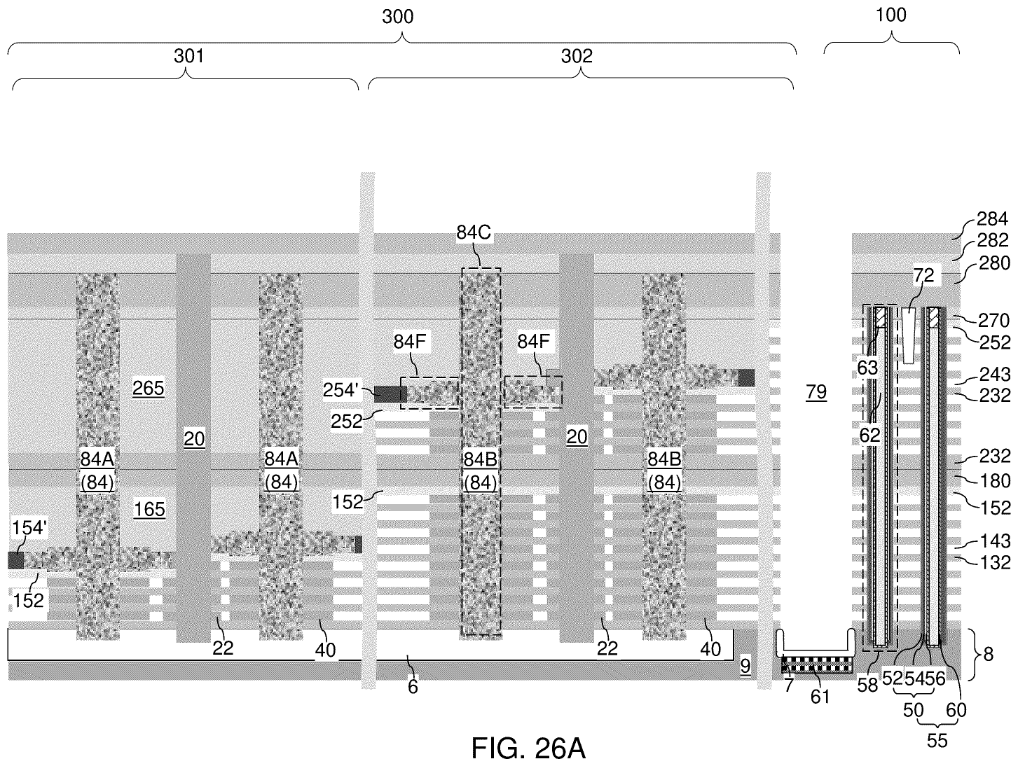

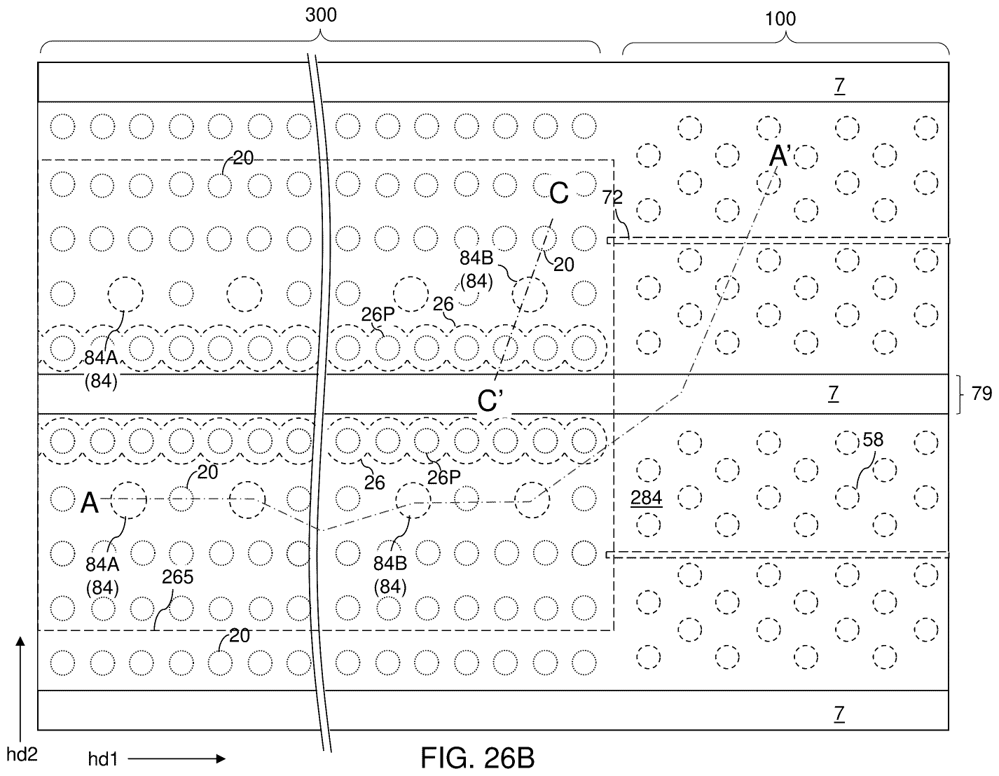

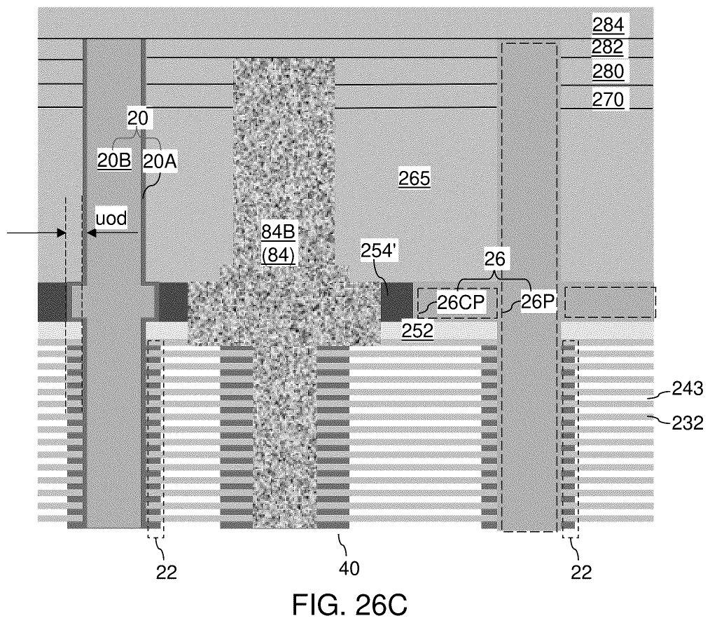

Referring to FIGS. 26A-26C, an etchant that selectively etches the materials of the first and second sacrificial material layers (142, 242) with respect to the materials of the first and second insulating layers (132, 232), the material of the outermost layer of the memory films 50 of the memory opening fill structures 58, the dielectric support assemblies 26, and the dielectric pillar structures 20 can be introduced into the lateral isolation trenches 79, for example, employing an isotropic etch process. First laterally-extending cavities 143 are formed in volumes from which the first sacrificial material layers 142 are removed. Second laterally-extending cavities 143 are formed in volumes from which the second sacrificial material layers 242 are removed. According to an aspect of the present disclosure, the dielectric support assemblies 26 cover edge portions of the dielectric material plates (154′, 254′) so that such edge portions are not exposed to the lateral isolation trenches 79. Thus, the dielectric support assemblies 26 function as etch barriers for the edge portions of the dielectric material plates (154′, 254′) because the edge portions are not exposed to the lateral isolation trenches 79. The etch barriers prevent further recessing of the dielectric material plates (154′, 254′) during the isotropic etch process and prevents the dielectric material plates (154′, 254′) from being replaced with electrically conductive material during subsequent replacement of the sacrificial material layers (142, 242) with electrically conductive layers. This reduces the likelihood of unintended short circuits that may result with the unintended replacement of the dielectric material plates (154′, 254′) with electrically conductive material. Furthermore, the dielectric connection plates 26CP can be located closer to the lateral isolation trenches 79 than the dielectric pillar structures 20. This improves the support provided by the dielectric connection plates 26CP to the insulating layers (132, 232) after removal of the sacrificial material layers (142, 242), and reduces the chance of pattern collapse and alternating stack tilting into the lateral isolation trenches 79.

The isotropic etch process can be a wet etch process employing a wet etch solution, or can be a gas phase (dry) etch process in which the etchant is introduced in a vapor phase into the lateral isolation trenches 79. For example, if the first and second sacrificial material layers (142, 242) include silicon nitride, the etch process can be a wet etch process in which the first exemplary structure is immersed within a wet etch tank including phosphoric acid, which etches silicon nitride selective to silicon oxide and silicon.

The annular insulating plates 40 and the sacrificial finned cavity fill material structures 84 vertically extend from the dielectric isolation layer 6 (if present, or from the substrate 8) to the first contact-level dielectric layer 280, and provide structural support for the portions of the insulating layers (132, 232) that are present in the contact region 300 and for the stepped dielectric material portions (165, 265), after removal of the sacrificial material layers. The annular insulating plates 40 can enhance structural support for the insulating layers (132, 232) and the stepped dielectric material portions (165, 265). The memory opening fill structures 58 provide structural support to the insulating layers (132, 232) in the memory array region 100.

Each of the first and second laterally-extending cavities (143, 243) can be a laterally extending cavity having a lateral dimension that is greater than the vertical extent of the cavity. In other words, the lateral dimension of each of the first and second laterally-extending cavities (143, 243) can be greater than the height of the respective laterally-extending cavity. A plurality of first laterally-extending cavities can be formed in the volumes from which the material of the first sacrificial material layers 142 is removed. A plurality of second laterally-extending cavities can be formed in the volumes from which the material of the second sacrificial material layers 242 is removed. Each of the first and second laterally-extending cavities can extend substantially parallel to the top surface of the substrate 8. A laterally-extending cavity (143, 243) can be vertically bounded by a top surface of an underlying insulating layer (132 or 232) and a bottom surface of an overlying insulating layer (132 or 232). In one embodiment, each of the first and second laterally-extending cavities (143, 243) can have a uniform height throughout.

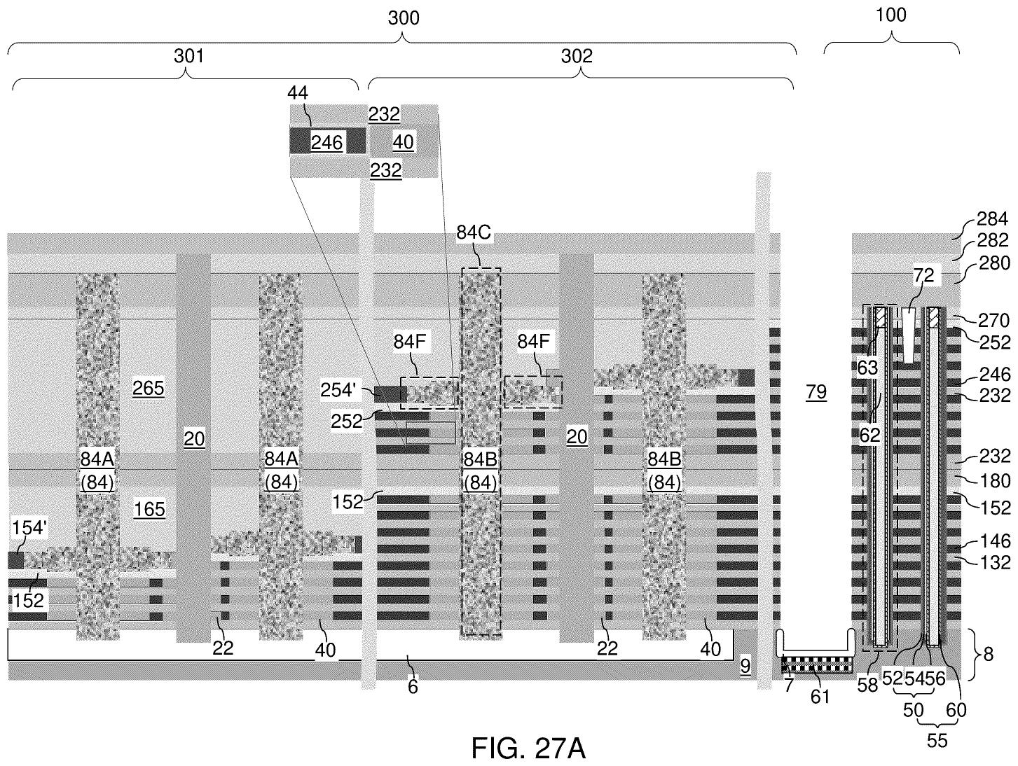

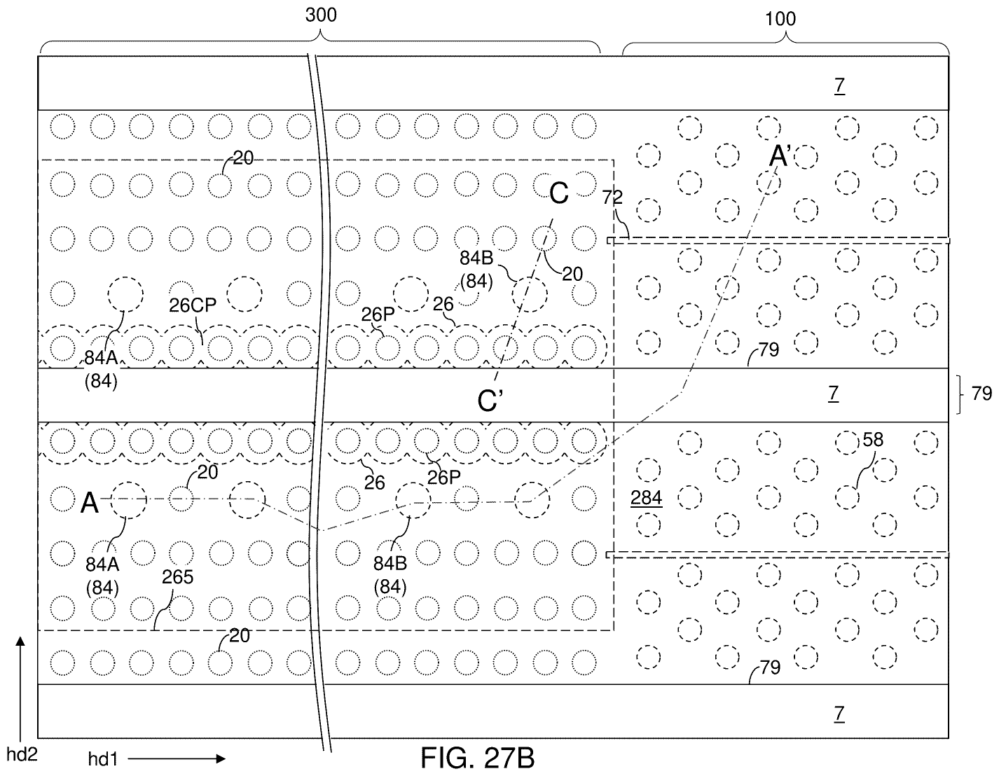

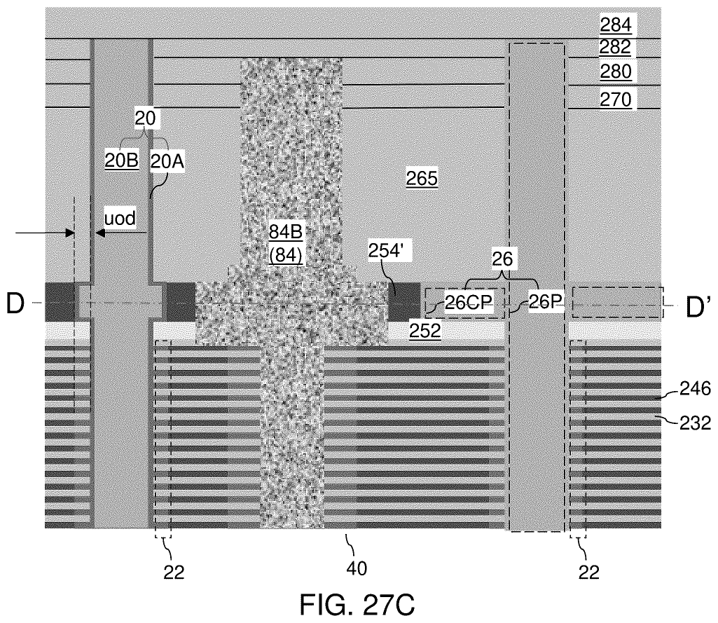

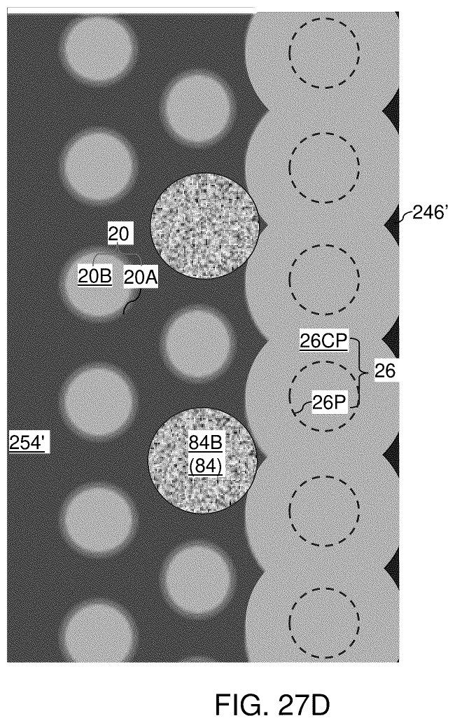

Referring to FIGS. 27A-27D, a backside blocking dielectric layer (not shown) can be optionally formed within each laterally-extending cavity (143, 243). At least one conductive material can be conformally deposited in the plurality of laterally-extending cavities (143, 243), on the sidewalls of the lateral isolation trench 79, and over the first contact-level dielectric layer 280. The at least one conductive material can include at least one metallic material, i.e., an electrically conductive material that includes at least one metal element.

The at least one metallic material can be deposited by a conformal deposition method, which can be, for example, chemical vapor deposition (CVD), atomic layer deposition (ALD), electroless plating, electroplating, and/or a combination thereof. The at least one metallic material can be an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof. Non-limiting exemplary metallic materials that can be deposited in the laterally-extending cavities include tungsten, tungsten nitride, titanium, titanium nitride, tantalum, tantalum nitride, cobalt, and/or ruthenium. In one embodiment, the at least one metallic material may comprise a combination of a metallic barrier liner material and a metallic fill material. The metallic barrier liner material may comprise titanium nitride, tantalum nitride, tungsten nitride, molybdenum nitride, or a combination thereof. The metallic fill material may comprise titanium, tantalum, tungsten, cobalt, molybdenum, ruthenium, copper, etc. In one embodiment, the at least one metallic material can be deposited by chemical vapor deposition or atomic layer deposition.

According to an aspect of the present disclosure, the total thickness of the at least one conformally-deposited conductive material may be greater than one half of the height of the laterally-extending cavities (143, 243). Thus, each of the laterally-extending cavities (143, 243) can be completely filled with the at least one conformally-deposited conductive material. The deposited at least one conductive material can be isotropically etched back from the sidewalls of lateral isolation trenches 79, and from above the sacrificial contact-level dielectric layers 282 by performing an isotropic etch back process. The etch distance of the isotropic etch back process may be the same as, or may be greater than, the total thickness of the deposited at least one conductive material. Each remaining portion of the deposited metallic material in the first laterally-extending cavities constitutes an electrically conductive layer 146. Each remaining portion of the deposited metallic material in the second laterally-extending cavities constitutes a second electrically conductive layer 246. Each electrically conductive layer (146, 246) can be a conductive line structure (e.g., word line or select gate electrode).

A plurality of electrically conductive layers 146 can be formed in the plurality of first laterally-extending cavities 143, and a plurality of second electrically conductive layers 246 can be formed in the plurality of second laterally-extending cavities 243. Thus, the first and second sacrificial material layers (142, 242) can be replaced with the first and second conductive material layers (146, 246), respectively. Specifically, each first sacrificial material layer 142 can be replaced with a backside blocking dielectric layer and a first electrically conductive layer 146, and each second sacrificial material layer 242 can be replaced with a backside blocking dielectric layer and a second electrically conductive layer 246. A backside cavity is present in the portion of each lateral isolation trench 79 that is not filled with the continuous metallic material layer.

Each of the memory opening fill structures 58 (which contains a respective memory stack structures 55) comprises a vertical stack of memory elements located at each level of the electrically conductive layers (146, 246). A subset of the middle electrically conductive layers (146, 246) can comprise the word lines for the memory elements. At least one uppermost electrically conductive layer 246 may comprise a drain side select gate electrode. At least one bottommost electrically conductive layer 146 may comprise a source side select gate electrode. A first alternating stack of first insulating layers 132 and first electrically conductive layers 146 can be formed underneath the inter-tier dielectric layer 180, and a second alternating stack of second insulating layers 232 and second electrically conductive layers 246 can be formed over the inter-tier dielectric layer 180.

In one embodiment shown in FIG. 27D, conductive material portions 246′ may be formed within lateral recesses between planar sidewall segments of the dielectric support assemblies 26. In this case, a plurality of conductive material portions 246′ may be laterally interlaced with a plurality of planar vertical sidewalls of a dielectric connection plate 26CP.

Referring to FIG. 28, an insulating material layer can be conformally deposited in the lateral isolation trenches 79. An optional anisotropic etch process can be performed to remove horizontally-extending portions of the insulating material layer and the horizontally extending portion of the semiconductor oxide liner 7. Each remaining tubular portion of the insulating material layer that remains in a respective lateral isolation trench 79 constitutes an insulating spacer 74. A laterally-extending cavity can be present within each unfilled volume of the lateral isolation trenches 79 that is laterally surrounded by a respective one of the insulating spacers 74.

At least one conductive fill material can optionally be deposited in the laterally-extending cavities. Portions of the at least one conductive material that overlie the horizontal plane including the top surface of the third contact-level dielectric layer 284 can be removed by a planarization process such as a recess etch process and/or a chemical mechanical polishing process. Each remaining portion of the at least one conductive fill material that fills a respective laterally-extending cavity constitutes a source contact via structure 76. Alternatively, if the source region 61 is omitted, then the source contact via structure 76 can also be omitted at this step. Instead, the lateral isolation trenches 79 may be completely filled with the insulating spacers 74.

An alternating stack {132, 146), (232, 246)} of insulating layers (132, 232) and electrically conductive layers (146, 246) can be formed between a first lateral isolation trench fill structure (74, 76) and a second lateral isolation trench fill structure (74, 76). The first lateral isolation trench fill structure (74, 76) can contact first sidewalls of the alternating stack {(132, 146), (232, 246)} and a stepped dielectric material portion (165 or 265), and can contact at least one planar vertical sidewall of a dielectric connection plate 26CP of a dielectric support assembly 26. The second lateral isolation trench fill structure (74, 76) can contact second sidewalls of the alternating stack {(132, 146), (232, 246)}, and can be laterally spaced from the dielectric support assembly 26. In one embodiment, the first lateral isolation trench fill structure (74, 76) contacts a plurality of planar vertical sidewalls of the dielectric connection plate 26CP that are laterally spaced apart along a first horizontal direction hd1, and further contacts a plurality of conductive material portions 246′ (shown in FIG. 27D) laterally interlaced with the plurality of planar vertical sidewalls of the dielectric connection plate 26CP.

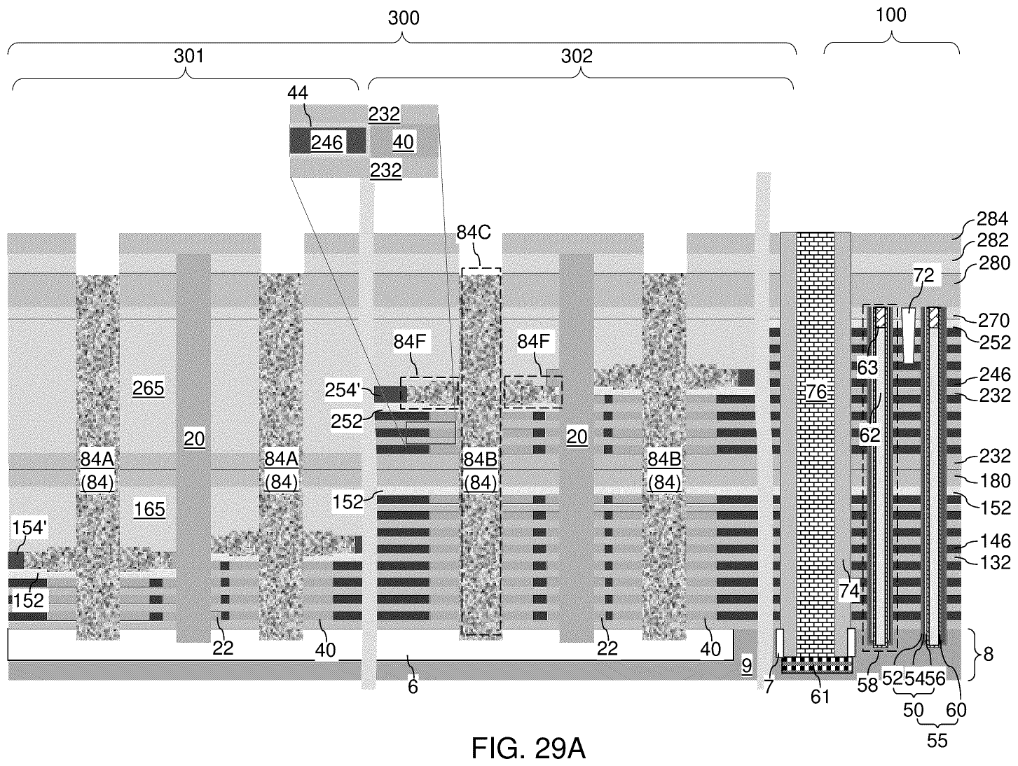

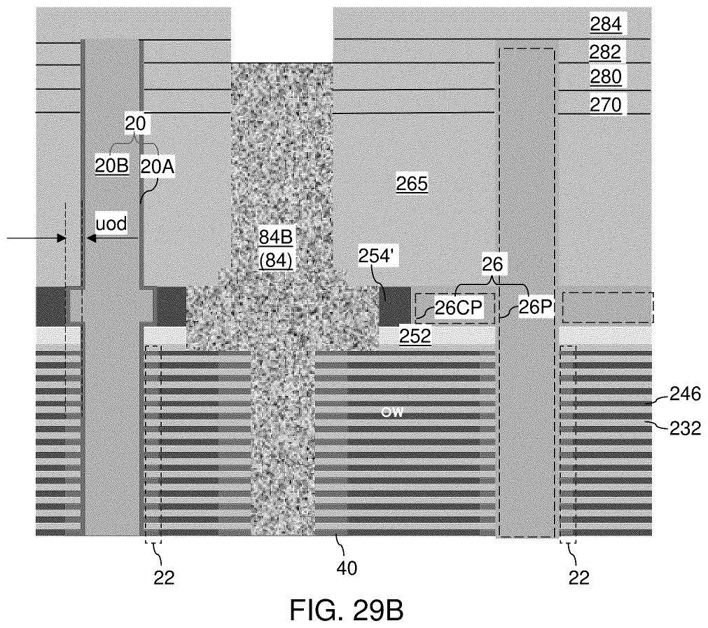

Referring to FIGS. 29A and 29B, a photoresist layer (not shown) can be applied over the third contact-level dielectric layer 284, and can be lithographically patterned to form openings in areas that overlap with top surfaces of the sacrificial finned cavity fill material structures 84. An anisotropic etch process can be performed to form etch through unmasked portions of the third contact-level dielectric layer 284 and the second contact-level dielectric layer 282 to physically expose top surfaces of the sacrificial finned cavity fill material structures 84.

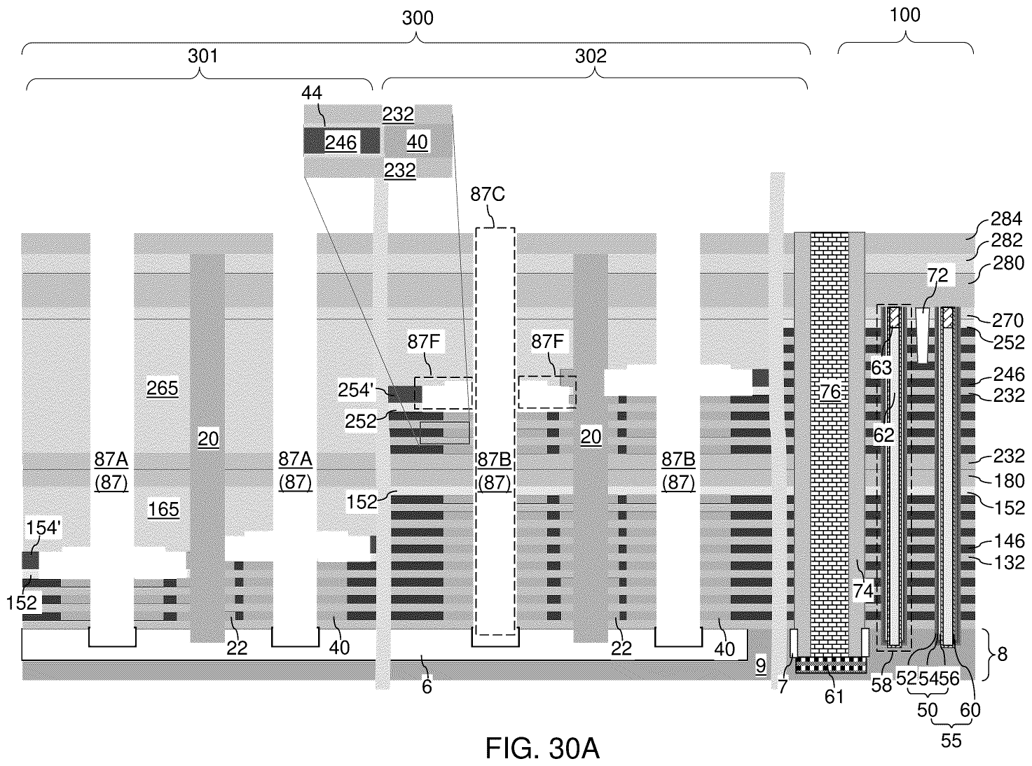

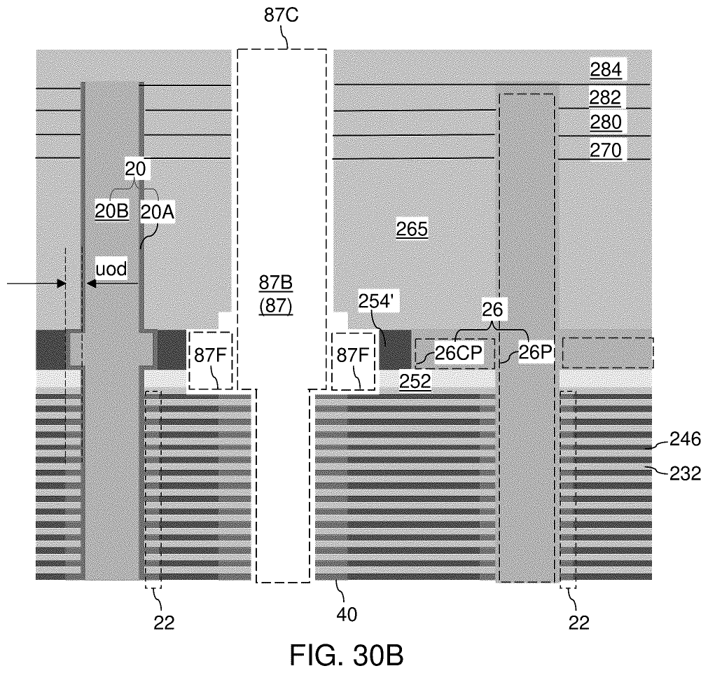

Referring to FIGS. 30A and 30B, a selective etch process can be performed to remove the sacrificial fill material of the sacrificial finned cavity fill material structures 84 selective to materials of the annular insulating plates 40, the stepped dielectric material portions (165, 265), and the dielectric isolation layer 6 (if present). Finned contact via cavities 87 are formed in volumes from which the sacrificial finned cavity fill material structures 84 are removed. The finned contact via cavities 87 comprises first finned contact via cavities 87A to which the first stepped dielectric material portion 165 is exposed, and second finned contact via cavities 87B to which the first stepped dielectric material portion 165 is not exposed. Each finned contact via cavity 87 comprises a cylindrical cavity portion 87C and a fin cavity portion 87F.

An isotropic etch process can be performed to isotropically etch the material of the first insulating liner 152 and the second insulating liner 252. The duration of the isotropic etch can be selected such that the etch distance for the material of the first insulating liner 152 and the second insulating liner 252 is greater than the thicknesses of the first insulating liner 152 and the second insulating liner 252. Thus, each physically exposed portion of the first insulating liner 152 and the second insulating liner 252 that underlie the fin cavity portions 87F are etched through. Each of the electrically conductive layers (146, 246) has a respective annular top surface segment that is physically exposed to a respective one of the fin cavity portions 87F of the finned contact via cavities 87. An annular tapered concave surface of an insulating liner (152, 252) can be physically exposed around each fin cavity portion 87F. The isotropic etch for the first insulating liner 152 and the second insulating liner 252 may comprise a dilute hydrofluoric acid etch. Optionally, the isotropic etch may be continued to remove exposed portions of the backside blocking dielectric layers. In one embodiment, surface portions of the stepped dielectric material layers (165, 265), the annular insulating plates 40, the first contact-level dielectric layer 280, the inter-tier dielectric layer 180, and the dielectric isolation layer 6 can be collaterally isotropically recessed during the isotropic etch process.

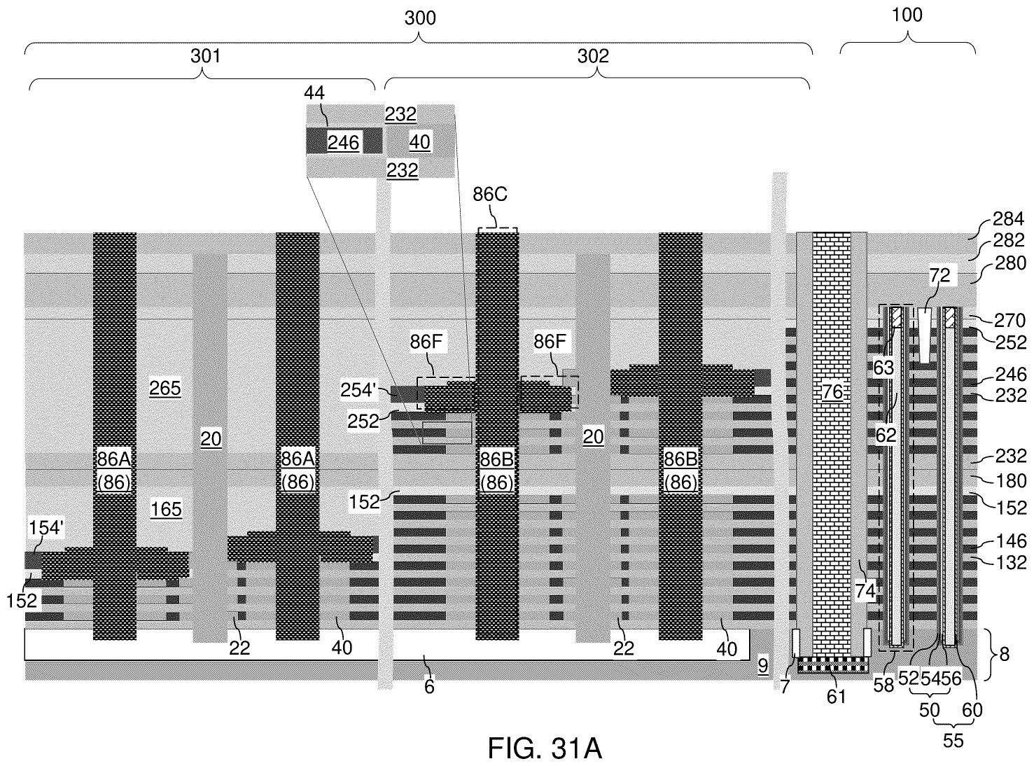

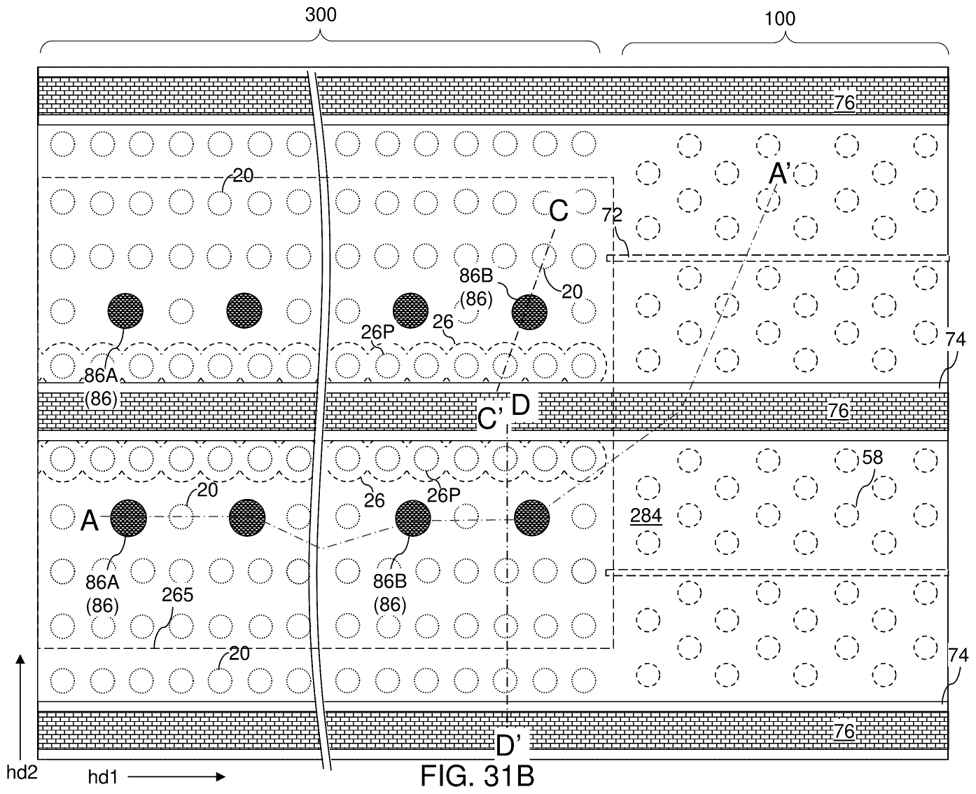

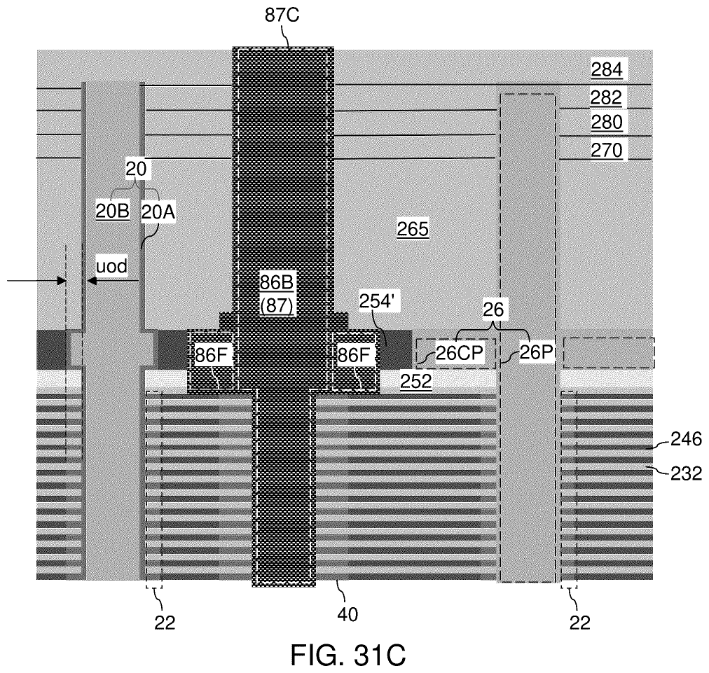

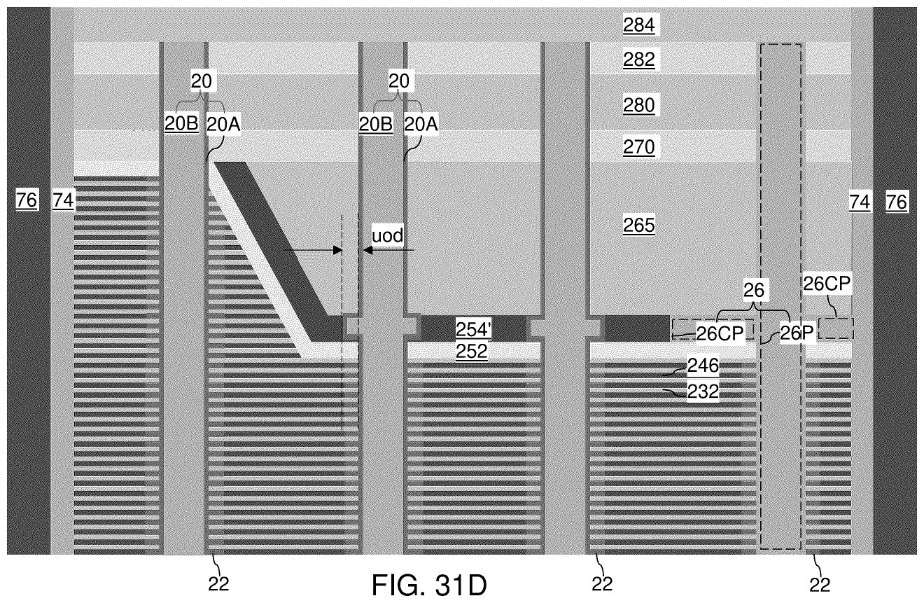

Referring to FIGS. 31A-31D, at least one conductive material, such as at least one metallic material, can be deposited in the finned contact via cavities 87. The at least one conductive material may comprise a combination of a metallic barrier liner material (such as TiN, TaN, WN, MON, or a combination thereof) and a metallic fill material (such as W, Ti, Ta, Mo, Ru, Co, Cu, etc.). Excess portions of the at least one conductive material can be removed from above the horizontal plane including the top surface of the contact-level dielectric layers (284, 282, 280) by a planarization process such as a chemical mechanical polishing process. Each remaining portion of the at least one conductive material that fills a respective finned contact via cavity 87 constitutes a contact via structure, which is herein referred to as a layer contact via structure 86.

The layer contact via structures 86 comprise first contact via structures 86A that are formed in the first finned contact via cavities 87A and second contact via structures 86B that are formed in the second finned contact via cavities 87B. Each of the layer contact via structures 86 vertically extends at least from a bottommost surface of the first alternating stack (132, 146) to a horizontal plane located at or above a top surface of the memory opening fill structure 58. Each layer contact via structure 86 comprises a respective conductive pillar portion 86C and a respective conductive fin portion 86F that laterally protrudes from the respective conductive pillar portion 86C and has a first annular bottom surface segment contacting an annular top surface segment of one of the electrically conductive layers (146, 246). Each conductive fin portion 86F may also have a second annular bottom surface segment contacting an annular top surface segment of an annular insulating plate 40, which may be a topmost annular insulating plate 40 within a vertical stack of annular insulating plates 40 underlying the respective conductive fin portion 86F. Each conductive fin portion 86F may have an annular top surface that contacts an annular bottom surface segment of one of the stepped dielectric material portions (165, 265).

A plurality of first contact via structures 86A vertically extends through the first stepped dielectric material portion 165 and the second stepped dielectric material portion 265. A plurality of second contact via structures 86B vertically extends through the second stepped dielectric material portion 265. In one embodiment, each annular insulating plate 40 within a vertical stack of annular insulating plates 40 has a lateral width which laterally offsets a respective electrically conductive layer (146, 246) from the conductive pillar portion 86C by a lateral offset distance. Each conductive fin portion 86F of a layer contact via structure 86 may have an outer sidewall that is laterally spaced from a sidewall of the conductive pillar portion 86C of the layer contact via structure 86 by a lateral offset distance.

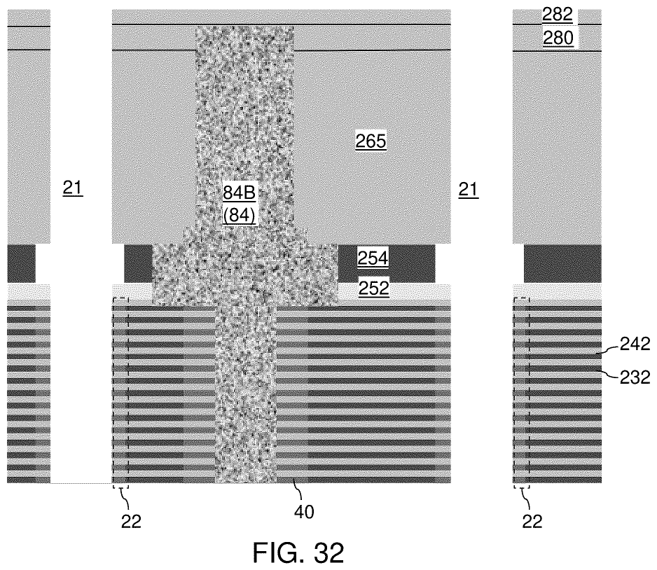

Referring to FIG. 32, a second exemplary structure according to a second embodiment of the present disclosure can be derived from the first exemplary structure of FIG. 22C by omitting formation of the photoresist layer 237 described with reference to FIG. 22D, and by performing the isotropic recess etch process which is described with respect of FIG. 22D. For example, if the conformal insulating layer 22L comprises silicon oxide, a wet etch process employing dilute hydrofluoric acid can be performed to isotropically recess the conformal insulating layer 22L within each of the support openings 21. The duration of the isotropic etch process can be selected such that the isotropic recess etch process completely removes the material of the conformal insulating layer 22L from inside each of the cylindrical annular cavities 21C of the support openings 21. Remaining portions of the conformal insulating layer 22L that fill the fin cavities 21F (i.e., the volumes from which portions of the sacrificial material layers (142, 242) are removed) constitute insulating fins 22.

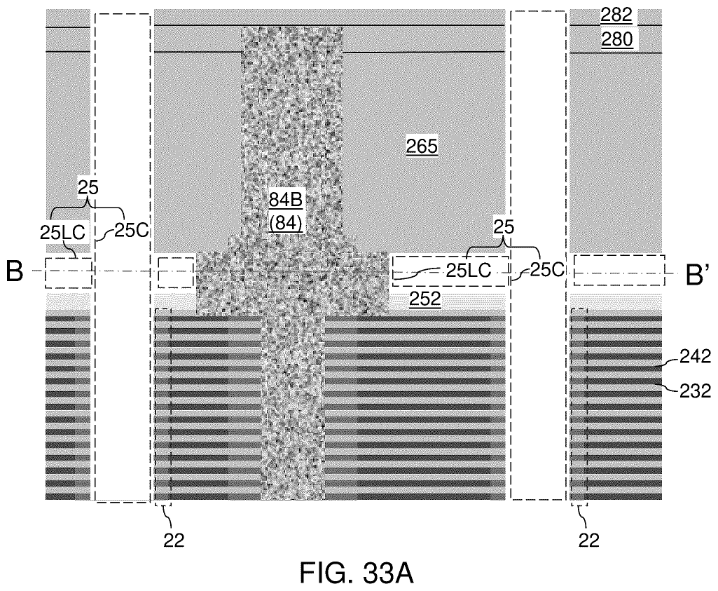

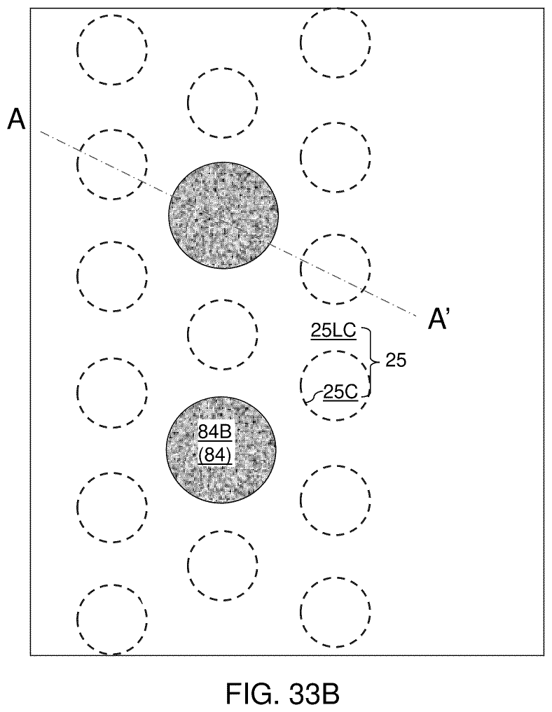

Referring to FIGS. 33A and 33B, a selective isotropic etch process can be performed to remove the etch-stop material layers (154, 254) selective to the contact-level dielectric layers (280, 282), the insulating cap layer 270, the stepped dielectric material portions (165, 265), the insulating liners (152, 252), the insulating fins 22, and the sacrificial finned cavity fill material structure 84. For example, if the etch-stop material layers (154, 254) comprise silicon nitride, the selective isotropic etch process may comprise a wet etch process employing hot phosphoric acid. The duration of the selective isotropic etch process can be selected such that the etch-stop material layers (154, 254) are entirely removed. Laterally-expanded cavities around support openings 21 merge to form continuous cavities 25. Each continuous cavity 25 includes a laterally-extending cavity 25LC that is interconnected to a row of cylindrical cavities 25C. The volumes of the cylindrical cavities 25C include volumes of an array of support openings 21. The volume of each laterally-extending cavity 25LC includes a volume of a removed etch-stop material layer (154, 254).

Generally, the etch-stop material layers (154, 254) can be isotropically etched around a subset of the support openings 21 by performing an isotropic etch process, and can be entirely removed. A continuous cavity 25 can be formed, which comprises volumes of the subset of the support openings 21 and further comprises a laterally-extending cavity 25LC that laterally surrounds the volumes of the subset of the support openings 21.

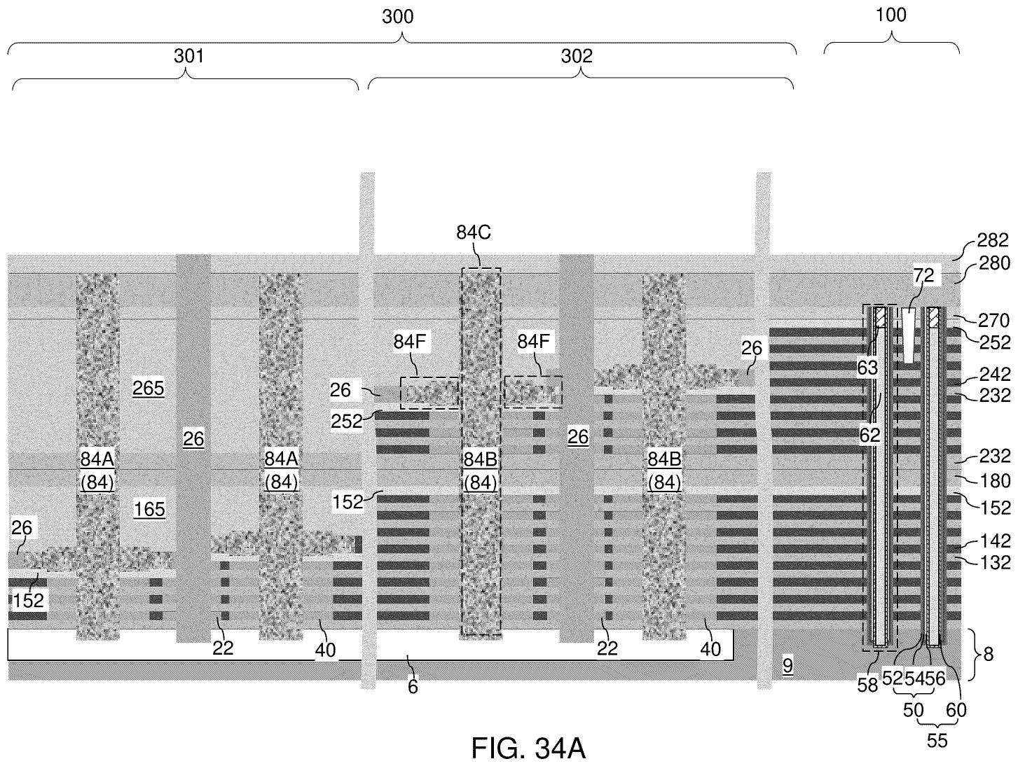

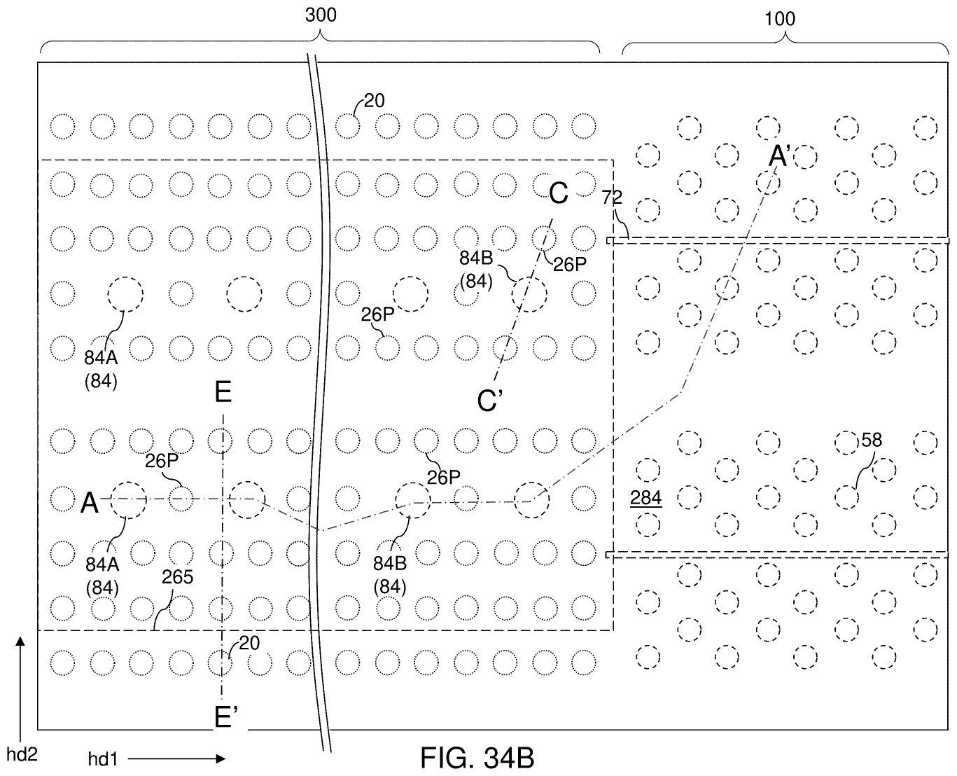

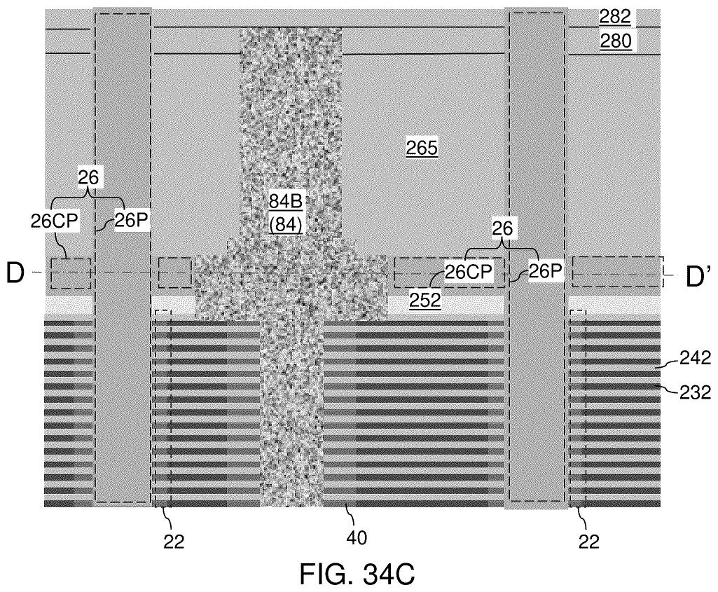

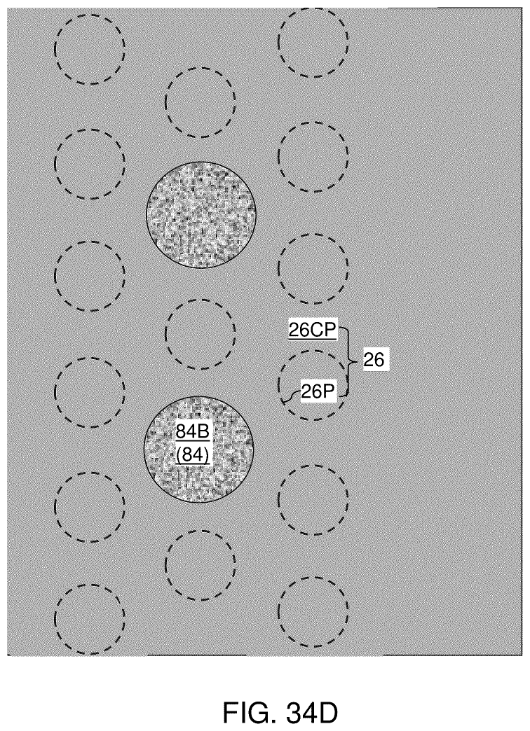

Referring to FIGS. 34A-34D, a dielectric fill material, such as undoped silicate glass or a doped silicate glass, can be conformally deposited in the continuous cavities 25 through the support openings 21 and into any remaining support openings (if any) 21 that are not connected to the continuous cavities 25. A planarization process, such as a recess etch process and/or a chemical mechanical polishing process, can be performed to remove portions of the deposited dielectric fill material from above the horizontal plane including the top surface of the second contact-level dielectric layer 282.

Each remaining portion of the dielectric fill material that fills a continuous cavity 25 constitutes a dielectric support assembly 26. Each dielectric support assembly 26 comprises a plurality of dielectric pillar structures 26P located in the volumes of a subset of the support openings 21 and further comprises a dielectric connection plate 26CP which fills a laterally-extending cavity 25LC and laterally surrounds, and is adjoined to, each of the plurality of dielectric pillar structures 26P. In one embodiment, the dielectric connection plate 26CP extends over multiple stepped surfaces among the stepped surfaces of the alternating stacks {(132, 142), (232, 242)}.

In one embodiment, the dielectric connection plate 26CP comprises horizontally-extending dielectric connection plate portions that overlie horizontally-extending surface segments of stepped surfaces of an alternating stack {(132, 142) or (232, 242)} and vertically-extending dielectric connection plate portions that overlie vertically-extending surface segments of the stepped surfaces of the alternating stack {(132, 142) or (232, 242)}. In one embodiment, a vertical thickness of the horizontally-extending dielectric connection plate portions is the same as a lateral thickness of the vertically-extending dielectric connection plate portions. In one embodiment, optional dielectric pillar structures 20 can be formed in the support openings (if any) 21 that are not connected to the dielectric support assembly 26.

In one embodiment, an entirety of the etch-stop material layers (154, 254) may be removed by performing an isotropic etch process. In one embodiment, a dielectric connection plate 26CP of a dielectric support assembly 26 may comprise a tapered portion having a top surface within a horizontal plane including a top surface of a stepped dielectric material portion (165 or 265). The tapered portion may have a uniform thickness throughout. The taper angle of a tapered surface of the tapered portion may be in a range from 0.2 degree to 5 degree as measured relative to the vertical direction. In one embodiment, a dielectric pillar structure 20 may have a straight sidewall that vertically extends through, and in contact with, each layer within the alternating stack {(132, 142), (232, 242)}.

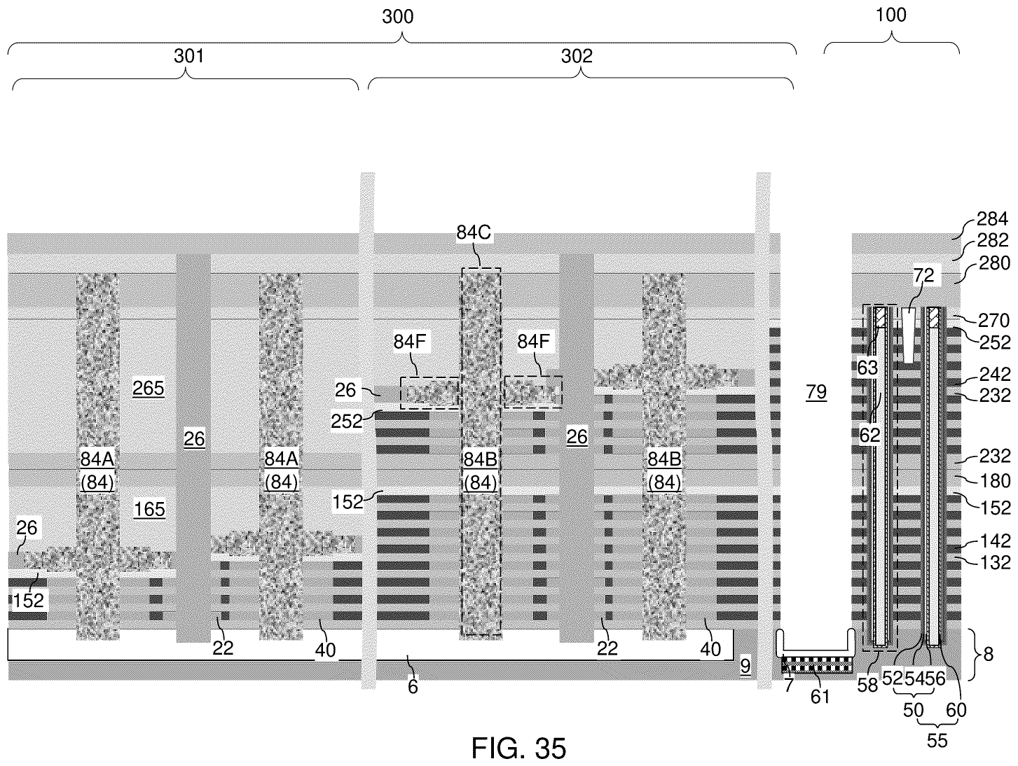

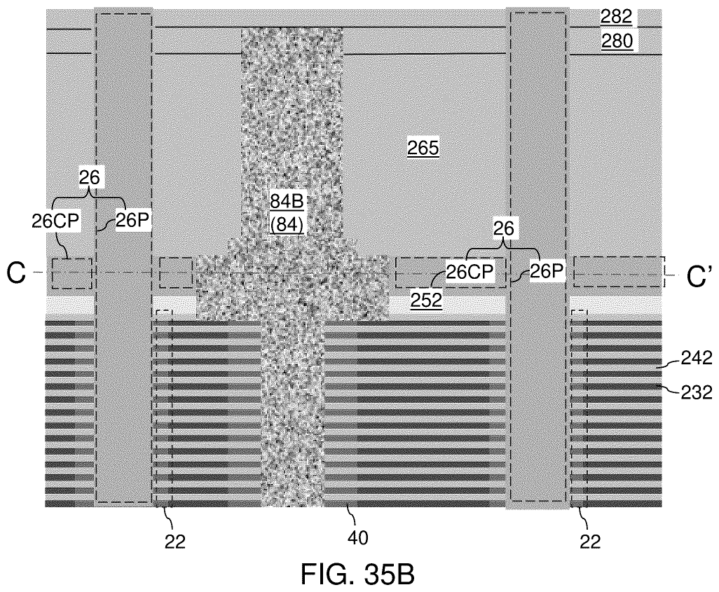

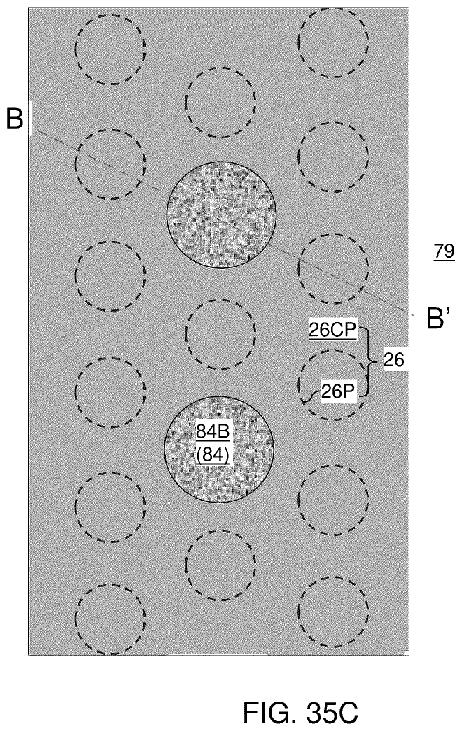

Referring to FIGS. 35A-35C, the processing steps described with reference to FIGS. 25A-25C can be performed to form a third contact-level dielectric layer 284 and lateral isolation trench fill structures (74, 76).

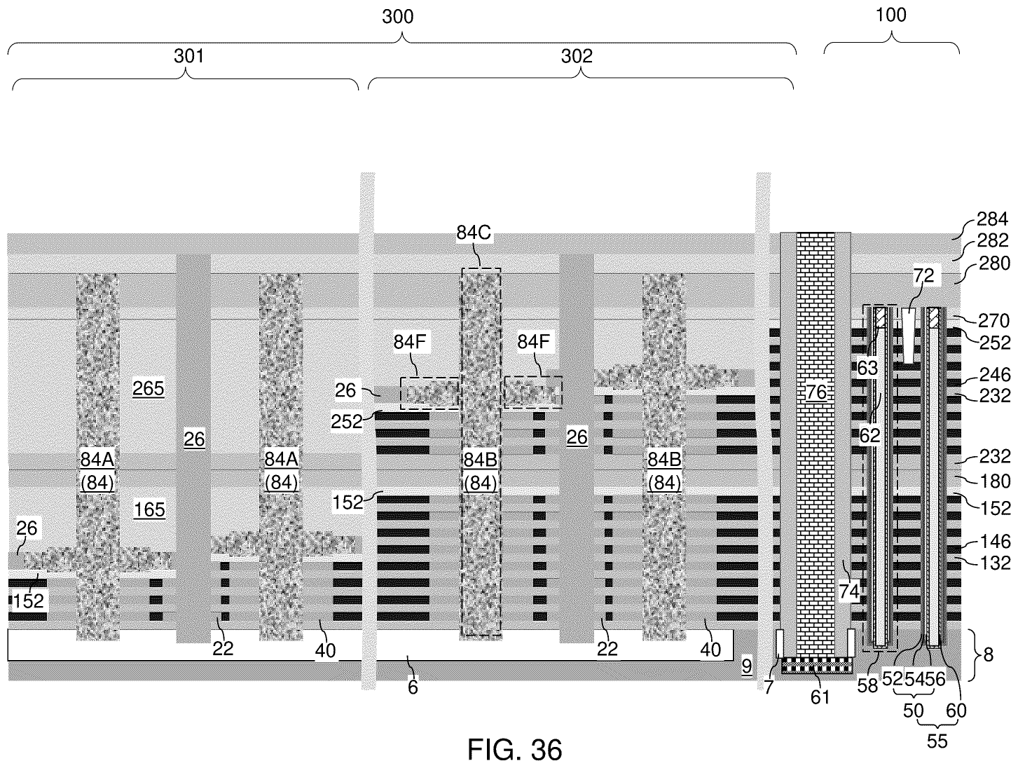

Referring to FIG. 36, the processing steps described with reference to FIGS. 26A-26C, 27A-27D, and 28 can be performed to replace the sacrificial material layers (142, 242) with electrically conductive layers (146, 246).

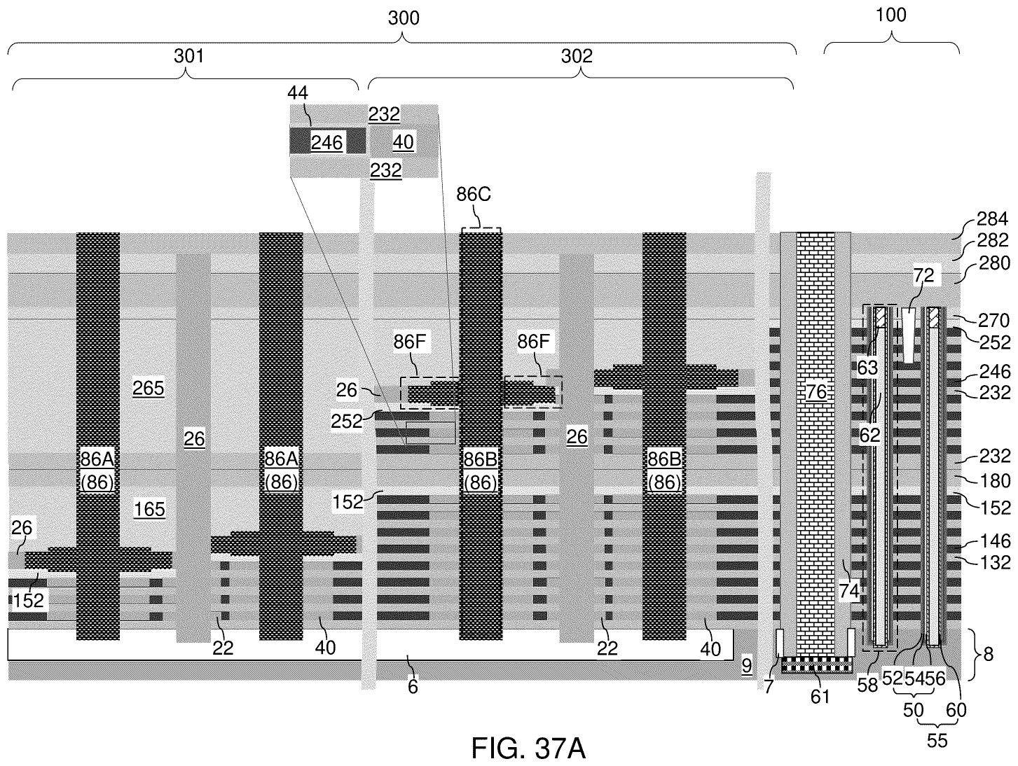

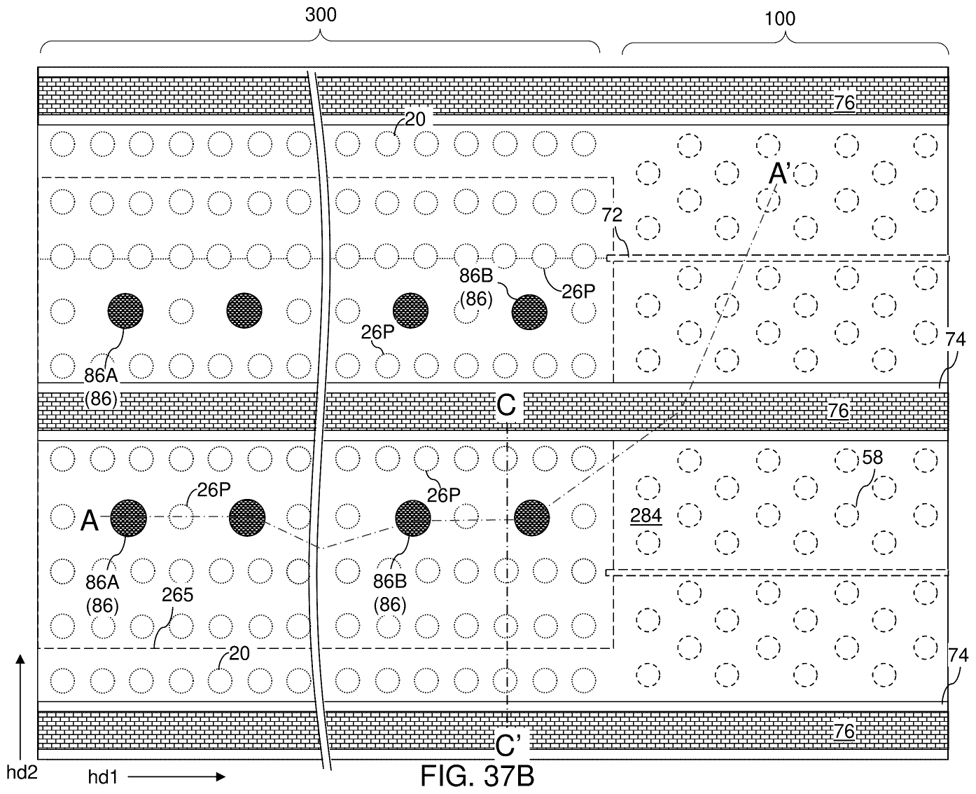

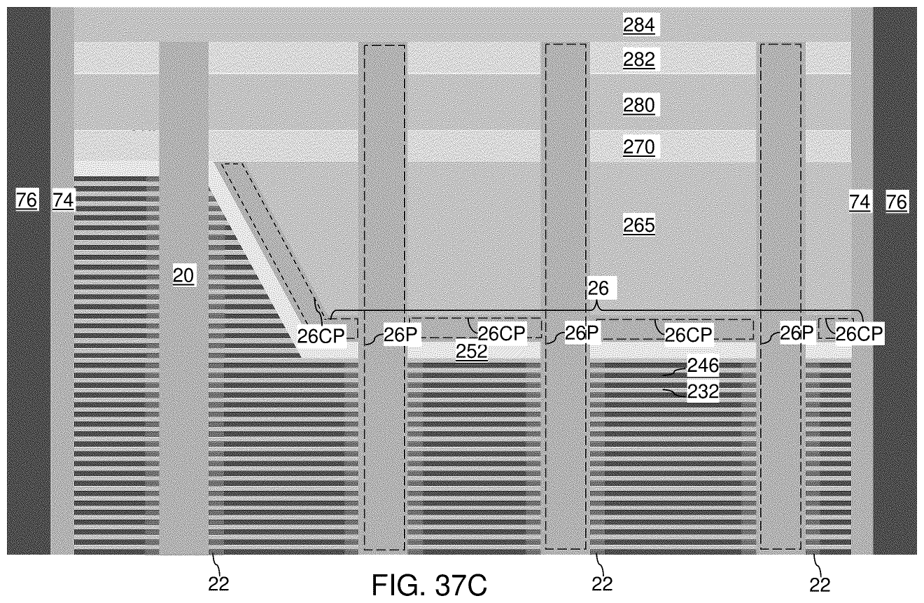

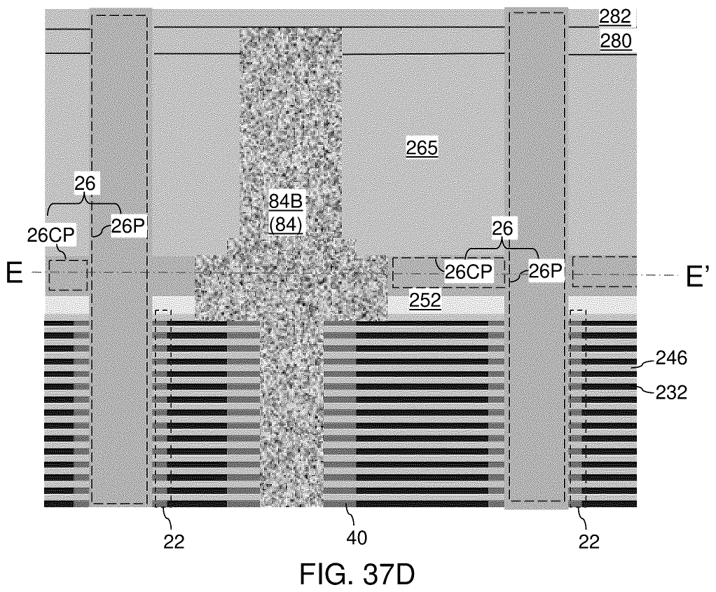

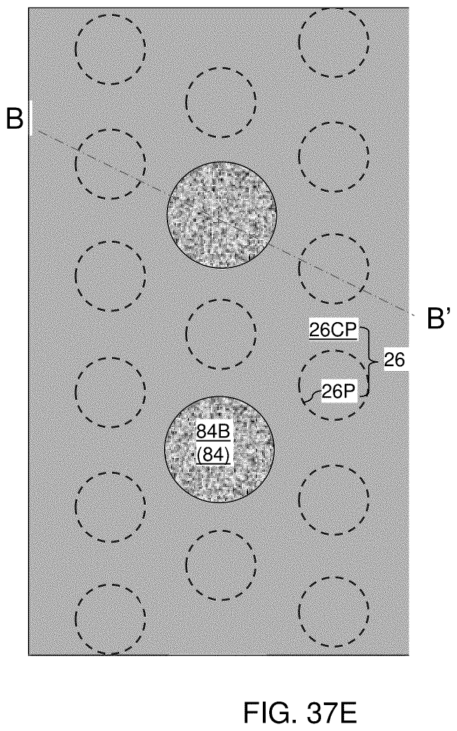

Referring to FIGS. 37A-37E, the processing steps described with reference to FIGS. 29A and 29B, 30A and 30B, and 31A-31D can be performed to replace sacrificial finned cavity fill material structures 84 with layer contact via structures 86.

Referring to all drawings and according to various embodiments of the present disclosure, a memory device is provided, which comprises: an alternating stack {(132, 146), (232, 246)} of insulating layers (132, 232) and electrically conductive layers (146, 246), wherein the alternating stack {(132, 146), (232, 246)} comprises stepped surfaces located in a contact region 300; a dielectric material portion (165 or 265) overlying the stepped surfaces of the alternating stack {(132, 146), (232, 246)}; a memory opening 49 vertically extending through the alternating stack {(132, 146), (232, 246)}; a memory opening fill structure 58 located in the memory opening 49 and comprising a vertical stack of memory elements (e.g., portions of the memory film 50) and a vertical semiconductor channel 60; and a dielectric support assembly 26 comprising a plurality of dielectric pillar structures 26P and a dielectric connection plate 26CP, wherein the plurality of dielectric pillar structures 26P vertically extend through the stepped surfaces, the dielectric material portion (165 or 265), and an underlying portion of the alternating stack {(132, 146), (232, 246)}, and the dielectric connection plate 26CP overlies the stepped surfaces and contacts and laterally surrounds each of the plurality of dielectric pillar structures 26P.

In one embodiment, the dielectric connection plate 26CP extends over multiple stepped surfaces. In one embodiment, the dielectric connection plate 26CP comprises horizontally-extending dielectric connection plate portions and vertically-extending dielectric connection plate portions; and a vertical thickness of the horizontally-extending dielectric connection plate portions is the same as a lateral thickness of the vertically-extending dielectric connection plate portions. In one embodiment, the dielectric connection plate 26CP comprises vertically-straight and horizontally-convex surface segments XS that are adjoined to each other at vertically-extending edges.

In the first embodiment, the memory device further comprises a dielectric material plate (154′, 254′) overlying the stepped surfaces of the alternating stack {(132, 146), (232, 246)} and comprising vertically-straight and horizontally-concave surface segments CS contacting the vertically-straight and horizontally-convex surface segments XS of the dielectric connection plate 26CP. In the first embodiment, the memory device further comprises a layer contact via structure 86 vertically extending through the dielectric material portion (165 or 265) and the dielectric material plate (154′, 254′) and contacting a top surface of one of the electrically conductive layers (146, 246).

In the first embodiment, the memory device further comprises a dielectric pillar structure 20 comprising a cylindrical portion 20C having a cylindrical shape and further comprising a rim portion 20R that protrudes outward from the cylindrical portion and contacting the dielectric material plate (154′, 254′), wherein a cylindrical surface of the dielectric material plate (154′, 254′) is laterally offset from a cylindrical surface of the cylindrical portion by a uniform offset distance uod.

In the first embodiment, the dielectric material plate comprises a first insulating material, such as silicon nitride, and the dielectric support assembly comprises a second insulating material, such as silicon oxide, which is different from the first insulating material. The stepped surfaces comprise horizontally-extending surface segments and vertically-extending surface segments that are adjoined to each other; the horizontally-extending surface segments are arranged along a first horizontal direction hd1; the alternating stack {(132, 146), (232, 246)} further comprises a tapered surface laterally extending along the first horizontal direction hd1, inclined along a second horizontal direction hd2 that is perpendicular to the first horizontal direction hd1, having a top edge located within a horizontal plane, and having a stepped bottom edge that is adjoined to a stepped edge of the stepped surfaces; and the dielectric material plate (154′, 254′) comprises a tapered portion overlying the tapered surface and having a top surface within a horizontal plane including a top surface of the dielectric material portion (165 or 265).

In the second embodiment, the dielectric connection plate 26CP comprises a tapered portion having a top surface within a horizontal plane including a top surface of the dielectric material portion (165 or 265). In the second embodiment, the memory device comprises a layer contact via structure 86 vertically extending through the dielectric material portion (165 or 265) and the dielectric connection plate 26CP and contacting a top surface of one of the electrically conductive layers (146, 246). In the second embodiment, the memory device comprises a dielectric pillar structure 20 having a straight sidewall that vertically extends through, and in contact with, each layer within the alternating stack {(132, 146), (232, 246)}.

In the second embodiment, the stepped surfaces comprise horizontally-extending surface segments and vertically-extending surface segments that are adjoined to each other; the horizontally-extending surface segments are arranged along a first horizontal direction hd1; the alternating stack {(132, 146), (232, 246)} further comprises a tapered surface laterally extending along the first horizontal direction hd1, inclined along a second horizontal direction hd2 that is perpendicular to the first horizontal direction hd1, having a top edge located within a horizontal plane, and having a stepped bottom edge that is adjoined to a stepped edge of the stepped surfaces; and the tapered portion of the dielectric connection plate 26CP overlies the tapered surface of the alternating stack {(132, 146), (232, 246)}.

In one embodiment, the memory device further comprises: a first lateral isolation trench fill structure (74, 76) contacting first sidewalls of the alternating stack {(132, 146), (232, 246)} and the dielectric material portion (165 or 265) and contacting at least one planar vertical sidewall of the dielectric connection plate 26CP; and a second lateral isolation trench fill structure (74, 76) contacting second sidewalls of the alternating stack {(132, 146), (232, 246)} and laterally spaced from the dielectric support assembly 26. In one embodiment, the first lateral isolation trench fill structure (74, 76) contacts a plurality of planar vertical sidewalls of the dielectric connection plate 26CP that are laterally spaced apart along a first horizontal direction hd1, and further contacts a plurality of conductive material portions 246′ laterally interlaced with the plurality of planar vertical sidewalls of the dielectric connection plate 26CP.

In one embodiment, the memory device further comprises a layer contact via structure 86 vertically extending at least from a bottommost surface of the alternating stack {(132, 146), (232, 246)}, through the dielectric material portion (165 or 265), and to a horizontal plane located at or above a top surface of the memory opening fill structure 58, wherein the layer contact via structure 86 comprises a conductive pillar portion 86C and a conductive fin portion 86F that laterally protrudes from the conductive pillar portion 86C and having a first annular bottom surface segment contacting an annular top surface segment of one of the electrically conductive layers (146, 246).

The various embodiments of the present disclosure can be employed to at least partially replace etch-stop material layers (154, 254). Specifically, each etch-stop material layer (154, 254) may be partly or fully replaced with a dielectric support assembly 26 including a plurality of dielectric pillar structures 26P and a dielectric connection plate 26CP. The dielectric connection plate 26CP is located between an overlying stepped dielectric material portion (165, 265) and an underlying alternating stack {(132, 146), (232, 246)}, and prevents formation of lateral recesses (143, 243) and electrically conductive material portions above the stepped surfaces during formation of the electrically conductive layers (146, 246). Electrical shorts caused by presence of electrically conductive material portions can be prevented or reduced through formation of the dielectric support assemblies 26.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device, comprising:
an alternating stack of insulating layers and electrically conductive layers, wherein the alternating stack comprises stepped surfaces located in a contact region;
a dielectric material portion overlying the stepped surfaces of the alternating stack;
a memory opening vertically extending through the alternating stack;
a memory opening fill structure located in the memory opening and comprising a vertical stack of memory elements and a vertical semiconductor channel; and
a dielectric support assembly comprising a plurality of dielectric pillar structures and a dielectric connection plate, wherein the plurality of dielectric pillar structures vertically extend through the stepped surfaces, the dielectric material portion, and an underlying portion of the alternating stack, and the dielectric connection plate overlies the stepped surfaces and contacts and laterally surrounds each of the plurality of dielectric pillar structures.

2. The memory device of claim 1, wherein the dielectric connection plate extends over multiple ones of the stepped surfaces.

3. The memory device of claim 2, wherein:
the dielectric connection plate comprises horizontally-extending dielectric connection plate portions and vertically-extending dielectric connection plate portions; and
a vertical thickness of the horizontally-extending dielectric connection plate portions is the same as a lateral thickness of the vertically-extending dielectric connection plate portions.

4. The memory device of claim 1, wherein the dielectric connection plate comprises vertically-straight and horizontally-convex surface segments that are adjoined to each other at vertically-extending edges.

5. The memory device of claim 4, further comprising a dielectric material plate overlying the stepped surfaces of the alternating stack and comprising vertically-straight and horizontally-concave surface segments contacting the vertically-straight and horizontally-convex surface segments of the dielectric connection plate.

6. The memory device of claim 5, further comprising a layer contact via structure vertically extending through the dielectric material portion and the dielectric material plate and contacting a top surface of one of the electrically conductive layers.

7. The memory device of claim 5, further comprising a dielectric pillar structure comprising a cylindrical portion having a cylindrical shape and further comprising a rim portion that protrudes outward from the cylindrical portion and contacting the dielectric material plate, wherein a cylindrical surface of the dielectric material plate is laterally offset from a cylindrical surface of the cylindrical portion by a uniform offset distance.

8. The memory device of claim 5, wherein:
the dielectric material plate comprises silicon nitride;
the dielectric support assembly comprises silicon oxide;
the stepped surfaces comprise horizontally-extending surface segments and vertically-extending surface segments that are adjoined to each other;
the horizontally-extending surface segments are arranged along a first horizontal direction;
the alternating stack further comprises a tapered surface laterally extending along the first horizontal direction, inclined along a second horizontal direction that is perpendicular to the first horizontal direction, having a top edge located within a horizontal plane, and having a stepped bottom edge that is adjoined to a stepped edge of the stepped surfaces; and
the dielectric material plate comprises a tapered portion overlying the tapered surface and having a top surface within a horizontal plane including a top surface of the dielectric material portion.

9. The memory device of claim 1, wherein the dielectric connection plate comprises a tapered portion having a top surface within a horizontal plane including a top surface of the dielectric material portion.

10. The memory device of claim 9, further comprising a layer contact via structure vertically extending through the dielectric material portion and the dielectric connection plate and contacting a top surface of one of the electrically conductive layers.

11. The memory device of claim 9, further comprising a dielectric pillar structure having a straight sidewall that vertically extends through and in contact with each layer within the alternating stack.

12. The memory device of claim 9, wherein:
the stepped surfaces comprise horizontally-extending surface segments and vertically-extending surface segments that are adjoined to each other;
the horizontally-extending surface segments are arranged along a first horizontal direction;
the alternating stack further comprises a tapered surface laterally extending along the first horizontal direction, inclined along a second horizontal direction that is perpendicular to the first horizontal direction, having a top edge located within a horizontal plane, and having a stepped bottom edge that is adjoined to a stepped edge of the stepped surfaces; and
the tapered portion of the dielectric connection plate overlies the tapered surface of the alternating stack.

13. The memory device of claim 1, further comprising:
a first lateral isolation trench fill structure contacting first sidewalls of the alternating stack and the dielectric material portion and contacting at least one planar vertical sidewall of the dielectric connection plate; and
a second lateral isolation trench fill structure contacting second sidewalls of the alternating stack and laterally spaced from the dielectric support assembly.

14. The memory device of claim 13, wherein the first lateral isolation trench fill structure contacts a plurality of planar vertical sidewalls of the dielectric connection plate that are laterally spaced apart along a first horizontal direction, and further contacts a plurality of conductive material portions laterally interlaced with the plurality of planar vertical sidewalls of the dielectric connection plate.

15. The memory device of claim 1, further comprising a layer contact via structure vertically extending at least from a bottommost surface of the alternating stack, through the dielectric material portion, and to a horizontal plane located at or above a top surface of the memory opening fill structure, wherein the layer contact via structure comprises a conductive pillar portion and a conductive fin portion that laterally protrudes from the conductive pillar portion and having a first annular bottom surface segment contacting an annular top surface segment of one of the electrically conductive layers.

16. A method of forming a memory device, comprising:
forming an alternating stack of insulating layers and sacrificial material layers over a substrate;
forming stepped surfaces by patterning the alternating stack;
forming an etch-stop material layer over the stepped surfaces;
forming a dielectric material portion over a portion of the etch-stop material layer that overlies the stepped surfaces;
forming a memory opening through the alternating stack;
forming a memory opening fill structure in the memory opening, wherein the memory opening fill structure comprises a vertical stack of memory elements and a vertical semiconductor channel;
forming support openings through the dielectric material portion, the etch-stop material layer, and a portion of the alternating stack that underlies the dielectric material portion;
isotropically etching the etch-stop material layer around a subset of the support openings by performing an isotropic etch process to form continuous cavity which comprises volumes of the subset of the support openings and further comprises a laterally-extending cavity that laterally surrounds the volumes of the subset of the support openings;
forming a dielectric support assembly in the continuous cavity, wherein the dielectric support assembly comprises a plurality of dielectric pillar structures located in the volumes of the subset of the support openings and further comprises a dielectric connection plate which fills the laterally-extending cavity and laterally surrounds each of the plurality of dielectric pillar structures; and
replacing the sacrificial material layers with electrically conductive layers.

17. The method of claim 16, wherein the dielectric connection plate extends over multiple ones of the stepped surfaces.

18. The method of claim 16, wherein:
the dielectric connection plate comprises vertically-straight and horizontally-convex surface segments that are adjoined to each other at vertically-extending edges;
the etch-stop material layer comprises a dielectric material different from a material of the dielectric support assembly; and
a remaining portion of the etch-stop material layer comprises a dielectric material plate overlying the stepped surfaces of the alternating stack and comprising vertically-straight and horizontally-concave surface segments contacting the vertically-straight and horizontally-convex surface segments of the dielectric connection plate.

19. The method of claim 16, wherein:
an entirety of the etch-stop material layer is removed by performing the isotropic etch process; and
the dielectric connection plate comprises a tapered portion having a top surface within a horizontal plane including a top surface of the dielectric material portion.

20. The method of claim 16, further comprising forming a layer contact via structure vertically extending at least from a bottommost surface of the alternating stack, through the dielectric material portion, and to a horizontal plane located at or above a top surface of the memory opening fill structure, wherein the layer contact via structure comprises a conductive pillar portion and a conductive fin portion that laterally protrudes from the conductive pillar portion and having a first annular bottom surface segment contacting an annular top surface segment of one of the electrically conductive layers.
